(19) United States
(12) Patent Application Publication
(10) Pub. No.: US 2018/0166632 A1
(43) Pub. Date: Jun. 14, 2018

(54) HIGH MOLECULAR COMPOUND, ORGANIC ELECTROLUMINESCENCE ELEMENT MATERIAL, ORGANIC ELECTROLUMINESCENCE ELEMENT, AND ELECTRONIC DEVICE

(71) Applicant: IDEMITSU KOSAN CO., LTD., Chiyoda-ku (JP)

(72) Inventors: Hironori KAWAKAMI, Katsushika-ku (JP); Masakazu FUNAHASHI, Chiba-shi (JP); Takahiro FUJIYAMA, Kisarazu-shi (JP); Shinji KIYONO, Kimitsu-shi (JP)

(73) Assignee: IDEMITSU KOSAN CO., LTD., Chiyoda-ku (JP)

(21) Appl. No.: 15/577,928

(22) PCT Filed: May 24, 2016
(86) PCT No.: PCT/JP2016/065365

§ 371 Date: Nov. 29, 2017

(30) Foreign Application Priority Data
May 29, 2015 (JP) 2015-110297
May 29, 2015 (JP) 2015-110298
May 29, 2015 (JP) 2015-110815

(51) Int. Cl. H01L 51/00; C08G 61/02

(52) U.S. Cl. CPC H01L 51/0039; H01L 51/5088; H01L 51/0043; C08G 61/02

(57) ABSTRACT

Provided is a high-molecular compound having a structural unit (A) and a structural unit (B) differing from each other, wherein the structural unit (A) is represented by the following general formula (A-1) and the structural unit (B) has a structure containing an arylene group or a heteroarylene group. The high-molecular compound can produce an organic EL device having a long lifetime, and is favorable as a forming material for organic EL devices. [In the formula, Ar^{A} represents a linking group having a fluorene skeleton, L¹, L², Ar¹ and Ar² each are a predetermined group, at least one of Ar¹ and Ar² is a monovalent organic group represented by the following general formula (a). (In the formula, X represents a divalent group selected from —O—, —S—, —N(R^{x})—, etc., R¹ and R² each represent a substituent, p is an integer of 0 to 3, q is an integer of 0 to 4, and * indicates a bonding position to L¹ or L².)]

### TECHNICAL FIELD

The present invention relates to a high-molecular compound, a material for organic electroluminescence devices containing the high-molecular compound, an organic electroluminescence device using the high-molecular compound, and an electronic device equipped with the organic electroluminescence device.

### BACKGROUND ART

Recently, studies and developments of functional materials using organic compounds have been made actively, and in particular, development of an organic electroluminescence device (hereinafter also referred to as “organic EL device”) using an organic compound has been pressed forward energetically.

In general, an organic EL device is composed of an anode, a cathode, and one or more organic thin-film layers which include a light emitting layer and are sandwiched between the anode and the cathode. When a voltage is applied between the electrodes, electrons are injected from the cathode side and holes are injected from the anode side into a light emitting region. The injected electrons recombine with the injected holes in the light emitting region to form an excited state. When the excited state returns to the ground state, the energy is released as light of various colors (for example, red, blue, green). Therefore, it is important for increasing the efficiency of an organic EL device to develop an organic compound which transports electrons or holes into the light emitting region efficiently and facilitates the recombination of electrons and holes.

As a material for forming an organic EL device, use of a light-emitting conjugated high-molecular compound in place of a low-molecular compound is under investigation. The high-molecular compound can form an organic thin-film layer having good mechanical strength and thermal stability and enables patterning according to a printing method, and therefore, as a material advantageous for large-size TV panels and flexible sheet displays, the compound is now under vigorous development.

### CITATION LIST

### Patent Literature

PTL 1: JP 2006-316224 A

PTL 2: JP 2011-174061 A

PTL 3: JP 2012-214732 A

PTL 4: JP 2012-236970 A

PTL 5: WO2009/110360

### SUMMARY OF INVENTION

### Technical Problem

However, an organic EL device using a conventional high-molecular compound has a problem that the lifetime thereof is short as compared with that of an organic EL device using a low-molecular compound. Consequently, a high-molecular compound capable of being a material for forming an organic EL device having a longer lifetime is desired.

An object of the present invention is to provide a high-molecular compound favorable for a material for forming an organic EL device and capable of forming a long lifetime organic EL device.

### Solution to Problem

The present inventors have assiduously studied to attain the above-described object and, as a result, have found that a high-molecular compound that has a structural unit derived from an aromatic amine derivative having a specific skeleton along with a fluorene skeleton can solve the above-described problems.

Specifically, according to an aspect of the present invention, the following [1] to [4] are provided.

[1] A high-molecular compound having a structural unit (A) and a structural unit (B) differing from each other, wherein:

the structural unit (A) is represented by the following general formula (A-1):

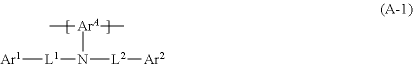

wherein Ar^{A} represents a linking group having a fluorene skeleton,

L¹ and L² each independently represent a single bond, a substituted or unsubstituted arylene group having 6 to 60 ring carbon atoms, or a substituted or unsubstituted heteroarylene group having 5 to 60 ring atoms, and

Ar¹ and Ar² each independently represent a substituted or unsubstituted aryl group having 6 to 60 ring carbon atoms, or a substituted or unsubstituted heteroaryl group having 5 to 60 ring atoms, and at least one of Ar¹ and Ar² is a monovalent organic group represented by the following general formula (a):

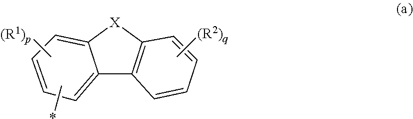

wherein X represents —O—, —S—, —N(R^{x})—, —C(R^{x})(R^{y})—, —Si(R^{x})(R^{y})—, —P(R^{x})—, —P(═O)(R^{x})—, or —P(═S)(R^{x})—, in which R^{x} and R^{y} each independently represent a hydrogen atom or a substituent, and R^{x} and R^{y} may bond to each other to form a ring structure,

R¹ and R² each independently represent a substituent, p represents an integer of 0 to 3, q represents an integer of 0 to 4, plural R¹'s, plural R²'s, and R¹ and R² may bond to each other to form a ring structure, and * indicates a bonding position to L¹ or L²; and the structural unit (B) is represented by the following general formula (B-1):

Ar^{B} (B-1)

wherein Ar^{B} represents a substituted or unsubstituted arylene group having 6 to 60 ring carbon atoms, or a substituted or unsubstituted heteroarylene group having 5 to 60 ring atoms.
[2] A material for organic electroluminescence devices, containing the high-molecular compound described in the above [1].
[3] An organic electroluminescence device including a cathode, an anode and an organic thin-film layer formed of one layer or plural layers sandwiched between the cathode and the anode, wherein:

the organic thin-film layer contains a light emitting layer, and

at least one layer of the organic thin-film layer contains the high-molecular compound described in the above [1].

[4] An electronic device equipped with the organic electroluminescence device described in the above [3].

### Advantageous Effects of Invention

A long lifetime organic EL device can be prepared by using the high-molecular compound of one aspect of the present invention as a material for organic EL devices.

### BRIEF DESCRIPTION OF DRAWING

FIG. 1 is a view showing a schematic configuration of an organic EL device according to an aspect of the present invention.

### DESCRIPTION OF EMBODIMENTS

In this description, the “XX to YY carbon atoms” in an expression “a substituted or unsubstituted ZZ group having XX to YY carbon atoms” refer to the number of the carbon atoms of the unsubstituted ZZ group, and when the ZZ group has a substituent, the carbon atoms of the substituent are not included. Here, “YY” is larger than “XX”, and “XX” and “YY” each mean an integer of 1 or more.

Also in this description, the “XX to YY atoms” in an expression “a substituted or unsubstituted ZZ group having XX to YY atoms” refer to the number of the atoms of the unsubstituted ZZ group, and when the ZZ group has a substituent, the atoms of the substituent are not included. Here, “YY” is larger than “XX”, and “XX” and “YY” each mean an integer of 1 or more.

In this description, the number of the ring carbon atoms refers to the number of the carbon atoms of the atoms constituting the ring itself of a compound having a structure in which the atoms combine and form a ring (for example, a monocyclic compound, a condensed ring compound, a cross-linked compound, a carbocyclic compound or a heterocyclic compound). When the ring has a substituent, the carbon atoms contained in the substituent are not counted as the ring carbon atoms. The term “the number of the ring carbon atoms” used below is the same unless otherwise noted. For example, a benzene ring has six ring carbon atoms, and a naphthalene ring has 10 ring carbon atoms. A pyridinyl group has five ring carbon atoms, and a furanyl group has four ring carbon atoms. When a benzene ring or a naphthalene ring has an alkyl group as a substituent for example, the carbon atoms of the alkyl group are not counted as the ring carbon atoms. Also, when a fluorene ring is bonded to another fluorene ring as a substituent for example (including a spirofluorene ring), the carbon atoms of the fluorene ring as the substituent are not counted as the ring carbon atoms.

In this description, the number of the ring atoms refers to the number of the atoms constituting the ring itself of a compound having a structure in which the atoms combine and form a ring (for example a monocycle, a condensed ring or a ring assembly) (for example, the compound is a monocyclic compound, a condensed ring compound, a cross-linked compound, a carbocyclic compound or a heterocyclic compound). The atoms which do not constitute the ring (for example, a hydrogen atom which terminates a binding site of an atom constituting the ring) and the atoms contained in a substituent which the ring has, if any, are not counted as the ring atoms. The term “the number of the ring atoms” used below is the same unless otherwise noted. For example, a pyridine ring has six ring atoms, and a quinazoline ring has 10 ring atoms. A furan ring has five ring atoms. The hydrogen atoms bonded to the carbon atoms of a pyridine ring or a quinazoline ring and the atoms constituting a substituent are not counted as the ring atoms. When a fluorene ring is bonded to another fluorene ring as a substituent for example (including a spirofluorene ring), the atoms of the fluorene ring as the substituent are not counted as the ring atoms.

In this description, the term “hydrogen atom” includes isotopes with a different number of neutrons, namely protium, deuterium and tritium.

In this description, the “heteroaryl group” and the “heteroarylene group” each are a group containing at least one hetero atom as a ring atom.

The hetero atom is preferably one or more selected from an oxygen atom, a sulfur atom, a nitrogen atom, a silicon atom, a phosphorus atom, a lead atom, a bismuth atom, a selenium atom, a tellurium atom, and a boron atom, and is more preferably one or more selected from a nitrogen atom, an oxygen atom, a sulfur atom and a silicon atom.

In this description, the “substituted or unsubstituted carbazolyl group” includes the following carbazolyl groups:

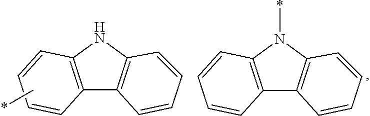

and substituted carbazolyl groups corresponding to the above-mentioned groups and additionally having any arbitrary substituent. In the above formulae, * indicates a bonding position.

In the substituted carbazolyl group, any arbitrary substituents may bond to each other to form a condensed ring, or may contain a hetero atom such as a nitrogen atom, an oxygen atom, a silicon atom, a selenium atom and the like, and the bonding position may be any of 1- to 9-positions.

Specific examples of such substituted carbazolyl groups include the following groups.

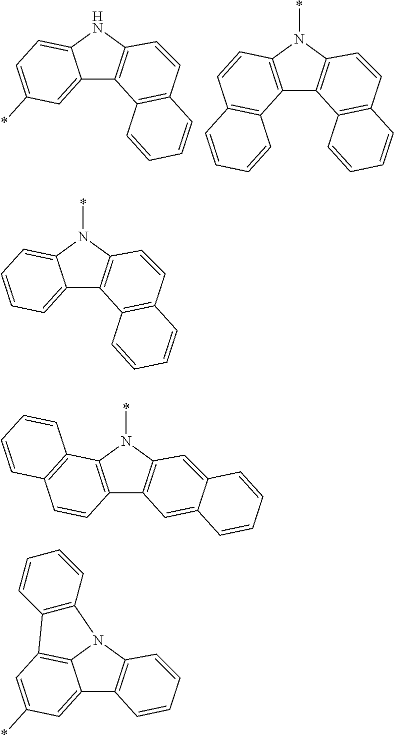

wherein * indicates a bonding position.

In this description, the “substituted or unsubstituted dibenzofuranyl group” and the “substituted or unsubstituted dibenzothiophenyl group” includes the following dibenzofuranyl group and dibenzothiophenyl group:

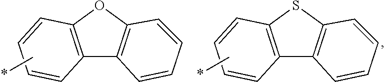

and substituted dibenzofuranyl groups and substituted dibenzothiophenyl groups corresponding to the above-mentioned groups and additionally having any arbitrary substituent. In the above formulae, * indicates a bonding position.

In the substituted dibenzofuranyl group and the substituted dibenzothiophenyl group, any arbitrary substituents may bond to each other to form a condensed ring, or may contain a hetero atom such as a nitrogen atom, an oxygen atom, a silicon atom, a selenium atom and the like, and the bonding position may be any of 1- to 8-positions.

Specific examples of such substituted dibenzofuranyl groups and substituted dibenzothiophenyl groups include the following groups.

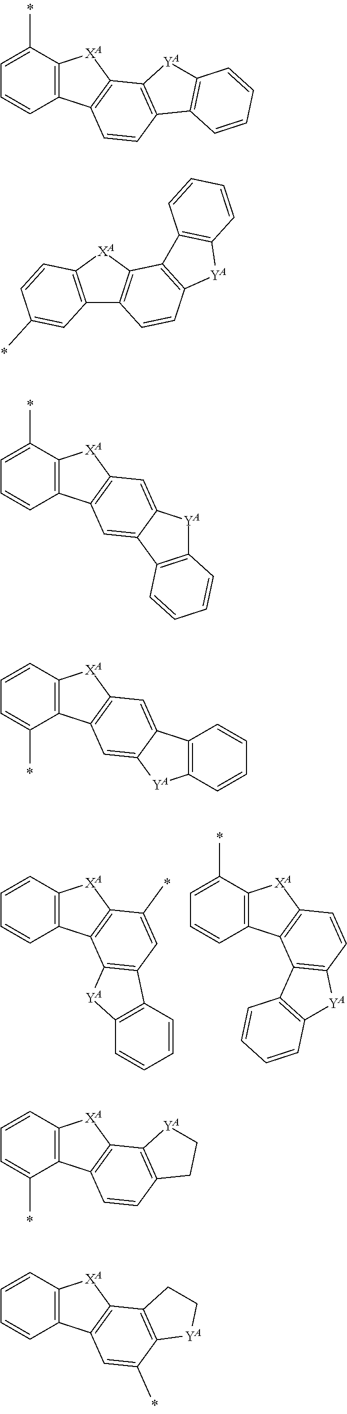

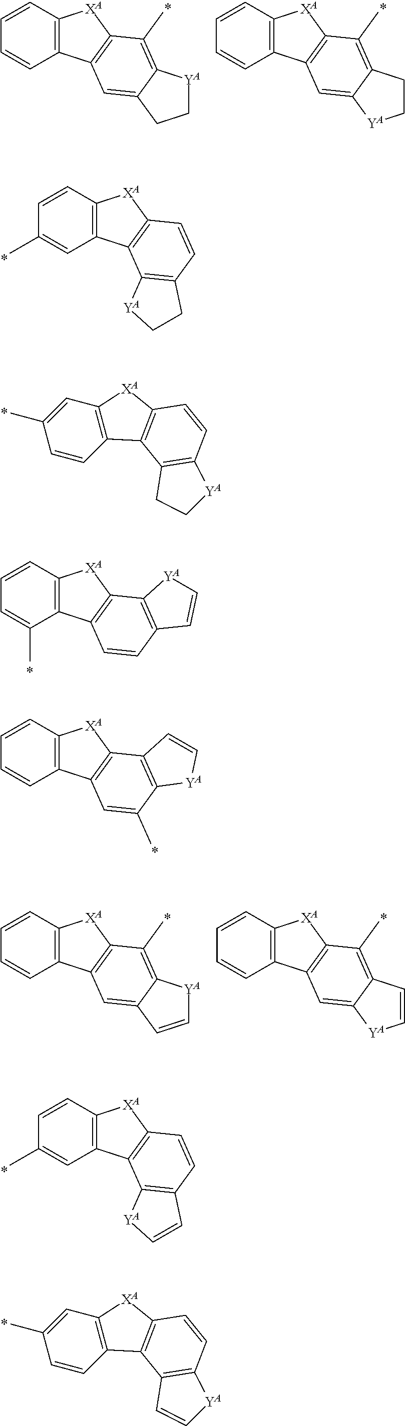

In the formulae, X^{A} represents an oxygen atom or a sulfur atom, Y^{A} represents an oxygen atom, a sulfur atom, —NH—, —NR^{α}—, —CH₂—, or —CR^{α}R^{β}—, and R^{α} and R^{β} each independently represent an alkyl group or an aryl group.

The “substituent” or the substituent referred to by the term “substituted or unsubstituted” is preferably one selected from the group consisting of: an alkyl group having 1 to 50 (preferably 1 to 18, more preferably 1 to 8, and even more preferably 1 to 4) carbon atoms; a cycloalkyl group having 3 to 50 (preferably 3 to 10, more preferably 3 to 8, and still more preferably 5 or 6) ring carbon atoms; an aryl group having 6 to 60 (preferably 6 to 25, and more preferably 6 to 18) ring carbon atoms; an aralkyl group having 7 to 51 (preferably 7 to 30, and more preferably 7 to 20) carbon atoms which has an aryl group having 6 to 60 (preferably 6 to 25, and more preferably 6 to 18) ring carbon atoms; an alkoxy group which has an alkyl group having 1 to 50 (preferably 1 to 18, and preferably 1 to 8, and even more preferably 1 to 4) carbon atoms; an aryloxy group which has an aryl group having 6 to 60 (preferably 6 to 25, and more preferably 6 to 18) ring carbon atoms; an arylthio group which has an aryl group having 6 to 60 (preferably 6 to 25, and more preferably 6 to 18) ring carbon atoms; a mono-substituted, di-substituted or tri-substituted silyl group having a substituent selected from an alkyl group having 1 to 50 (preferably 1 to 18, more preferably 1 to 8, and even more preferably 1 to 4) carbon atoms and an aryl group having 6 to 60 (preferably 6 to 25, and more preferably 6 to 18) ring carbon atoms; a heteroaryl group having 5 to 60 (preferably 5 to 24, and more preferably 5 to 13) ring atoms; a haloalkyl group having 1 to 50 (preferably 1 to 18, more preferably 1 to 8, and even more preferably 1 to 4) carbon atoms; a halogen atom (a fluorine atom, a chlorine atom, a bromine atom or an iodine atom); a cyano group; a nitro group; a sulfonyl group having a substituent selected from an alkyl group having 1 to 50 (preferably 1 to 18, more preferably 1 to 8, and even more preferably 1 to 4) carbon atoms and an aryl group having 6 to 60 (preferably 6 to 25, and more preferably 6 to 18) ring carbon atoms; a disubstituted phosphoryl group having substituents selected from an alkyl group having 1 to 50 (preferably 1 to 18, more preferably 1 to 8, and even more preferably 1 to 4) carbon atoms and an aryl group having 6 to 60 (preferably 6 to 25, and more preferably 6 to 18) ring carbon atoms; an alkylsulfonyloxy group which has an alkyl group having 1 to 50 (preferably 1 to 18, more preferably 1 to 8, and even more preferably 1 to 4) carbon atoms; an arylsulfonyloxy group which has an aryl group having 6 to 60 (preferably 6 to 25, and more preferably 6 to 18) ring carbon atoms; an alkylcarbonyloxy group which has an alkyl group having 1 to 50 (preferably 1 to 18, more preferably 1 to 8, and even more preferably 1 to 4) carbon atoms; an arylcarbonyloxy group which has an aryl group having 6 to 60 (preferably 6 to 25, and more preferably 6 to 18) ring carbon atoms; a boron-containing group; a zinc-containing group; a tin-containing group; a silicon-containing group; a magnesium-containing group; a lithium-containing group; a hydroxy group; an alkyl-substituted or aryl-substituted carbonyl group; a carboxy group; a vinyl group; a (meth)acryloyl group; an epoxy group; and an oxetanyl group.

These substituents may further have any of the optional substituents above. Also, a plurality of these substituents may combine to form a ring.

“Unsubstituted” in the expression of “substituted or unsubstituted” means that the group is not substituted with any such substituents and a hydrogen atom bonds thereto.

In one aspect of the present invention, the “substituent” or the substituent referred to by the term “substituted or unsubstituted” is preferably one selected from the group consisting of an alkyl group having 1 to 50 (preferably 1 to 18, more preferably 1 to 8, and even more preferably 1 to 4) carbon atoms, a cycloalkyl group having 3 to 50 (preferably 3 to 10, more preferably 3 to 8, and even more preferably 5 or 6) ring carbon atoms, an aryl group having 6 to 60 (preferably 6 to 25, and more preferably 6 to 18) ring carbon atoms, an alkoxy group which has an alkyl group having 1 to 50 (preferably 1 to 18, more preferably 1 to 8, and even more preferably 1 to 4) carbon atoms, an aryloxy group which has an aryl group having 6 to 60 (preferably 6 to 25, and more preferably 6 to 18) ring carbon atoms, an arylthio group which has an aryl group having 6 to 60 (preferably 6 to 25, and more preferably 6 to 18) ring carbon atoms, a heteroaryl group having 5 to 60 (preferably 5 to 24, and more preferably 5 to 13) ring atoms, an alkylcarbonyloxy group which has an alkyl group having 1 to 50 (preferably 1 to 18, more preferably 1 to 8, and even more preferably 1 to 4) carbon atoms, a halogen atom (fluorine atom, chlorine atom, bromine atom, iodine atom), a cyano group, a nitro group, a hydroxy group, and a carboxy group.

Further, the substituent is even more preferably an alkyl group having 1 to 50 (preferably 1 to 18, more preferably 1 to 8, and even more preferably 1 to 4) carbon atoms, an aryl group having 6 to 60 (preferably 6 to 25, and more preferably 6 to 18) ring carbon atoms, or a halogen atom (fluorine atom, chlorine atom, bromine atom, iodine atom).

In this description, the preferred prescription may be selected in any arbitrary manner, and a combination of preferred prescriptions can be said to be more preferred.

### [High-Molecular Compound]

The high-molecular compound of one aspect of the present invention has a structural unit (A) represented by the general formula (A-1) and a structural unit (B) represented by the general formula (B-1). The structural unit (A) and the structural unit (B) each have a different structure.

Having the structural unit (A), reorientation energy of the high-molecular compound of one aspect of the present invention, which relates to charge transportation performance, can be made small, and therefore it is considered that when the high-molecular compound is used as an organic EL device material, the charge transportation performance thereof can be thereby enhanced.

Consequently, the high-molecular compound of one aspect of the present invention is useful as a material for organic electroluminescence devices.

In addition, having the structural unit (B), the high-molecular compound can have good solubility in solvent.

Regarding the morphology thereof, the high-molecular compound of one aspect of the present invention may be an alternating copolymer where the structural unit (A) and the structural unit (B) bond alternately to each other, or a random copolymer where the structural unit (A) and the structural unit (B) bond randomly to each other, or a block copolymer where one of the structural units (A) and (B) bonds continuously and then the other structural unit bonds continuously.

In the high-molecular compound of one aspect of the present invention, the ratio of the molar fraction of the structural unit (A) to the molar fraction of the structural unit (B) [(A)/(B)] is preferably 30/70 to 90/10, more preferably 35/65 to 80/20, even more preferably 40/60 to 70/30, and still more preferably 45/55 to 60/40.

The high-molecular compound of one aspect of the present invention may have any other structural unit than the structural unit (A) and the structural unit (B).

In one aspect of the present invention, the total content of the structural unit (A) and the structural unit (B) is preferably 70 to 100 mol % relative to 100 mol % of all the structural units of the high-molecular compound, more preferably 80 to 100 mol %, even more preferably 90 to 100 mol %, and still more preferably 95 to 100 mol %.

The weight average molecular weight (Mw) of the high-molecular compound of one aspect of the present invention is, from the viewpoint of bettering the film quality of an organic thin-film layer containing the high-molecular compound and from the viewpoint of bettering the solubility of the high-molecular compound in solvent, preferably 1×10³ to 1×10⁸, and more preferably 1×10³ to 1×10⁶.

The molecular weight distribution (Mw/Mn (Mn: number average molecular weight)) of the high-molecular compound of one aspect of the present invention is preferably 10 or less, and more preferably 5 or less.

Examples of the solvent for use in forming a film of the high-molecular compound of one aspect of the present invention include chlorine-containing solvents such as chloroform, methylene chloride, 1,2-dichloroethane, etc.; ether solvents such as dibutyl ether, tetrahydrofuran, dioxane, etc.; aromatic solvents such as toluene, xylene, mesitylene, tetralin, n-butylbenzene, etc.

One alone or two or more kinds of these solvents may be used either singly or as combined.

### <Regarding Structural Unit (A)>

The structural unit (A) that the high-molecular compound of one aspect of the present invention has is represented by the following general formula (A-1).

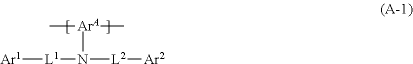

The content of the structural unit (A) is, from the viewpoint of providing an organic EL device material having improved charge transportation performance, preferably 30 mol % or more relative to 100 mol % of all the structural units of the high-molecular compound, more preferably 35 mol % or more, even more preferably 40 mol % or more, and still more preferably 45 mol % or more, and is, from the viewpoint of securing the content of the structural unit (B) to provide a high-molecular compound having good solubility in solvent, preferably 90 mol % or less, more preferably 80 mol % or less, even more preferably 70 mol % or less, still more preferably 60 mol % or less.

The high-molecular compound of one aspect of the present invention may have one kind alone of the structural unit (A), or may have two or more kinds of the structural units (A).

Ar^{A}, L¹ and L², Ar¹ and Are in the general formula (A-1) are described below.

### <Structural Unit (A): Regarding Ar^{A} in General Formula (A-1)>

In the above general formula (A-1), Ar^{A} represents a linking group having a fluorene skeleton. The linking group includes a group having a substituent bonding to the carbon atom of the fluorene skeleton.

Examples of the linking group having such a fluorene skeleton include a trivalent residue of the following compounds. The hydrogen atom bonding to the carbon atom in these groups may be substituted with any of the above-mentioned substituents.

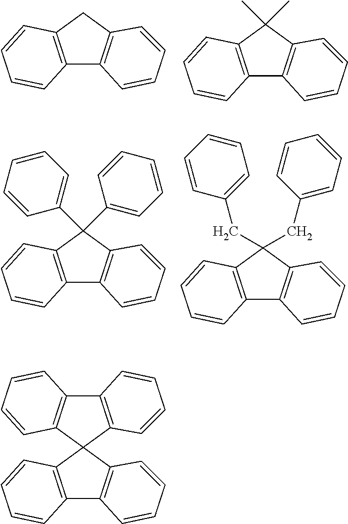

As one aspect of the present invention, Ar^{A} is preferably a linking group represented by the following general formula (A-1a).

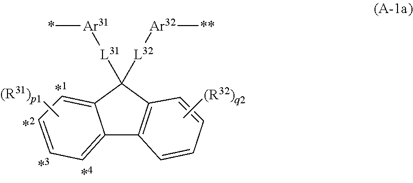

In the above general formula (A-1a), one carbon atom selected from *1 to *4 bonds to the nitrogen atom that the amino group in the general formula (A-1) has. * and ** each represent a bonding position to the other structural unit.

L³¹ and L³² each independently represent a single bond, or a substituted or unsubstituted alkylene group having 1 to 50 (preferably 1 to 18, more preferably 1 to 8, even more preferably 1 to 4, and still more preferably 1 to 2) carbon atoms.

Examples of the alkylene group include a methylene group, an ethylene group, a propylene group, a trimethylene group, a butylene group, a tetramethylene group, a pentamethylene group, a hexamethylene group, a heptamethylene group, a nonamethylene group, a decamethylene group, an undecamethylene group, a dodecamethylene group, etc.

Ar³¹ and Ar³² each independently represent a single bond, a substituted or unsubstituted arylene group having 6 to 60 (preferably 6 to 25, more preferably 6 to 18, and even more preferably 6 to 13) ring carbon atoms, or a substituted or unsubstituted heteroarylene group having 5 to 60 (preferably 5 to 24, and more preferably 5 to 13) ring atoms.

In one aspect of the present invention, Ar³¹ and Ar³² each are preferably a single bond, or a substituted or unsubstituted arylene group having 6 to 60 (preferably 6 to 25, more preferably 6 to 18, and even more preferably 6 to 13) ring carbon atoms.

R³¹ and R³² each independently represent a substituent, bonding to the carbon atom of the benzene ring in the above-mentioned general formula (A-1a). In the case where p1 and q2 are 0, each benzene ring is unsubstituted.

p1 represents an integer of 0 to 3, preferably an integer of 0 to 2, more preferably an integer of 0 to 1, and even more preferably 0.

q2 represents an integer of 0 to 4, preferably an integer of 0 to 2, more preferably an integer of 0 to 1, and even more preferably 0.

Plural R³¹'s, plural R³²'s, and R³⁴ and R³² may bond to each other to form a ring structure.

Preferably, Ar^{A} is a linking group represented by the following general formula (A-1b).

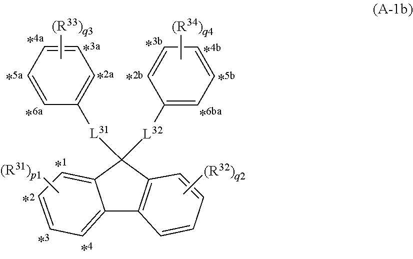

In the general formula (A-1b), one carbon atom selected from *1 to *4 bonds to the nitrogen atom that the amino group in the general formula (A-1) has.

One carbon atom selected from *2a to *6a, and one carbon atom selected from *2b to *6b bond to the other structural unit to form a high-molecular chain.

L³¹, L³², R³¹, R³², p1 and q2 in the general formula (A-1b) have the same definitions as in the general formula (A-1a), and preferred embodiments thereof are also the same as therein.

R³³ and R³⁴ each independently represent a substituent, bonding to the carbon atom of the benzene ring in the general formula (A-1b). In the case where q3 and q4 are 0, the benzene ring is unsubstituted.

q3 and q4 each independently represent an integer of 0 to 4, preferably an integer of 0 to 2, more preferably an integer of 0 to 1, and even more preferably 0.

Plural R³³'s, plural R³⁴'s, and R³³ and R³⁴ may bond to each other to form a ring structure. For example, the linking group where one R³³ and one R³⁴ bond to each other to form a ring structure is a linking group represented by the following general formula (A-1b′).

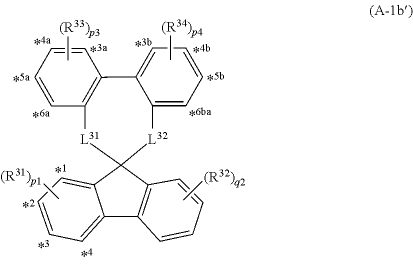

In the general formula (A-1b′), one carbon atom selected from *1 to *4 bonds to the nitrogen atom that the amino group in the general formula (A-1) has.

One carbon atom selected from *3a to *6a, and one carbon atom selected from *3b to *6b bond to the other structural unit to form a high-molecular chain. Preferably, the carbon atom of *5a and the carbon atom of *5b bond to the other structural unit to form a high-molecular chain.

L³¹, L³², R³¹ to R³⁴, p1 and q2 have the same definitions as in the general formula (A-1b), and preferred embodiments thereof are the same as therein.

p3 and p4 each independently represent an integer of 0 to 3, preferably an integer of 0 to 2, more preferably an integer of 0 to 1, and even more preferably 0.

Further, Ar^{A} is more preferably a linking group represented by the following general formula (A-1c), (A-1d) or (A-1e), and is even more preferably a linking group represented by the following general formula (A-1c) or (A-1e).

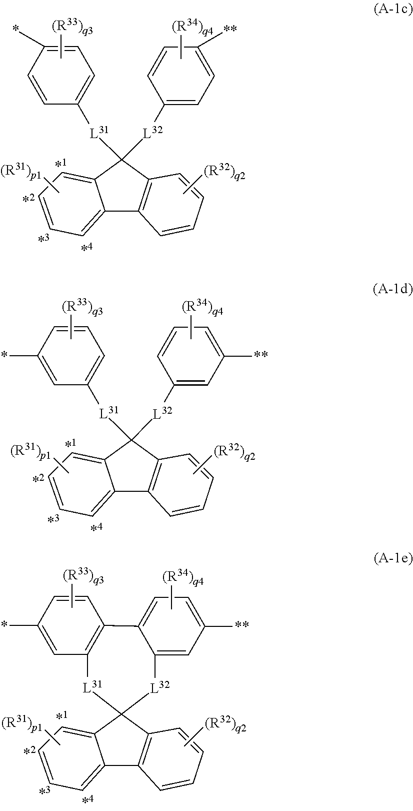

In the above general formulae (A-1c), (A-1d) and (A-1e), one carbon atom selected from *1 to *4 bonds to the nitrogen atom that the amino group in the general formula (A-1) has. * and ** each indicate a bonding position to the other structural unit.

L³¹, L³², R³¹ to R³⁴, p1, and q2 to q4 have the same definitions as in the general formula (A-1a) or (A-1b), and preferred embodiments thereof are also the same as therein.

p3 and p4 each independently represent an integer of 0 to 3, preferably an integer of 0 to 2, more preferably an integer of 0 to 1, and even more preferably 0.

<Structural Unit (A): Regarding L¹ and L² in General Formula (A-1)>

In the general formula (A-1), L¹ and L² each independently represent a single bond, a substituted or unsubstituted arylene group having 6 to 60 (preferably 6 to 24, more preferably 6 to 18, and even more preferably 6 to 13) ring carbon atoms, or a substituted or unsubstituted heteroarylene group having 5 to 60 (preferably 5 to 24, and more preferably 5 to 13) ring atoms.

In one aspect of the present invention, preferably, L¹ and L² each are independently a single bond, or a substituted or unsubstituted arylene group having 6 to 60 (preferably 6 to 24, more preferably 6 to 18, and even more preferably 6 to 13) ring carbon atoms, and more preferably, each are independently a single bond or a group represented by any of the following general formulae (L-i) and L-ii).

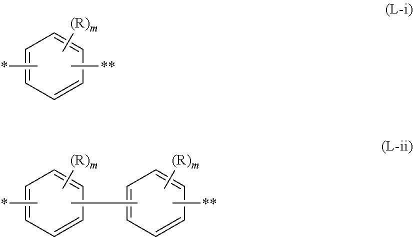

In the general formulae (L-i) and (L-ii), R each independently represent a substituent and bonds to the carbon atom of the benzene ring. When m is 0, each benzene ring is unsubstituted.

m each independently are an integer of 0 to 4, preferably an integer of 0 to 2, more preferably an integer of 0 to 1, and even more preferably 0.

Plural R's, if any, may be the same as or different from each other, and two selected from plural R's may bond to each other to form a ring structure.

* and ** each indicate a bonding position. Specifically, one of * and ** indicates a bonding position to the nitrogen atom in the general formula (A-1), and the other indicates a bonding position to Ar¹ or Ar².

<Structural Unit (A): Regarding Ar¹ and Ar² in General Formula (A-1)>

In the general formula (A-1), Ar¹ and Ar² each independently represent a substituted or unsubstituted aryl group having 6 to 60 (preferably 6 to 24, more preferably 6 to 18, and even more preferably 6 to 13) ring carbon atoms, or a substituted or unsubstituted heteroaryl group having 5 to 60 (preferably 5 to 24, and more preferably 5 to 13) ring atoms.

However, at least one of Ar¹ and Ar² represents a monovalent organic group represented by the following formula (a), and preferably, Ar¹ and Ar² each are independently a monovalent organic group represented by the general formula (a).

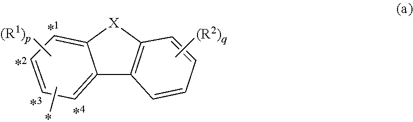

In the general formula (a), X represents —O—, —S—, —N(R^{x})—, —C(R^{x})(R^{y})—, —Si(R^{x})(R^{y})—, —P(R^{x})—, —P(═O)(R^{x})—, or —P(═S)(R^{x})—.

R^{x} and R^{y} each independently represent a hydrogen atom or a substituent, and R^{x} and R^{y} may bond to each other to form a ring structure.

Examples of the monovalent organic group having such a ring structure include organic groups represented by the following formula.

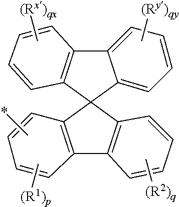

In the formula, R¹, R², p, and q have the same definitions as in the general formula (a), R^{x′} and R^{y′} each independently represent a hydrogen atom or a substituent, qx and qy each independently represent an integer of 0 to 4, preferably an integer of 0 to 2, more preferably an integer of 0 to 1 and even more preferably 0. * indicates a bonding position to L¹ or L².

In one aspect of the present invention, X is preferably —O—, —S—, —N(R^{x})—, —C(R^{x})(R^{y})—, or —Si(R^{x})(R^{y})—, more preferably —O—, —S—, or —N(R^{x})—, and even more preferably —O— or —S—.

The substituent that can be selected for R^{x} and R^{y} includes those mentioned above, and is preferably an alkyl group having 1 to 50 (preferably 1 to 18, more preferably 1 to 8, and even more preferably 1 to 4) carbon atoms, or an aryl group having 6 to 60 (preferably 6 to 25, more preferably 6 to 18, and even more preferably 6 to 13) ring carbon atoms.

R¹ and R² each independently represent a substituent, bonding to the carbon atom of the benzene ring in the general formula (a). When p and q are 0, the benzene ring is unsubstituted.

p represents an integer of 0 to 3, preferably an integer of 0 to 2, more preferably an integer of 0 to 1, and even more preferably 0.

q represents an integer of 0 to 4, preferably an integer of 0 to 2, more preferably an integer of 0 to 1, and even more preferably 0.

Plural R¹'s, plural R²'s, and R¹ and R² each may bond to each other to form a ring structure.

* indicates a bonding position to L¹ or L². Specifically, one carbon atom selected from *1 to *4 bond to L¹ or L².

Regarding the bonding position to L¹ or L², the substituent preferably bonds to the carbon atom of *1 or *3. Bonding at the position provides a high-molecular compound capable of bettering surface uniformity in film formation with the compound in the form of a solution. An organic EL device having an organic thin-film layer having such good surface uniformity is excellent in emission efficiency and lifetime.

From the above-mentioned viewpoint, in a more preferred aspect of the present invention, at least one of Ar¹ and Ar² is preferably a monovalent organic group represented by the following general formula (a-1) or (a-2).

More preferably, Ar¹ and Ar² each are independently a monovalent organic group represented by the following general formula (a).

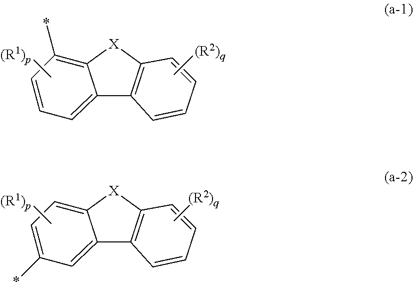

In the above general formulae (a-1) and (a-2), X, R¹, R², p, and q have the same definitions as in the above general formula (a). * indicates a bonding position to L¹ or L².

In a more preferred embodiment of the present invention, at least one of Ar¹ and Ar² is preferably a monovalent organic group represented by the following general formula (a-1-1), (a-1-2), (a-2-1), (a-2-2) or (a-2-3).

Further, more preferably, Ar¹ and Ar² each are independently a monovalent organic group represented by the following general formula (a-1-1), (a-1-2), (a-2-1), (a-2-2) or (a-2-3).

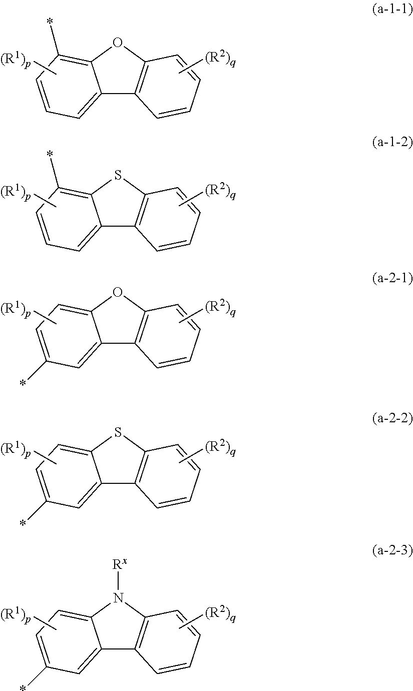

In the above general formulae (a-1-1), (a-1-2), (a-2-1), (a-2-2) and (a-2-3), R¹, R², p, and q have the same definitions as in the general formula (a).

R^{X} represents a hydrogen atom or a substituent. * indicates a bonding position to L¹ or L².

In the case where one of Ar¹ and Ar² is not a monovalent organic group represented by the general formula (a), those Ar¹ and Ar² each are preferably a group represented by any of the following general formulae (Ar-1) to (Ar-6).

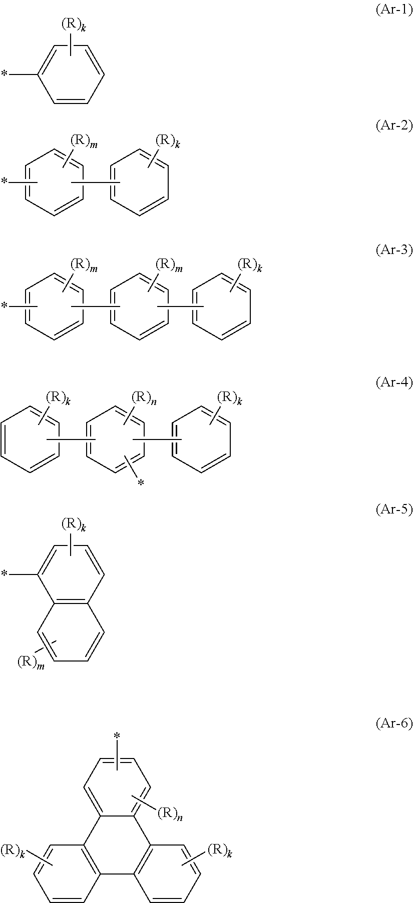

In the above general formulae (Ar-1) to (Ar-6), R each independently represent a substituent, bonding to the carbon atom of the benzene ring. When k, m and n are 0, the benzene ring is unsubstituted.

k each independently represent an integer of 0 to 5, preferably an integer of 0 to 2, more preferably an integer of 0 to 1, and even more preferably 0.

m each independently represent an integer of 0 to 4, preferably an integer of 0 to 2, more preferably an integer of 0 to 1, and even more preferably 0.

n each independently represent an integer of 0 to 3, preferably an integer of 0 to 2, more preferably an integer of 0 to 1, even more preferably 0.

### <Exemplification of Aryl Group>

Examples of the aryl group having 6 to 60 ring carbon atoms, which can be selected for Ar¹ and Ar² in the above-mentioned general formulae include a phenyl group, a naphthylphenyl group, a biphenylyl group, a terphenylyl group, a biphenylenyl group, a naphthyl group, a phenylnaphthyl group, an acenaphthylenyl group, an anthryl group, a benzanthryl group, an aceanthryl group, a phenanthryl group, a benzophenanthryl group, a phenalenyl group, a fluorenyl group, a 9,9-dimethylfluorenyl group, a 7-phenyl-9,9-dimethylfluorenyl group, a pentacenyl group, a picenyl group, a pentaphenyl group, a pyrenyl group, a chrysenyl group, a benzochrysenyl group, an s-indacenyl group, an as-indacenyl group, a fluoranthenyl group, and a perylenyl group, etc.

Among these, a phenyl group, a naphthylphenyl group, a biphenylyl group, a terphenylyl group, a naphthyl group, and a 9,9-dimethylfluorenyl group are preferred, a phenyl group, a biphenylyl group, a naphthyl group and a 9,9-dimethylfluorenyl group are more preferred, and a phenyl group is even more preferred.

### <Exemplification of Arylene Group>

The arylene group having 6 to 60 ring carbon atoms, which can be selected for Ar³¹ and Ar³², L¹ and L² in the above-mentioned general formulae includes a divalent group to be obtained by removing one hydrogen atom from the above-mentioned aryl group having 6 to 60 ring carbon atoms.

Specifically, the arylene group is preferably a terphenyldiyl group (including isomer groups), a biphenyldiyl group (including isomer groups), or a phenylene group (including isomer groups), more preferably a biphenyldiyl group (including isomer groups), or a phenylene group (including isomer groups), and even more preferably an o-phenylene group, an m-phenylene group or a p-phenylene group.

### <Exemplification of Heteroaryl Group>

The heteroaryl group having 5 to 60 ring atoms, which can be selected for Ar¹ and Ar² in the above-mentioned general formulae contains at least one, preferably 1 to 3, the same or different hetero atoms.

Examples of the heteroaryl group include a pyrrolyl group, a furyl group, a thienyl group, a pyridyl group, a pyridazinyl group, a pyrimidinyl group, a pyrazinyl group, a triazinyl group, an imidazolyl group, an oxazolyl group, a thiazolyl group, a pyrazolyl group, an isoxazolyl group, an isothiazolyl group, an oxadiazolyl group, a thiadiazolyl group, a triazolyl group, an indolyl group, an isoindolyl group, a benzofuranyl group, an isobenzofuranyl group, a benzothiophenyl group, an indolizinyl group, a quinolizinyl group, a quinolyl group, an isoquinolyl group, a cinnolyl group, a phthalazinyl group, a quinazolinyl group, a quinoxalinyl group, a benzimidazolyl group, a benzoxazolyl group, a benzothiazolyl group, an indazolyl group, a benzisoxazolyl group, a benzisothiazolyl group, a dibenzofuranyl group, a dibenzothiophenyl group, a phenanthridinyl group, an acridinyl group, a phenanthrolinyl group, a phenazinyl group, a phenothiazinyl group, a phenoxazinyl group, and a xanthenyl group.

Among these, a furyl group, a thienyl group, a pyridyl group, a pyridazinyl group, a pyrimidinyl group, a pyrazinyl group, a triazinyl group, a benzofuranyl group, a benzothiophenyl group, a dibenzofuranyl group, and a dibenzothiophenyl group are preferred, and a dibenzofuranyl group and a dibenzothiophenyl group are even more preferred.

### <Exemplification of Heteroarylene Group>

The heteroarylene group having 5 to 60 ring atoms, which can be selected for Ar³¹ and Ar³², L¹ and L² in the above-mentioned general formulae contains at least one, preferably 1 to 3, the same or different hetero atoms.

The heteroarylene group includes a divalent group to be obtained by removing one hydrogen atom from the above-mentioned heteroaryl group having 5 to 60 ring carbon atoms.

Specifically, the heteroarylene group is preferably a furylene group, a thienylene group, a pyridylene group, a pyridazinylene group, a pyrimidinylene group, a pyrazinylene group, a triazinylene group, a benzofuranylene group, a benzothiophenylene group, a dibenzofuranylene group, or a dibenzothiophenylene group, and even more preferably a benzofuranylene group, a benzothiophenylene group, a dibenzofuranylene group or a dibenzothiophenylene group.

### Preferred Embodiment of Structural Unit (A)

In the high-molecular compound of one aspect of the present invention, the structural unit (A) is preferably a structural unit (A2) represented by the following general formula (A-2).

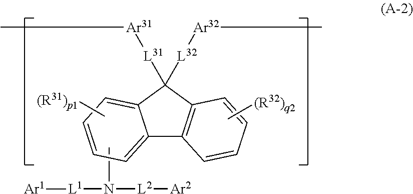

In the general formula (A-2), L¹, L², Ar¹ and Are have the same definitions as in the general formula (A-1), and preferred embodiments thereof are also the same as therein.

L³¹, L³², Ar³¹, Ar³², R³¹, R³², p1, and q2 have the same definitions as in the general formula (A-1a), and preferred embodiments thereof are also the same as therein.

In the high-molecular compound of one aspect of the present invention, the structural unit (A2) is preferably a structural unit (A3) represented by the following general formula (A-3).

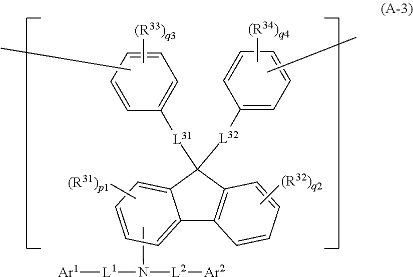

In the above general formula (A-3), L¹, L², Ar¹ and Ar¹ have the same definitions as in the general formula (A-1), and preferred embodiments thereof are also the same as therein.

L³¹, L³², R³¹, R³², p1 and q2 have the same definitions as in the general formula (A-1a), and preferred embodiments thereof are also the same as therein.

Further, R³³, R³⁴, q3, and q4 have the same definitions as in the general formula (A-1b), and preferred embodiments thereof are also the same as therein.

In the high-molecular compound of one aspect of the present invention, the structural unit (A3) is preferably a structural unit (A4a) represented by the following general formula (A-4a), or a structural unit (A4b) represented by the following general formula (A-4 b).

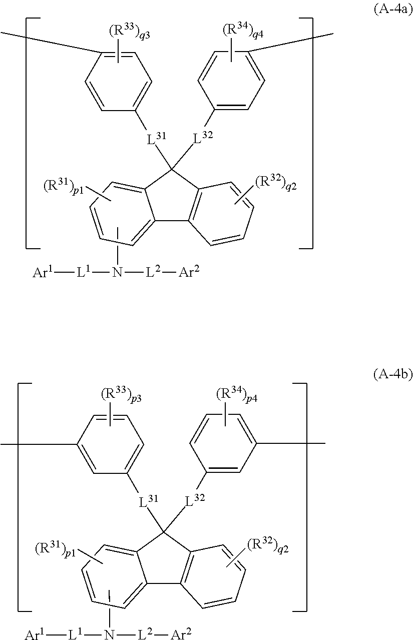

In the above general formulae (A-4a) and (A-4b), L¹, L², Ar¹ and Are have the same definitions as in the general formula (A-1), and preferred embodiments thereof are also the same as therein.

L³¹, L³², R³¹, R³², p1 and q2 have the same definitions as in the general formula (A-1a), and preferred embodiments thereof are also the same as therein.

Further, R³³, R³⁴, q3, and q4 have the same definitions as in the general formula (A-1b), and preferred embodiments thereof are also the same as therein. p3 and p4 each independently represent an integer of 0 to 3, preferably an integer of 0 to 2, more preferably an integer of 0 to 1, and even more preferably 0.

In the high-molecular compound of another aspect of the present invention, the structural unit (A3) is preferably a structural unit (A5a) represented by the following general formula (A-5a), or a structural unit (A5b) represented by the following general formula (A-5b).

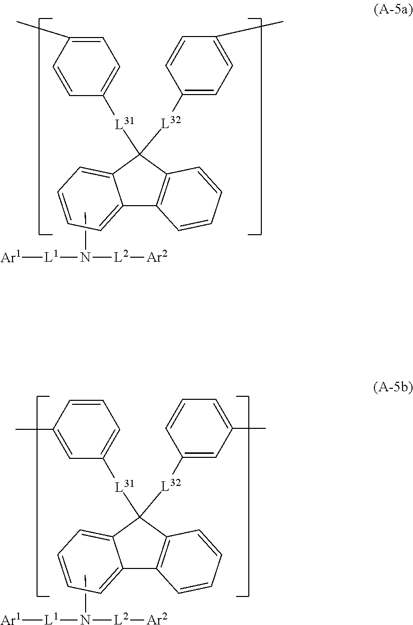

In the above general formulae (A-5a) and (A-5b), L¹, L², Ar¹ and Ar² have the same definitions as in the general formula (A-1), and preferred embodiments thereof are also the same as therein.

L³¹ and L³² have the same definitions as in the general formula (A-1a), and preferred embodiments thereof are also the same as therein.

In the high-molecular compound of another aspect of the present invention, the structural unit (A) is preferably a structural unit (AG) represented by the following general formula (A-6).

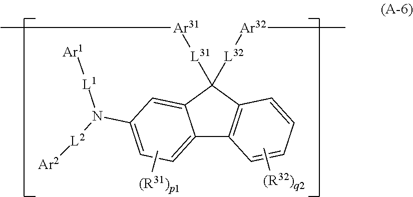

In the above general formula (A-6), L¹, L², Ar¹ and Ar² have the same definitions as in the general formula (A-1), and preferred embodiments thereof are also the same as therein.

L³¹, L³², Ar³¹, Ar³², R³¹, R³², p1, and q2 have the same definitions as in the general formula (A-1a), and preferred embodiments thereof are also the same as therein.

In the high-molecular compound of one aspect of the present invention, the structural unit (A6) is preferably a structural unit (A7) represented by the following general formula (A-7).

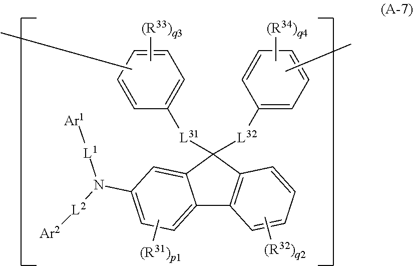

In the above general formula (A-7), L¹, L², Ar¹ and Are have the same definitions as in the general formula (A-1), and preferred embodiments thereof are also the same as therein.

L³¹, L³², R³¹, R³², p1, and q2 have the same definitions as in the general formula (A-1a), and preferred embodiments thereof are also the same as therein.

Further, R³³, R³⁴, q3, and q4 have the same definitions as in the general formula (A-1b), and preferred embodiments thereof are also the same as therein.

Further, in the high-molecular compound of one aspect of the present invention, the structural unit (A7) is preferably a structural unit (A8a) represented by the following general formula (A-8a) or a structural unit (A8b) represented by the following general formula (A-8 b).

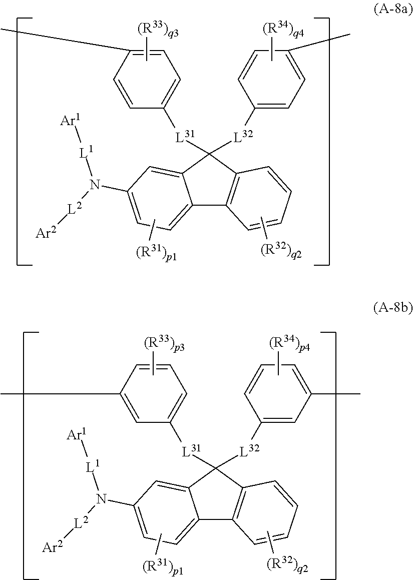

In the above general formulae (A-8a) and (A-8b), L¹, L², Ar¹ and Are have the same definitions as in the general formula (A-1), and preferred embodiments thereof are also the same as therein.

L³¹, L³², R³¹, R³², p1, and q2 have the same definitions as in the general formula (A-1a), and preferred embodiments thereof are also the same as therein.

Further, R³³, R³⁴, q3, and q4 have the same definitions as in the general formula (A-1b), and preferred embodiments thereof are also the same as therein. p3 and p4 each independently represent an integer of 0 to 3, preferably an integer of 0 to 2, more preferably an integer of 0 to 1, and even more preferably 0.

Further, in the high-molecular compound of another aspect of the present invention, the structural unit (A7) is preferably a structural unit (A9a) represented by the following general formula (A-9a) or a structural unit (A9b) represented by the following general formula (A-9b).

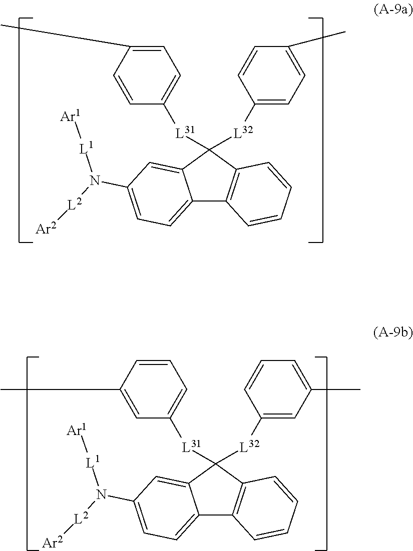

In the above general formulae (A-9a) and (A-9b), L¹, L², Ar¹ and Ar² have the same definitions as in the general formula (A-1), and preferred embodiments thereof are also the same as therein.

L³¹ and L³² have the same definitions as in the general formula (A-1a), and preferred embodiments thereof are also the same as therein.

### Examples of Structure of Structural Unit (A)

As examples of the structure of the structural unit (A) that the high-molecular compound of one aspect of the present invention has, structural units (A1) to (A96) are shown below, but the structure of the structural unit (A) is not limited thereto. In the formulae, * indicates a bonding position to the other structural unit. The hydrogen atom bonding to the carbon atom in the following structures may be substituted with any of the above-mentioned substituents.

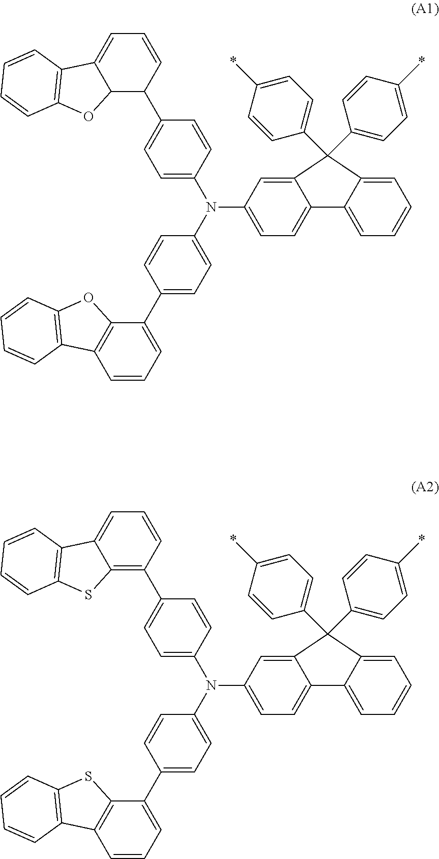

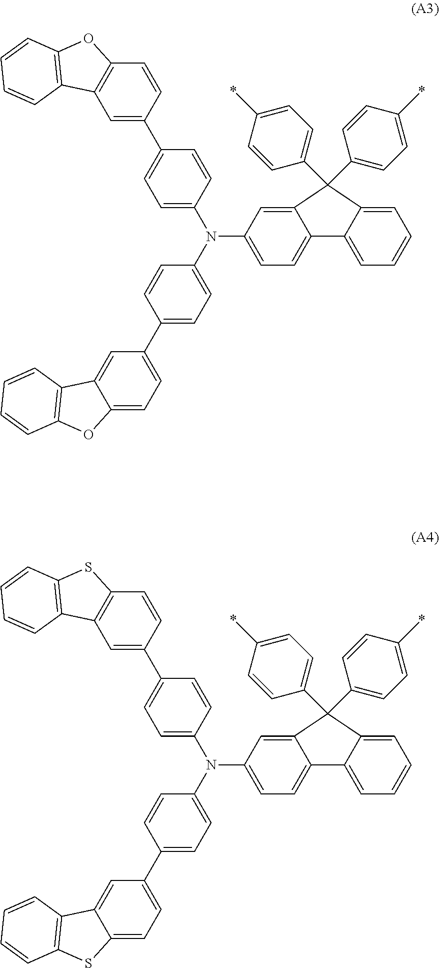

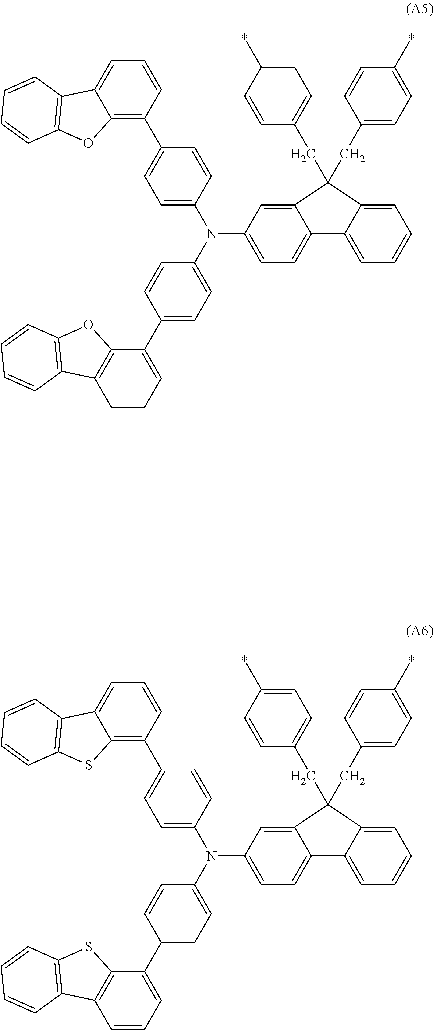

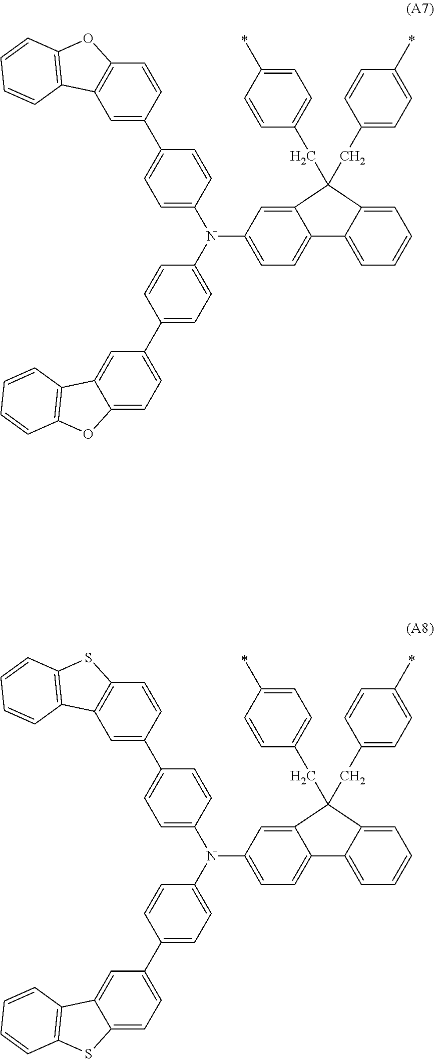

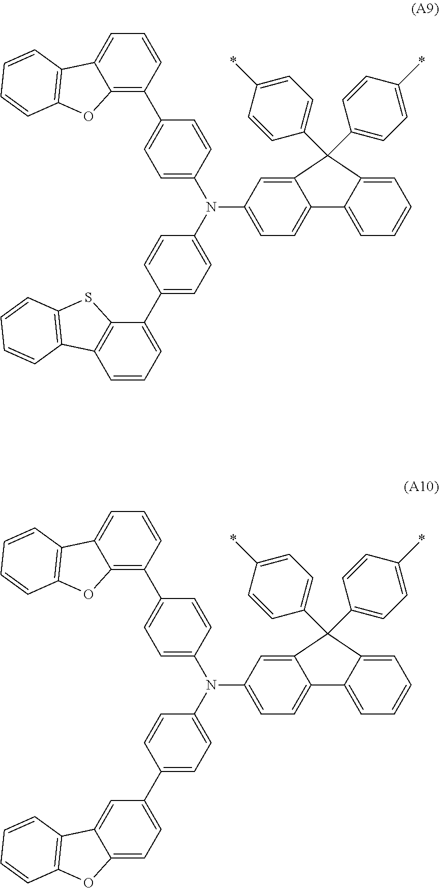

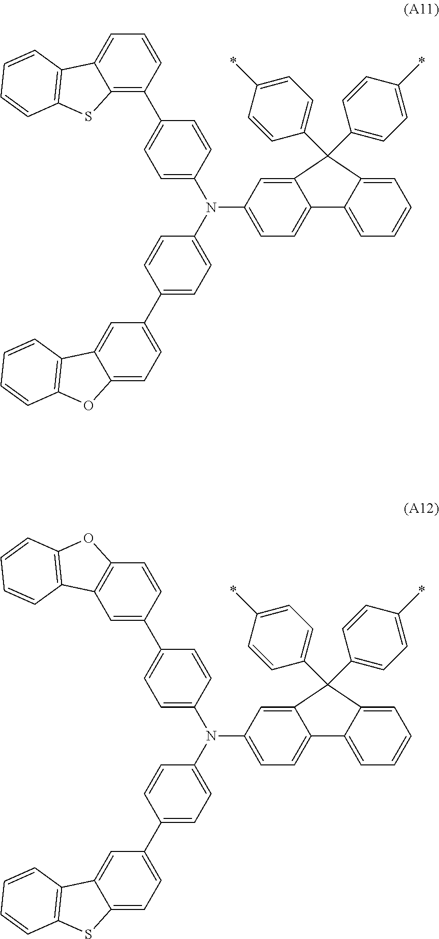

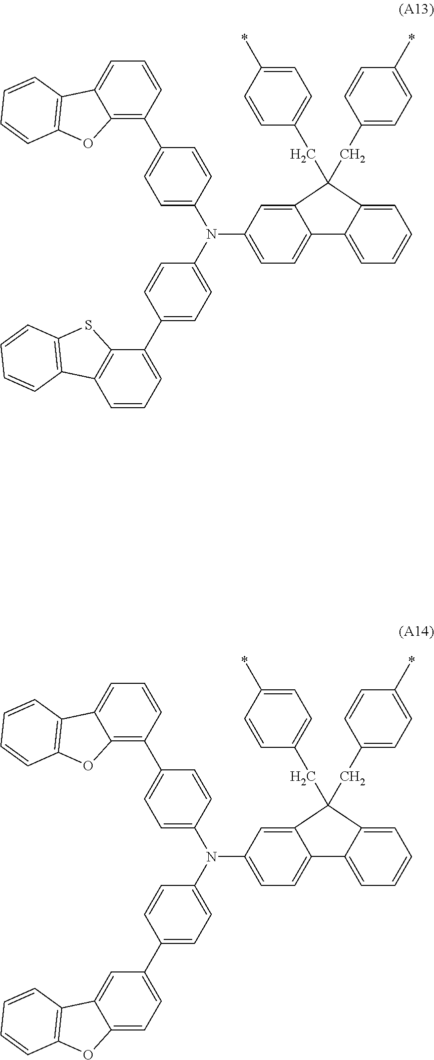

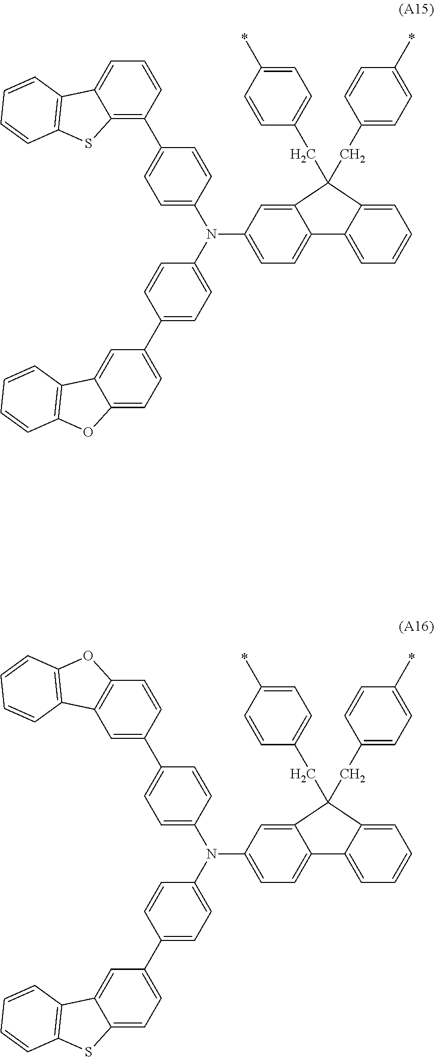

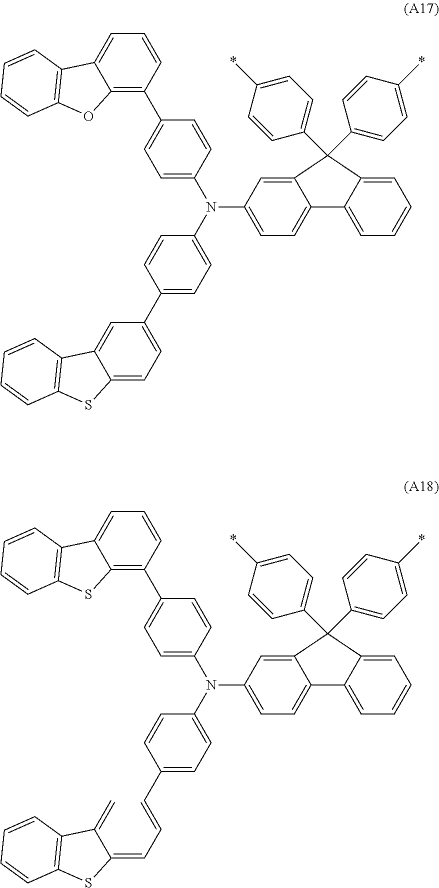

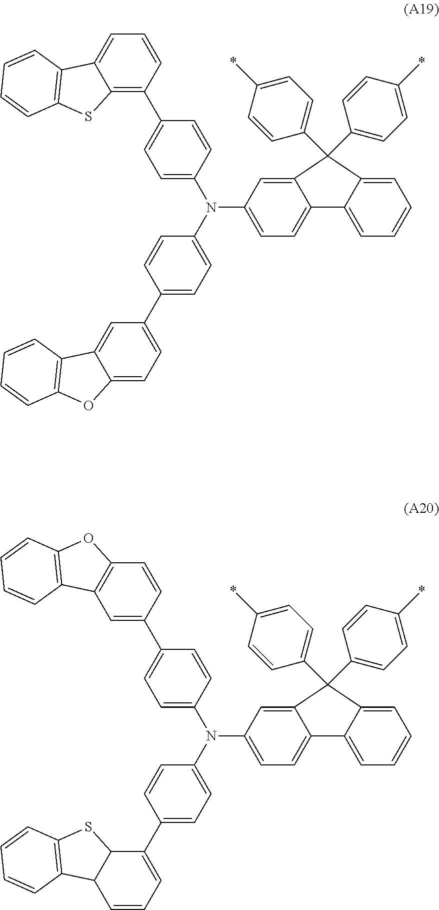

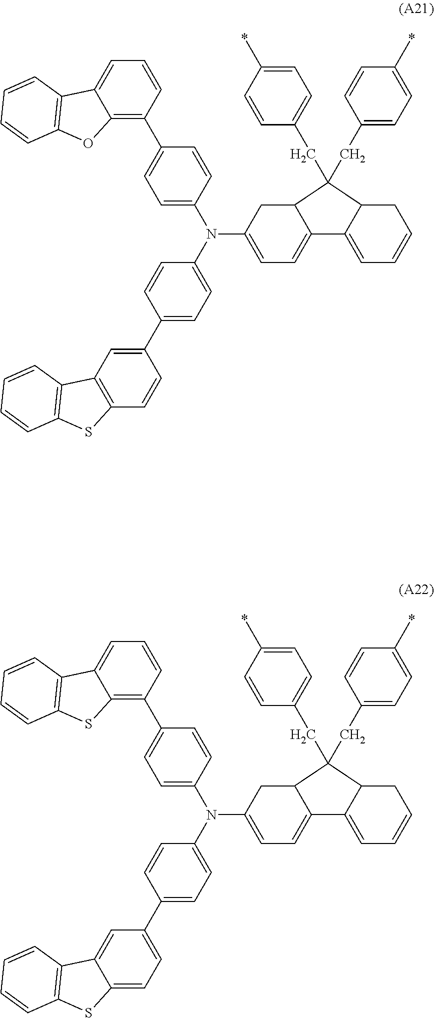

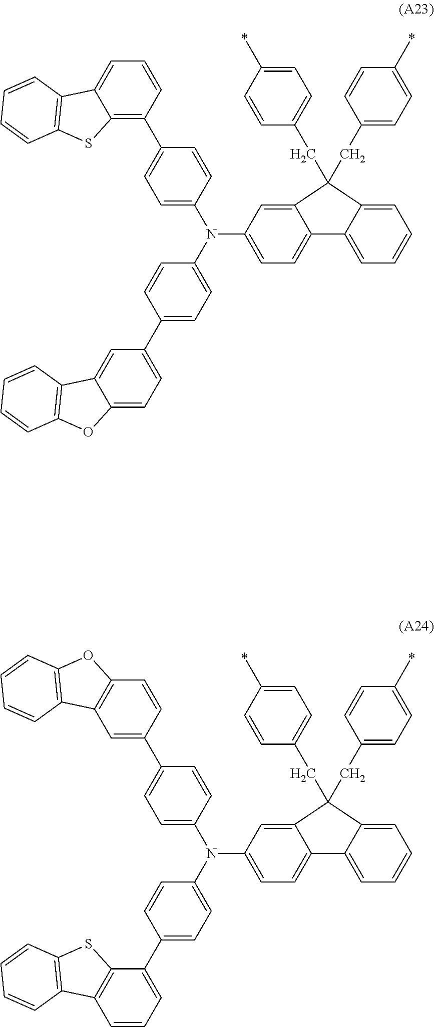

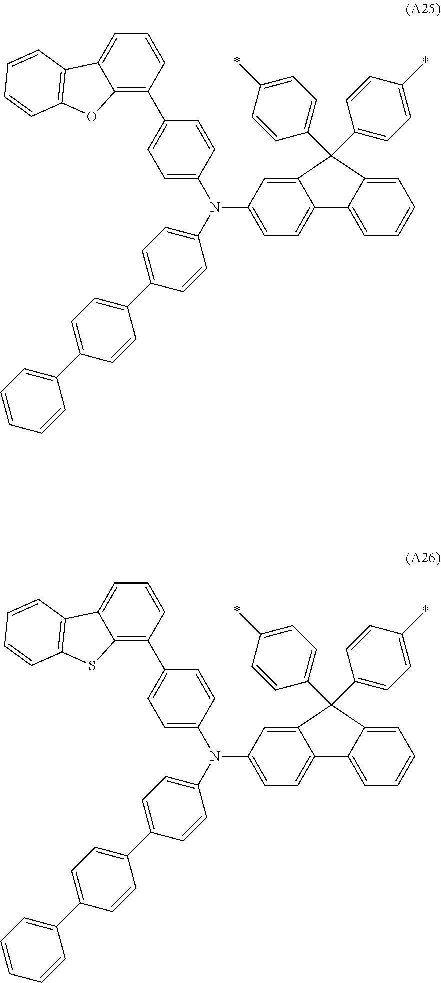

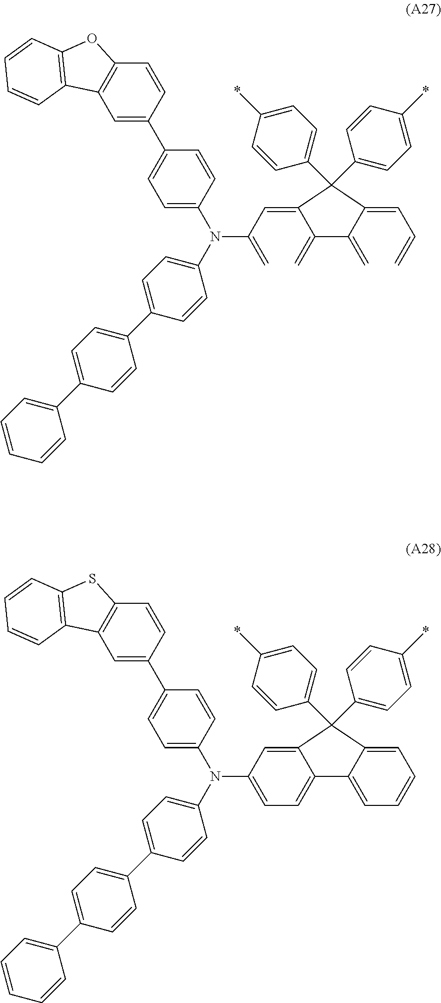

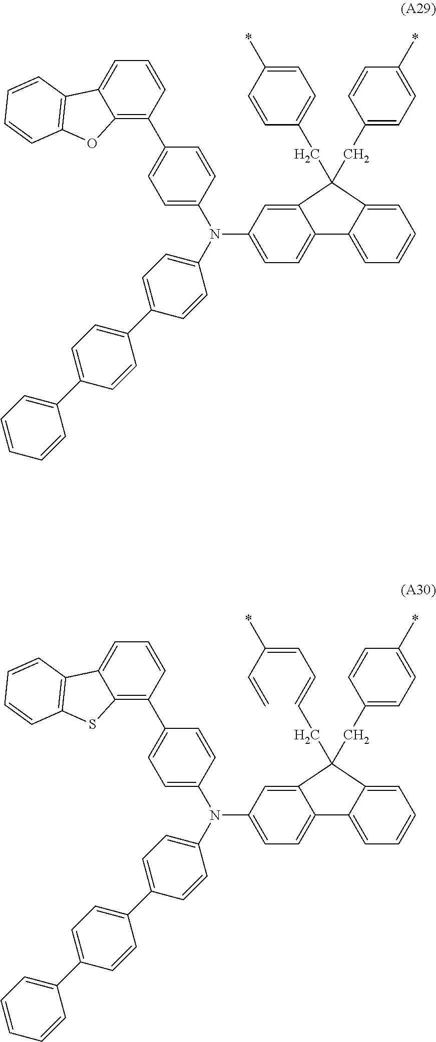

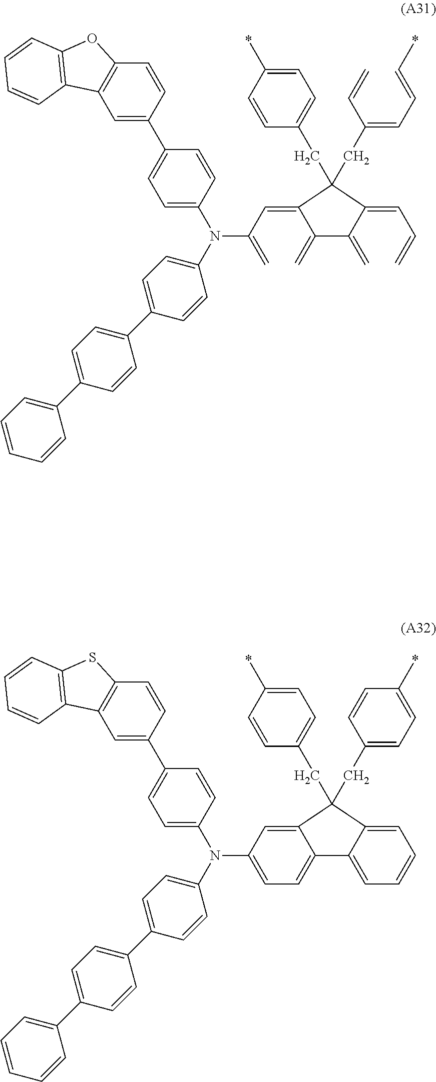

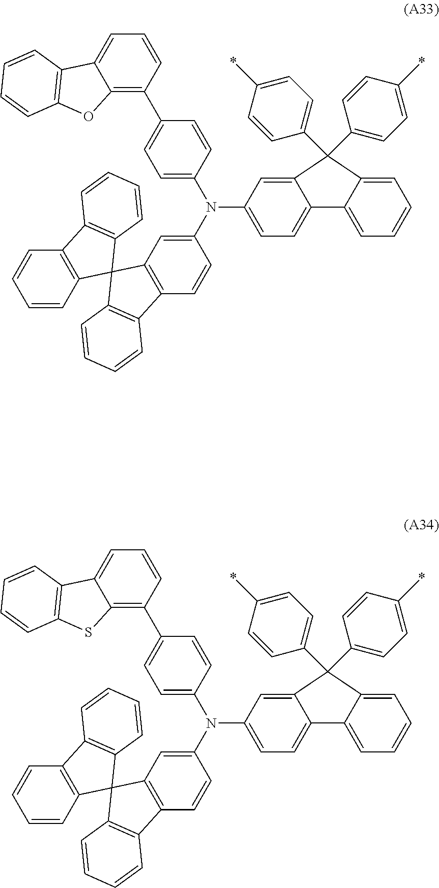

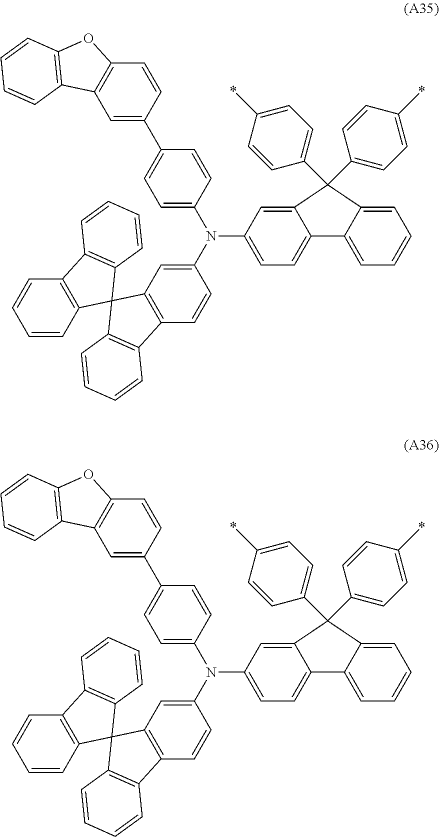

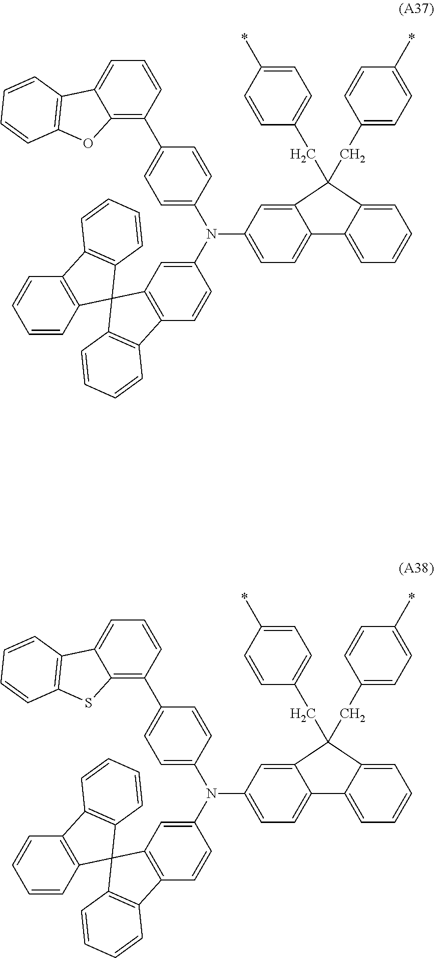

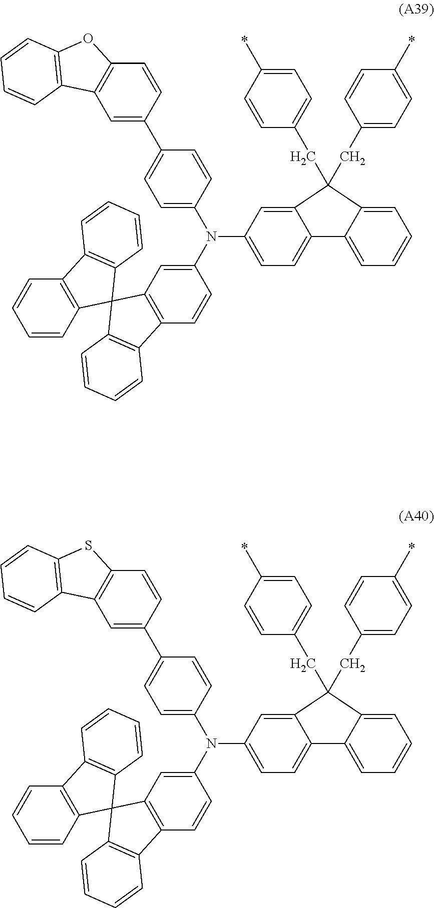

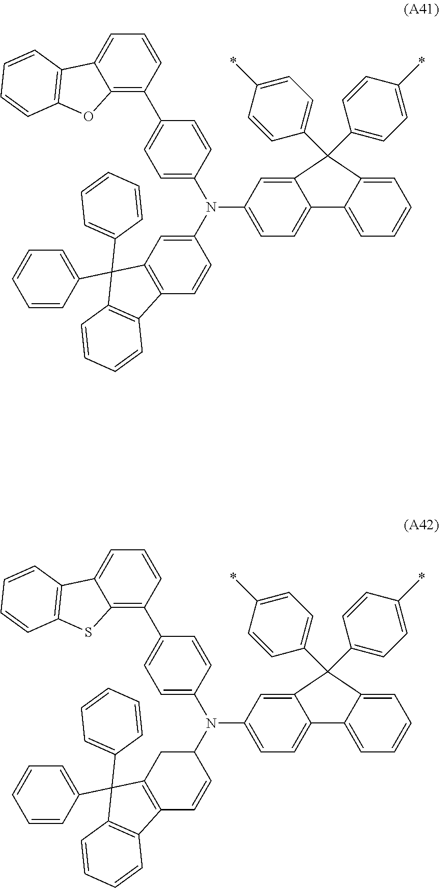

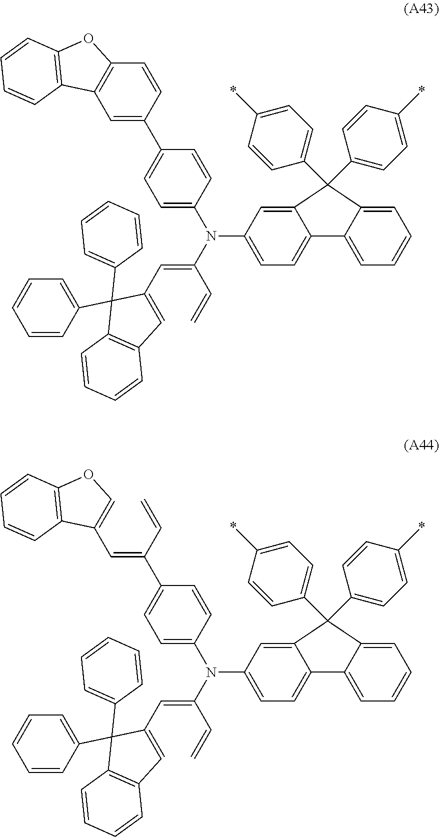

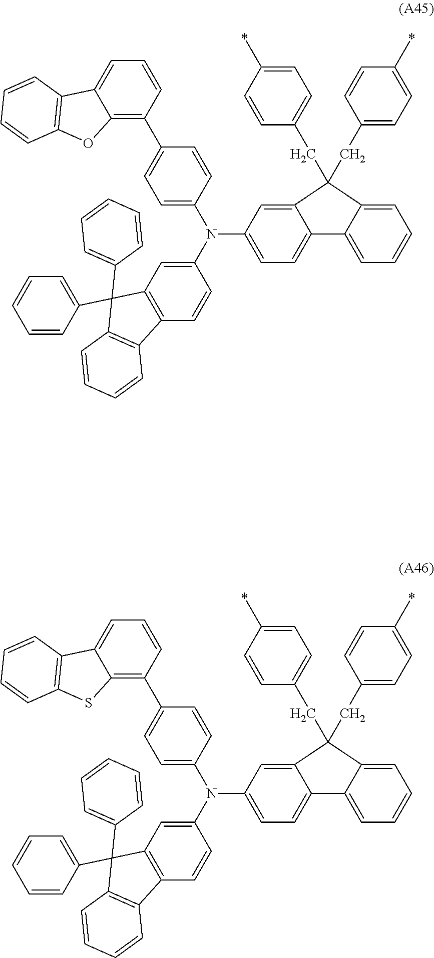

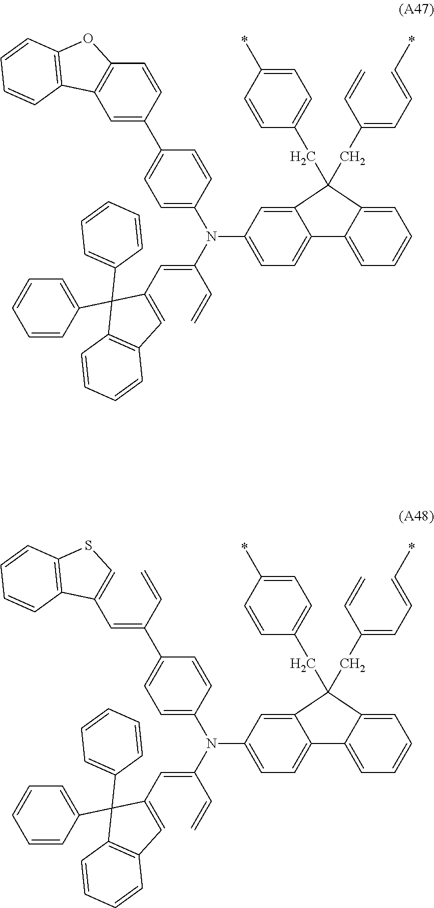

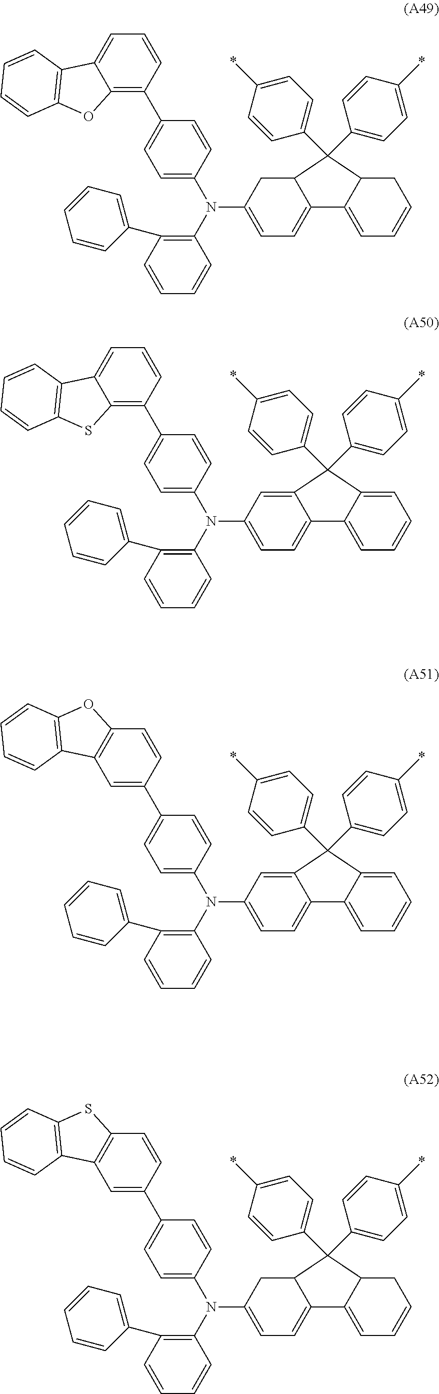

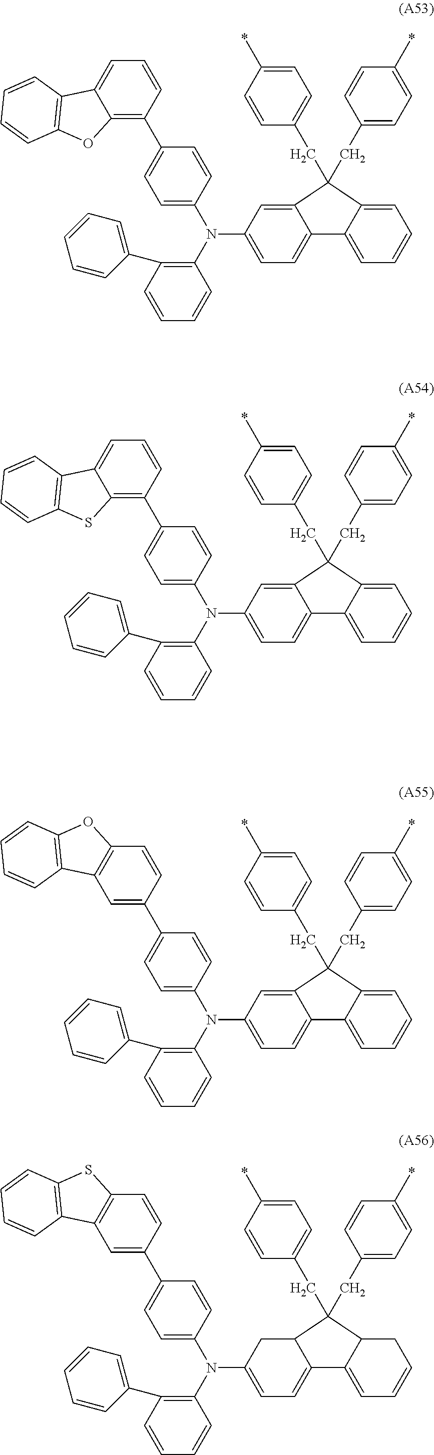

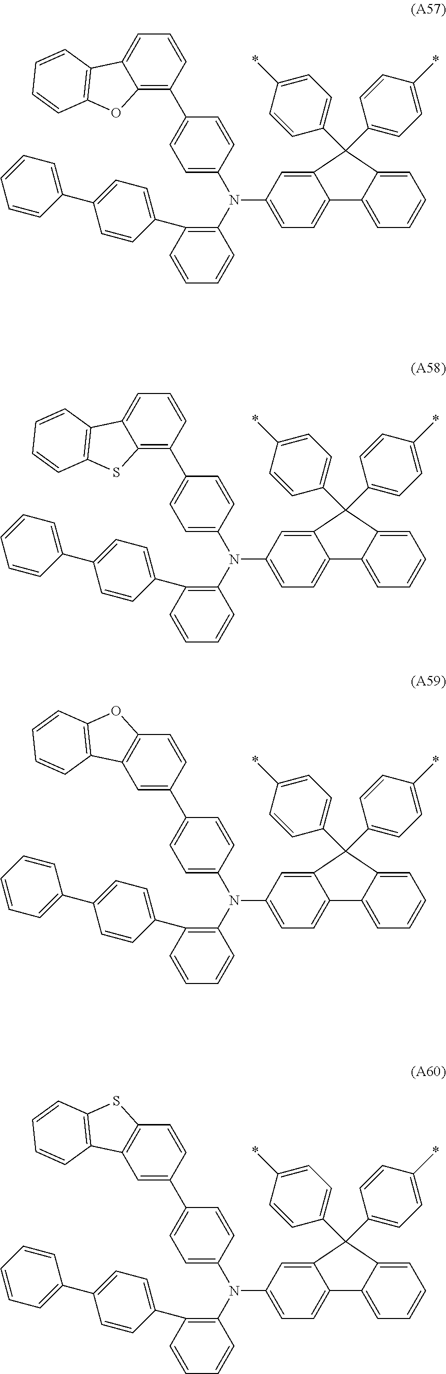

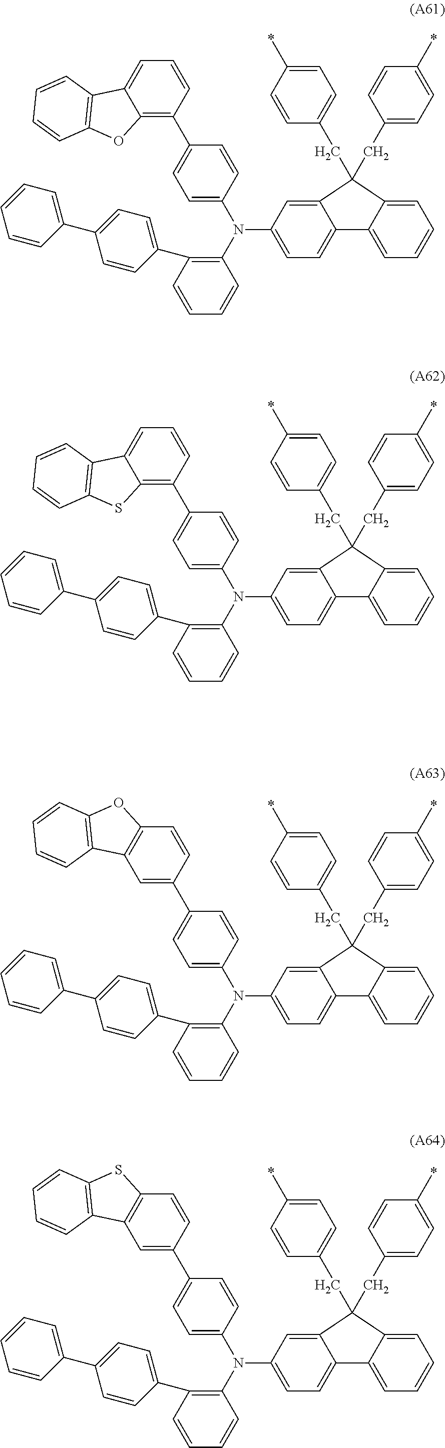

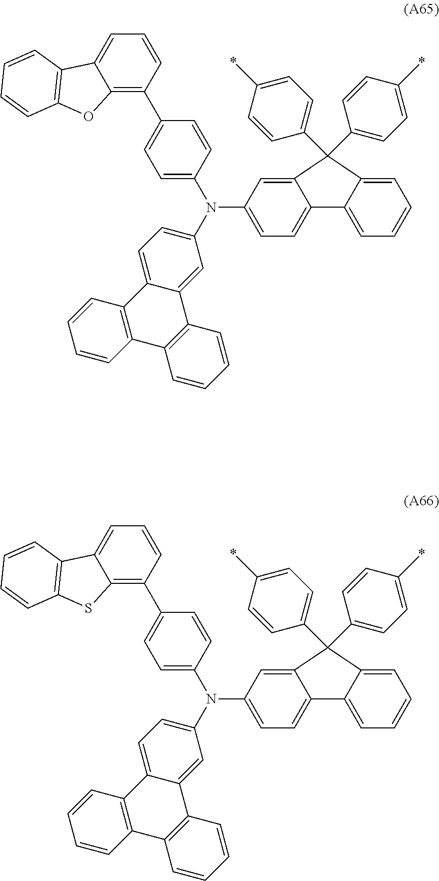

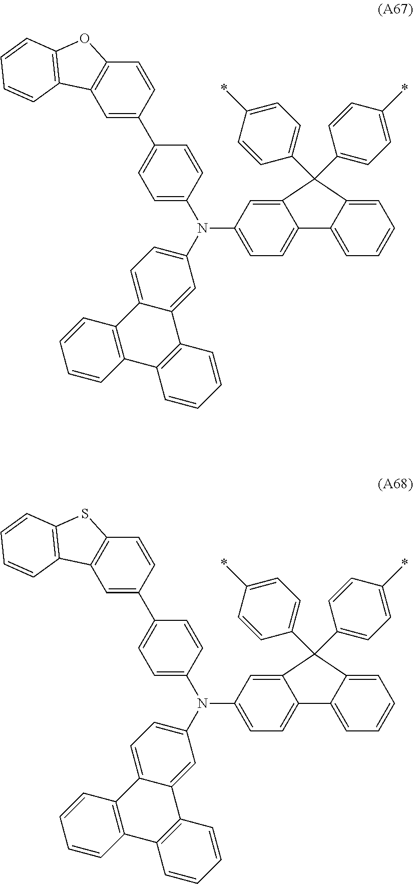

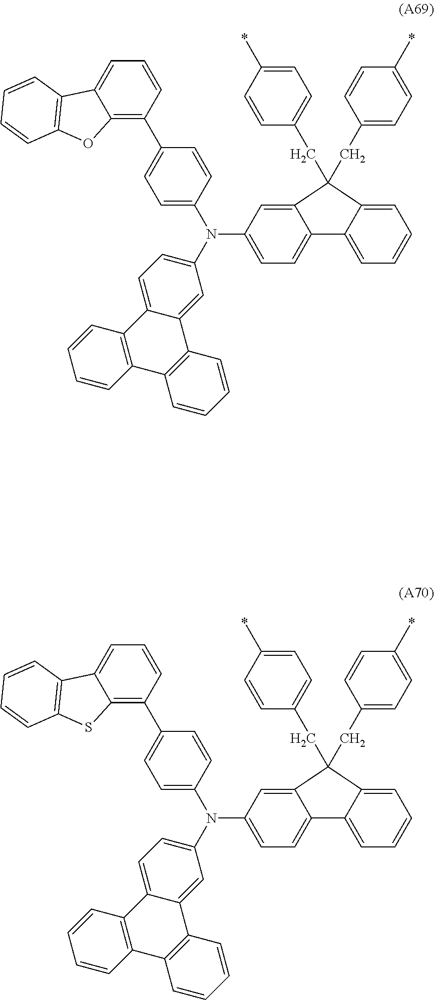

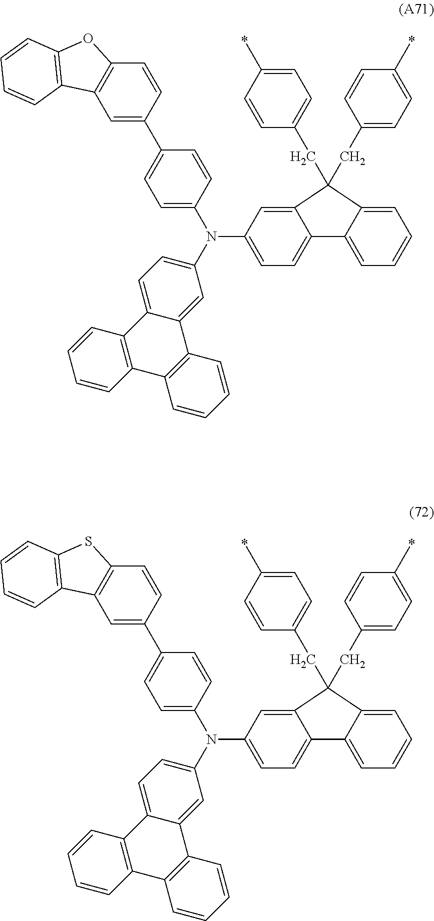

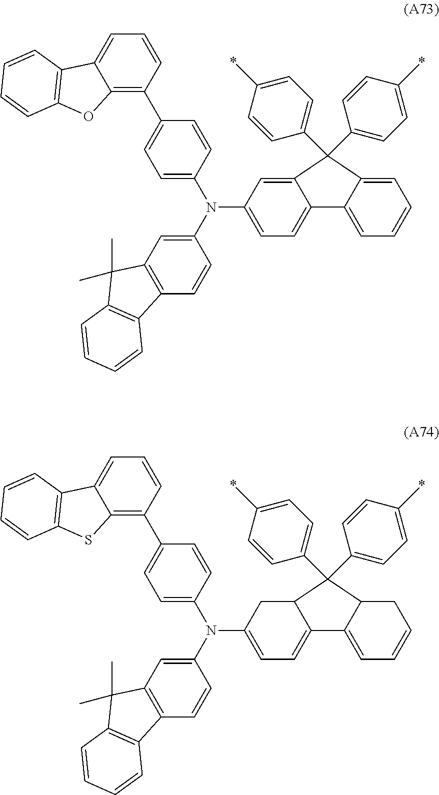

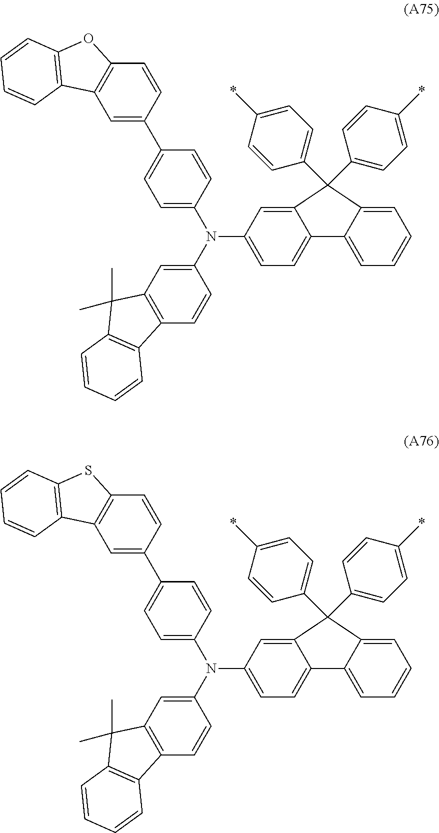

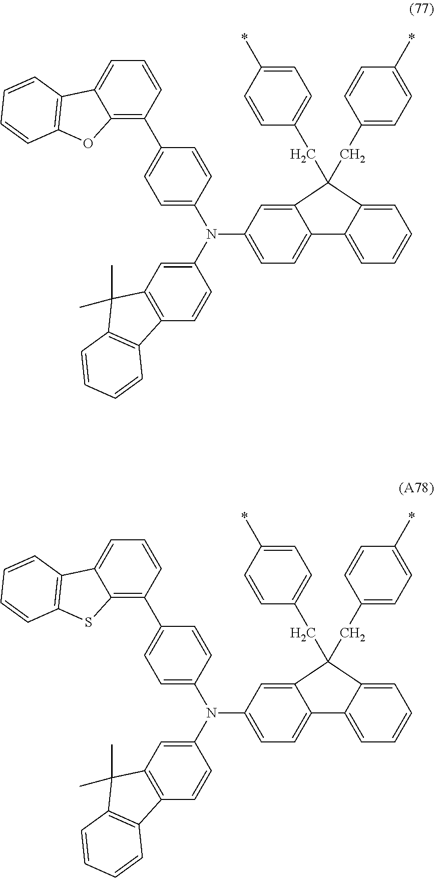

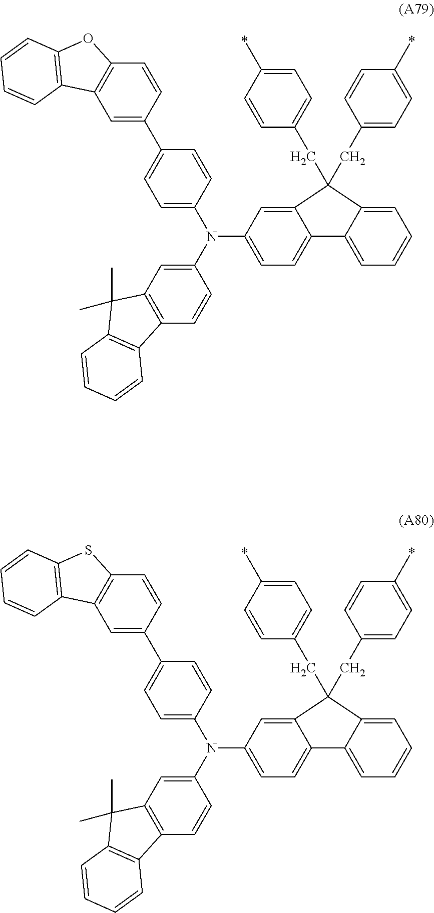

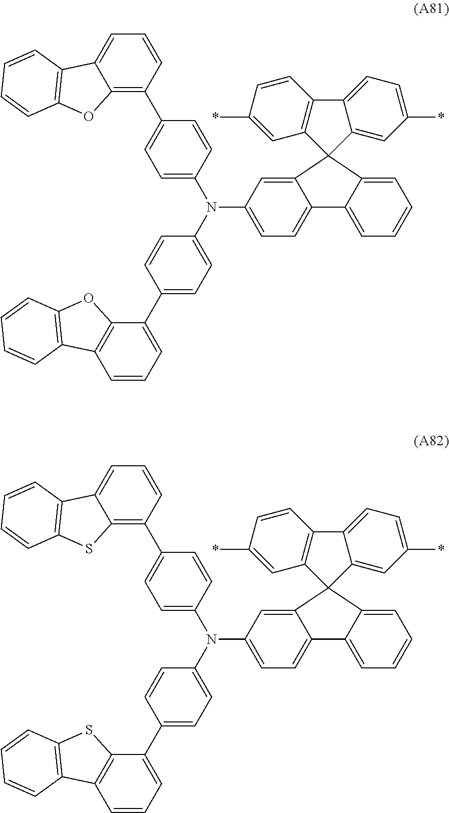

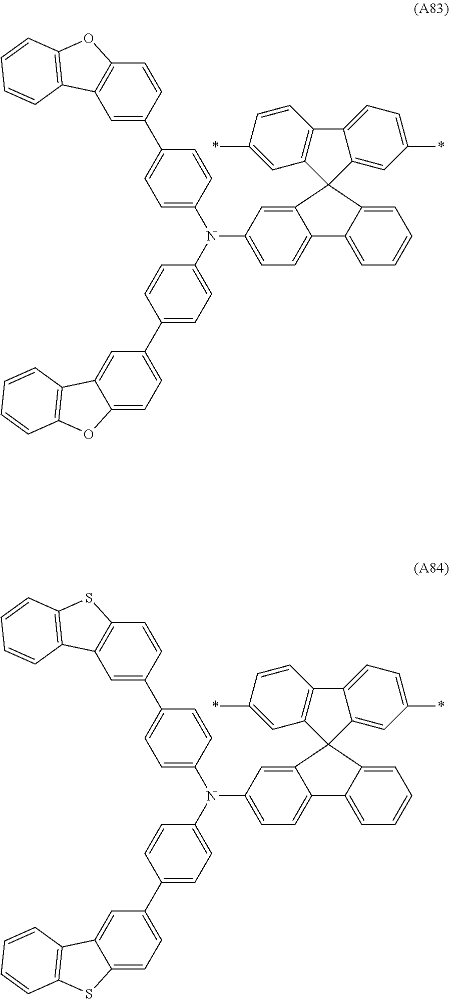

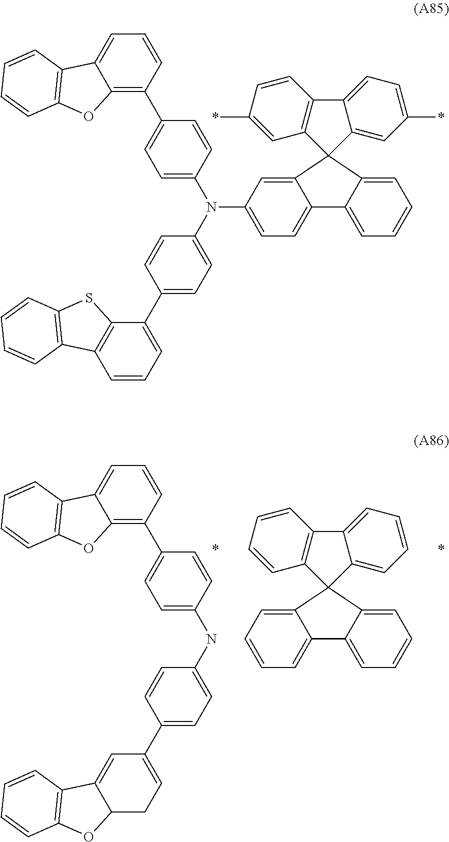

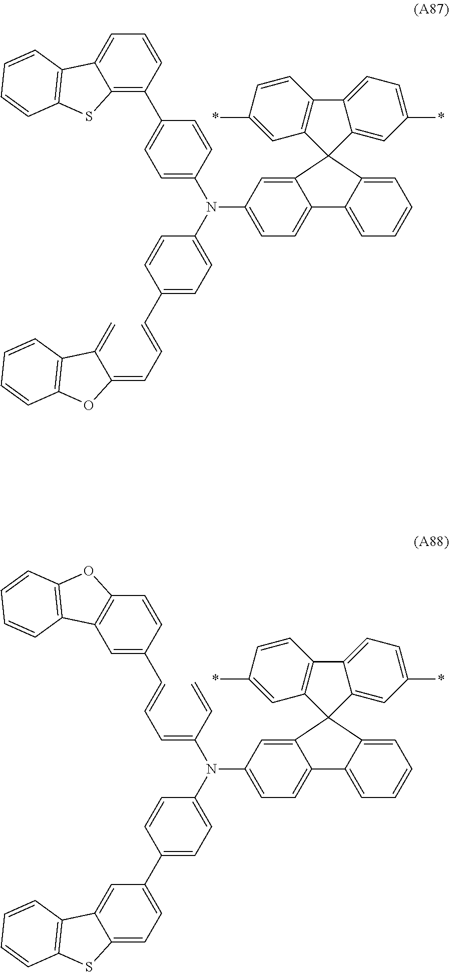

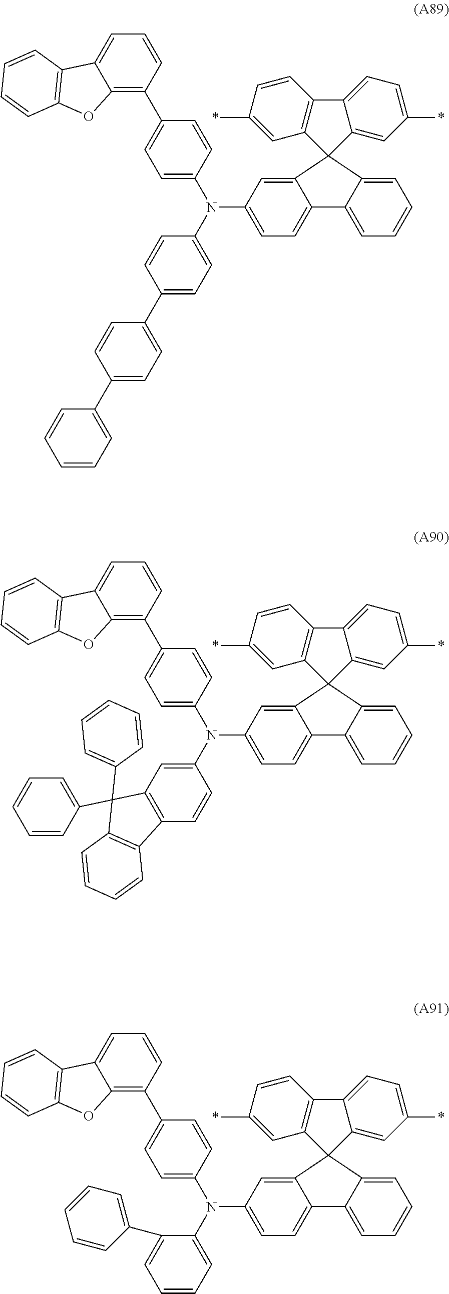

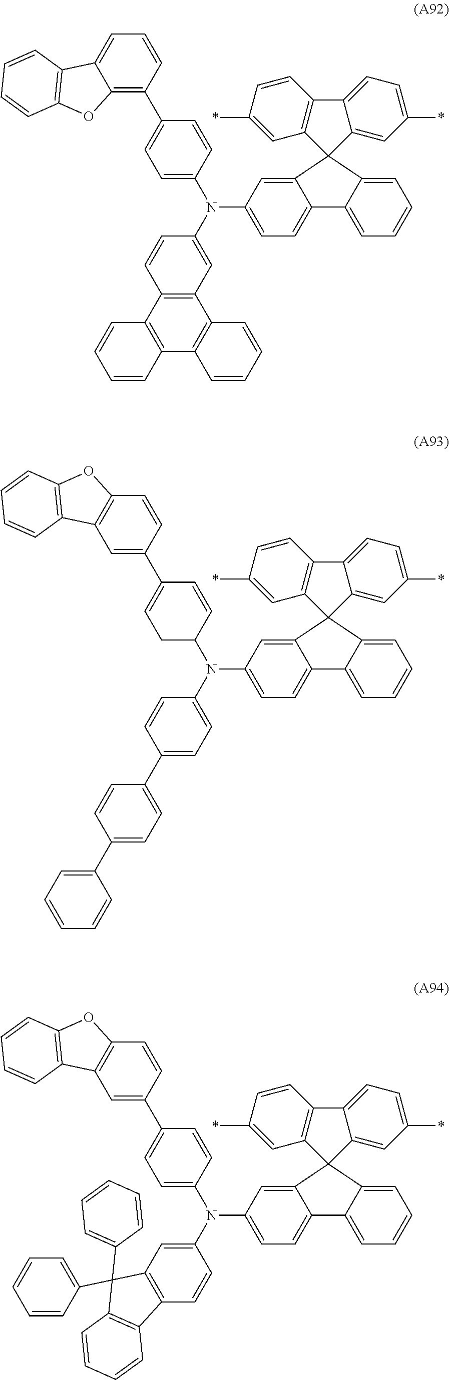

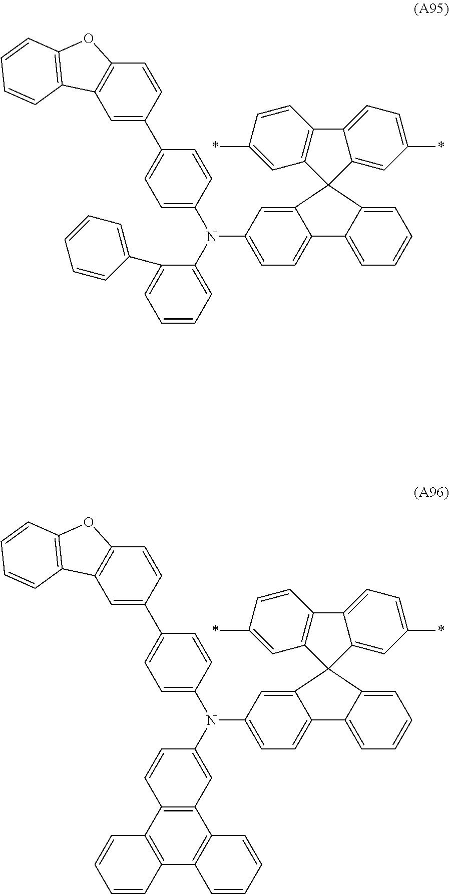

### <Regarding Structural Unit (B)>

The structural unit (B) that the high-molecular compound of one aspect of the present invention has is represented by the following general formula (B-1).

Ar^{B} (B-1)

The content of the structural unit (B) is, from the viewpoint of providing a high-molecular compound having good solubility in solvent, preferably 10 mol % or more relative to 100 mol % of all the structural units of the high-molecular compound, more preferably 20 mol % or more, even more preferably 30 mol % or more, and still more preferably 40 mol % or more, and from the viewpoint of securing the content of the structural unit (A) to provide an organic EL device material having improved charge transporting performance, preferably 70 mol % or less, more preferably 65 mol % or less, even more preferably 60 mol % or less, and still more preferably 55 mol % or less.

The high-molecular compound of one aspect of the present invention may have only one kind of the structural unit (B) or may have two or more kinds of the structural unit (B).

### <Structural Unit (B): Regarding Ar^{B} in General Formula (B-1)>

In the general formula (B-1), Ar^{B} represents a substituted or unsubstituted arylene group having 6 to 60 (preferably 6 to 25, more preferably 6 to 18, and even more preferably 6 to 13) ring carbon atoms, or a substituted or unsubstituted heteroarylene group having 5 to 60 (preferably 5 to 24, and more preferably 5 to 13) ring atoms.

Examples of the arylene group that can be selected for Ar^{B} include a phenylene group, a biphenylene group, a terphenylene group, a quaterphenylene group, a naphthylene group, an anthracenylene group, a phenanthrylene group, a crysenylene group, a pyrenylene group, a perylenylene group, a fluorenylene group, a stilbene-diyl group, etc.

Examples of the heteroarylene group that can be selected for Ar^{B} include a divalent residue of pyridine, pyrazine, quinolone, naphthyridine, quinoxaline, phenazine, diazaanthracene, pyridoquinone, pyrimidoquinazoline, pyrazinoquinoxaline, phenanthroline, carbazole, dibenzothiophene, thienothiophene, dithienothiophene, benzothiophene, dibenzothiophene, benzodithiophene, benzofuran, diobenzofuran, benzodifuran, dithiaindacene, dithiaindenoindene, dibenzoselenophene, diselanaindacene, diselanaindenoindene, dibenzosilole, etc.

In one aspect of the present invention, Ar^{B} in the general formula (B) is preferably an arylene group selected from a substituted or unsubstituted phenylene group, a substituted or unsubstituted biphenylene group, a substituted or unsubstituted terphenylene group, a substituted or unsubstituted naphthalenyl group, and a substituted or unsubstituted anthracenyl group.

The substituent that the arylene group may have includes those mentioned above, and preferably includes an alkyl group having 1 to 50 (preferably 1 to 18, more preferably 1 to 8, and even more preferably 1 to 4) carbon atoms, or an aryl group having 6 to 60 (preferably 6 to 25, more preferably 6 to 18, and even more preferably 6 to 13) ring carbon atoms.

In another aspect of the present invention, Ar^{B} in the general formula (B) is preferably a divalent residue of a compound represented by the following general formula (B-2).

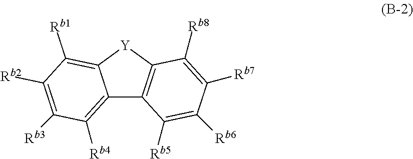

In the above general formula (B-2), R^{b1} to R^{b8} each independently represent a hydrogen atom or a substituent, and are preferably all hydrogen atoms.

Two selected from R^{b1} to R^{b8} may bond to each other to form a ring structure. Examples of compounds having such a ring structure include those of the following general formulae (B-2a) to (B-2e).

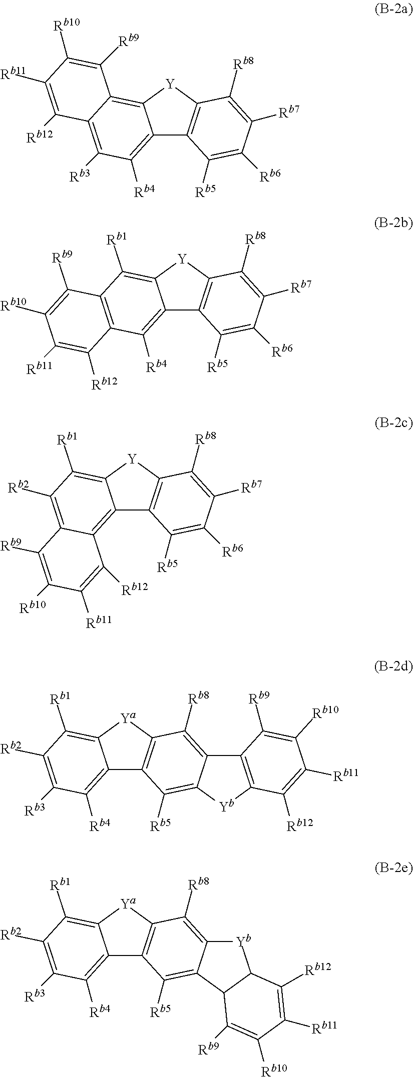

In the above formulae (B-2a), (B-2b), (B-2c), (B-2d), and (B-2e), R^{b1} to Rb¹² each independently represent a hydrogen atom or a substituent, and are preferably all hydrogen atoms. Two selected from R^{b1} to R^{b12} may bond to each other to form a ring structure.

In the above general formulae (B-2) and (B-2a) to (B-2e), Y, Y^{a}, and Y^{b} each independently represent —O—, —S—, —N(R^{a})—, —C(R^{a})(R^{b})—, or —Si(R^{a})(R^{b})—. R^{a} and R^{b} each independently represent a hydrogen atom or a substituent, and R^{a} and R^{b} may bond to each other to form a ring structure.

Among these, Y, Y^{a}, and Y^{b} each are preferably —O—, —S—, or —C(R^{a})(R^{b})—, and more preferably —C(R^{a})(R^{b})—.

Specific examples of the substituent that may be selected for the above R^{b1} to R^{b12}, R^{a}, and R^{b} include those mentioned hereinabove, and the substituent is preferably an alkyl group having 1 to 50 (preferably 1 to 18, more preferably 1 to 8, and even more preferably 1 to 4) alkyl group, or an aryl group having 6 to 60 (preferably 6 to 25, more preferably 6 to 18, and even more preferably 6 to 13) ring carbon atoms.

In the structure represented by the above general formula (B-2), two atoms selected from hydrogen atoms or atoms in the substituent (carbon atom, nitrogen atom, and silicon atom) bond to the other structural unit to form a high-molecular chain.

In the above general formula (B-2), preferably, the carbon atom in the aromatic ring bonding to one selected from R^{b1} to R^{b4} and the carbon atom in the aromatic ring bonding to one selected from R^{b5} to R^{b8} bond to the other structural unit.

In the general formula (B-2a), preferably, the carbon atom in the aromatic ring bonding to one selected from R^{b3}, R^{b4}, and R^{b9} to R^{b12} and the carbon atom in the aromatic ring bonding to one selected from R^{b5} to R^{b8} bond to the other structural unit.

In the general formula (B-2b), preferably, the carbon atom in the aromatic ring bonding to one selected from R^{b1}, R^{b4}, and R^{b9} to R^{b12} and the carbon atom in the aromatic ring bonding to one selected from R^{b5} to R^{b8} bond to the other structural unit.

In the general formula (B-2c), preferably, the carbon atom in the aromatic ring bonding to one selected from R^{b1}, R^{b2}, and R^{b9} to R^{b12} and the carbon atom in the aromatic ring bonding to one selected from R^{b5} to R^{b8} bond to the other structural unit.

In the general formula (B-2d), preferably, the carbon atom in the aromatic ring bonding to one selected from R^{b1} to R^{b4} and the carbon atom in the aromatic ring bonding to one selected from R^{b9} to R^{b12} bond to the other structural unit, and more preferably, the carbon atom in the aromatic ring bonding to R^{b2} and the carbon atom in the aromatic ring bonding to R^{b11} bond to the other structural unit.

In the general formula (B-2e), preferably, the carbon atom in the aromatic ring bonding to one selected from R^{b1} to R^{b4} and the carbon atom in the aromatic ring bonding to one selected from R^{b9} to R^{b12} bond to the other structural unit, and more preferably, the carbon atom in the aromatic ring bonding to R^{b2} and the carbon atom in the aromatic ring bonding to R^{b11} bond to the other structural unit.

### Examples of Structure of Structural Unit (B)

As examples of the structure of the structural unit (B) that the high-molecular compound of one aspect of the present invention has, structural units (B1) to (B96) are shown below, but the structure of the structural unit (B) is not limited to these. * in the formulae indicates a bonding position to the other structural unit.

The hydrogen atom bonding to the carbon atom or the silicon atom in the following structure may be substituted with the above-mentioned substituent. Specific examples of the case are the following structural units (B87) to (B96).

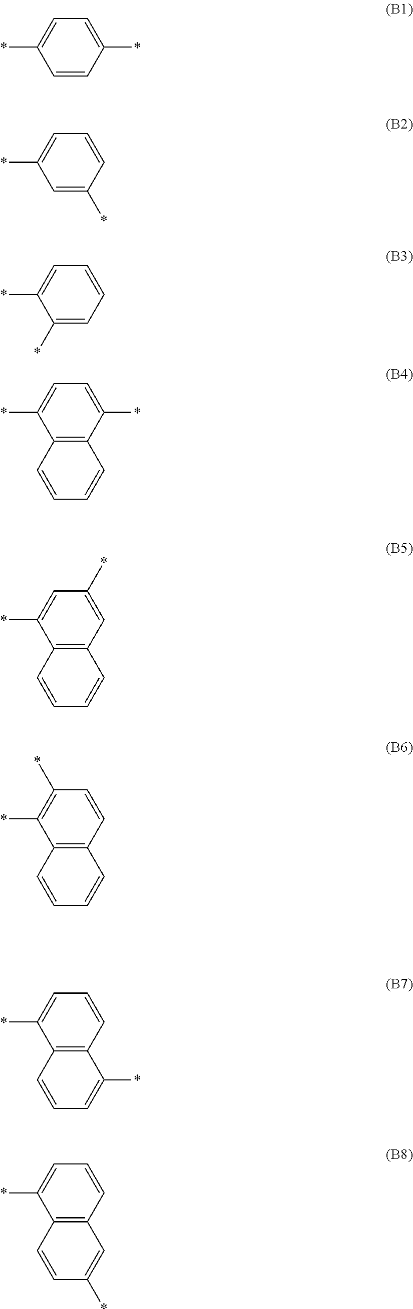

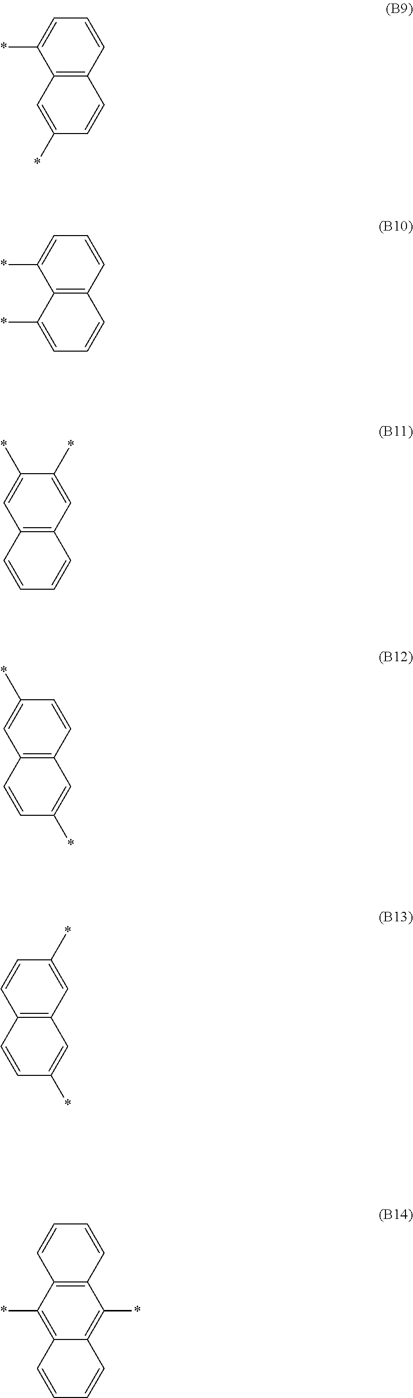

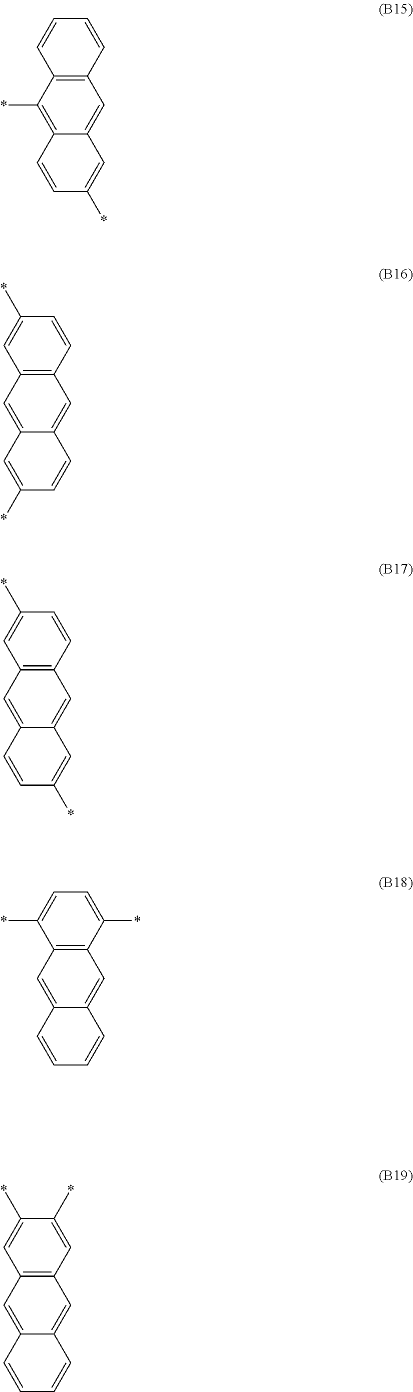

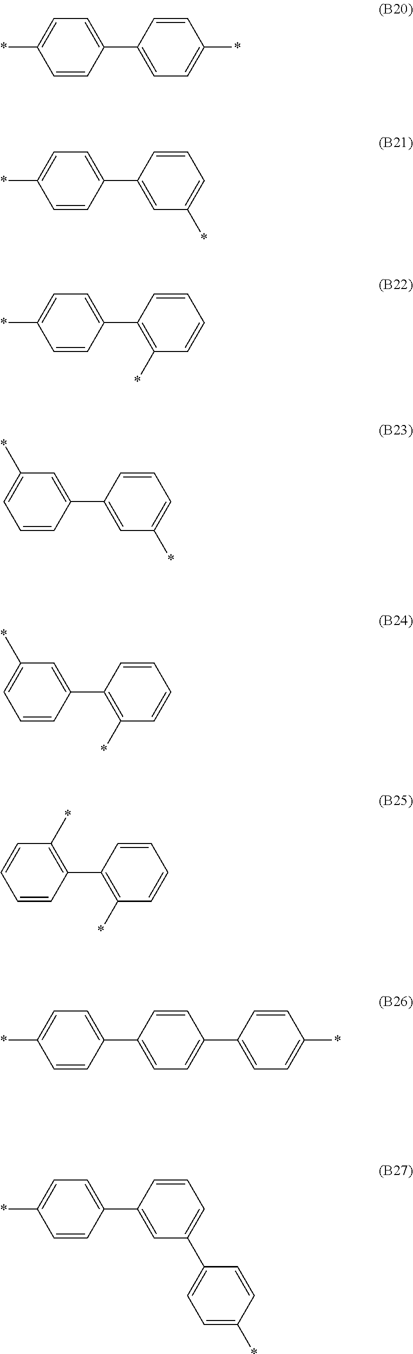

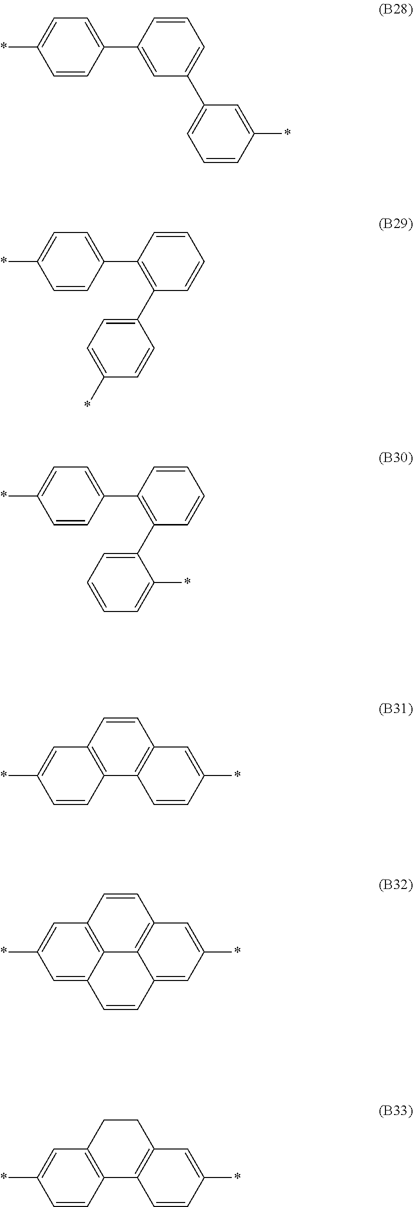

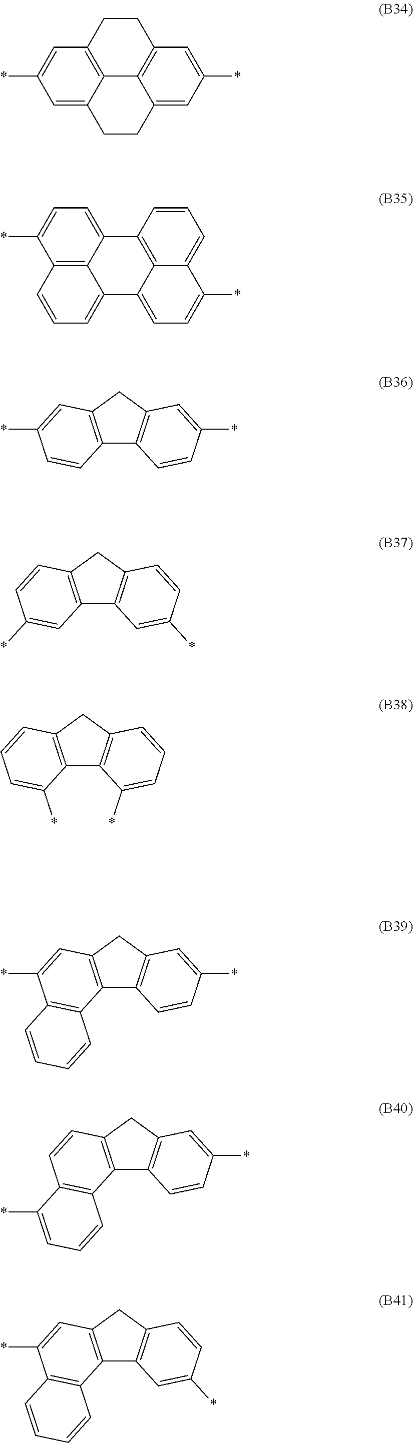

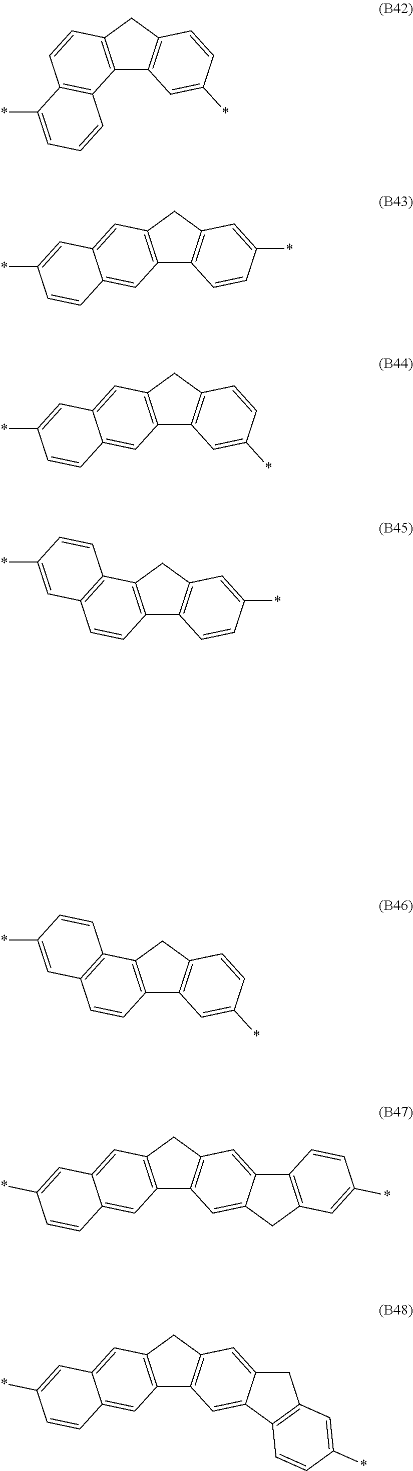

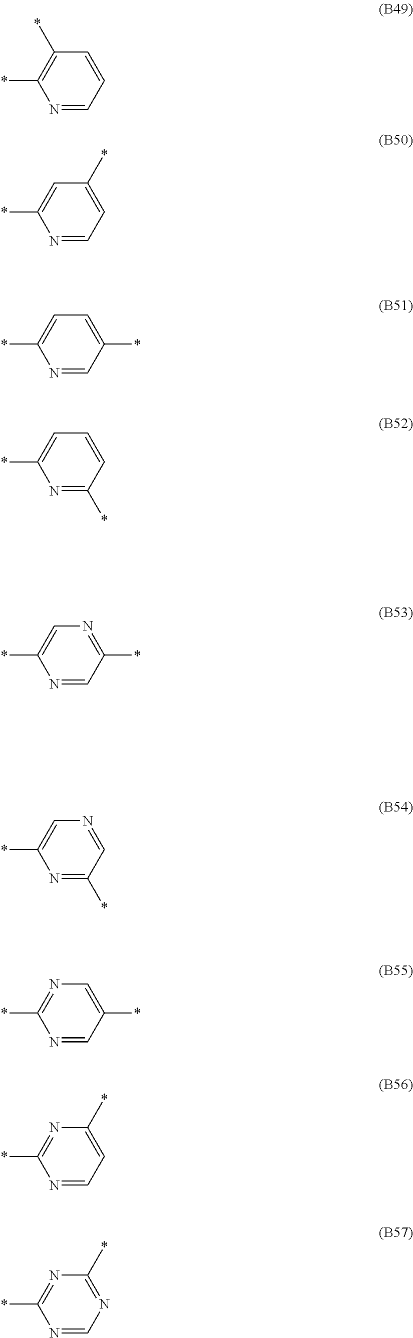

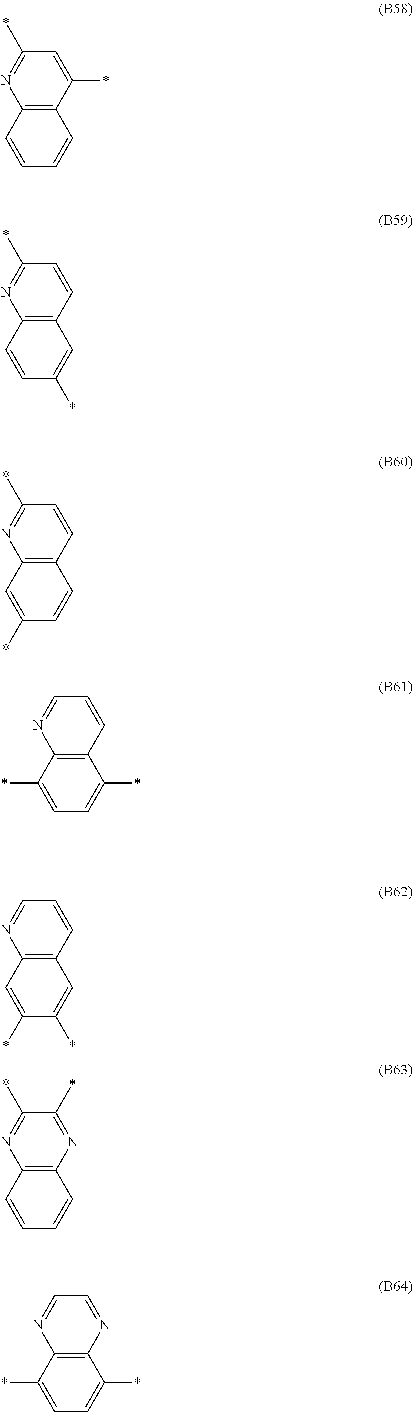

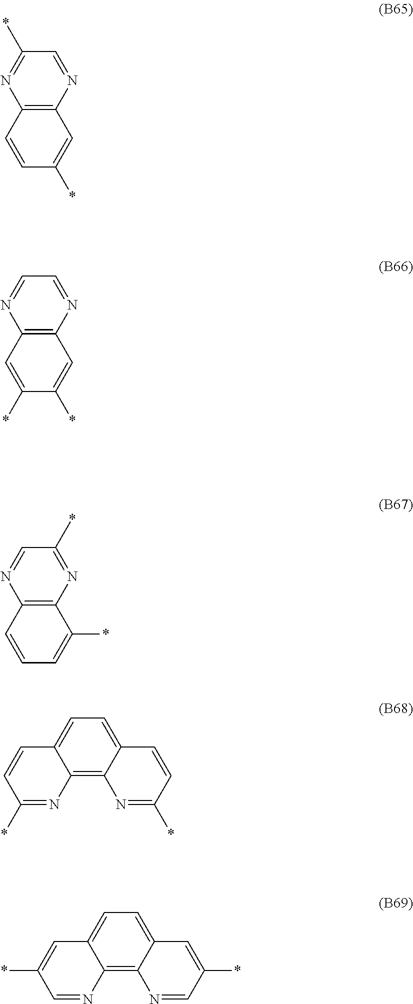

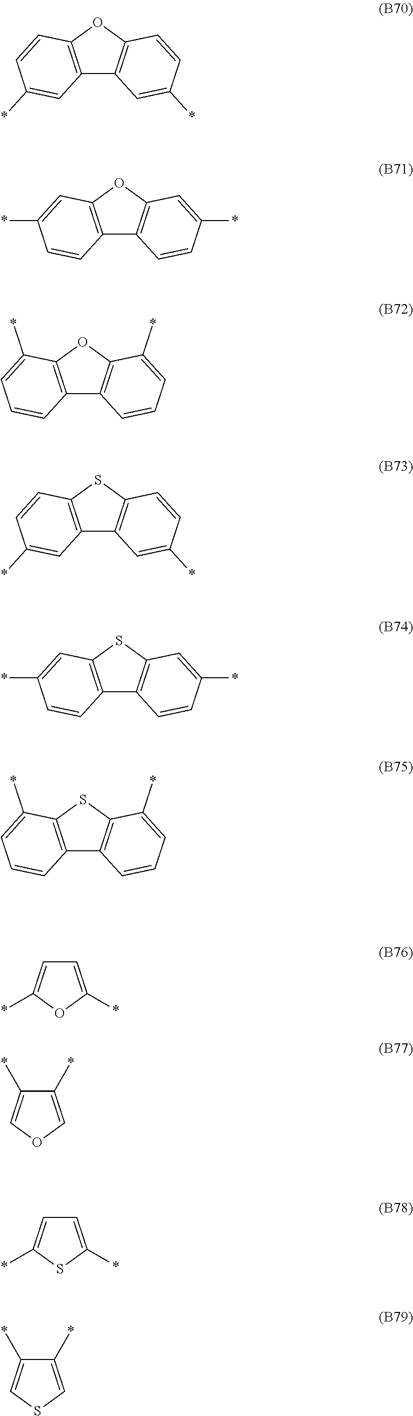

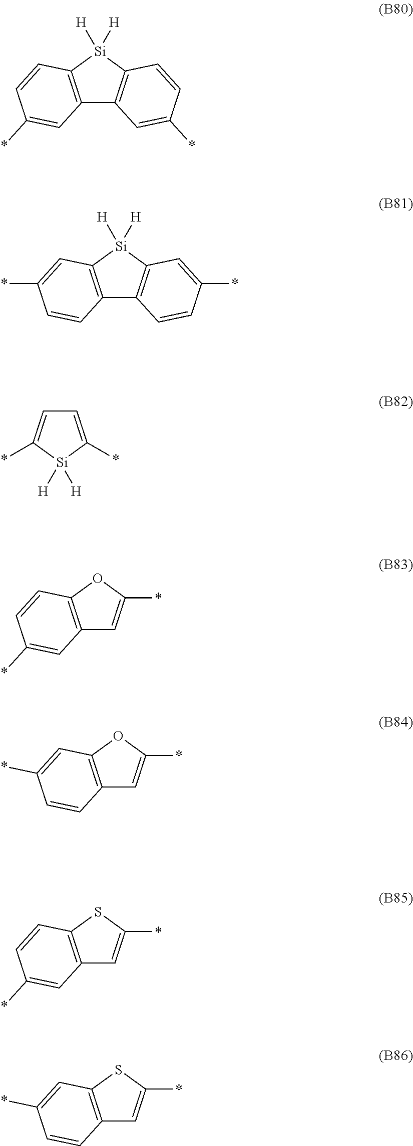

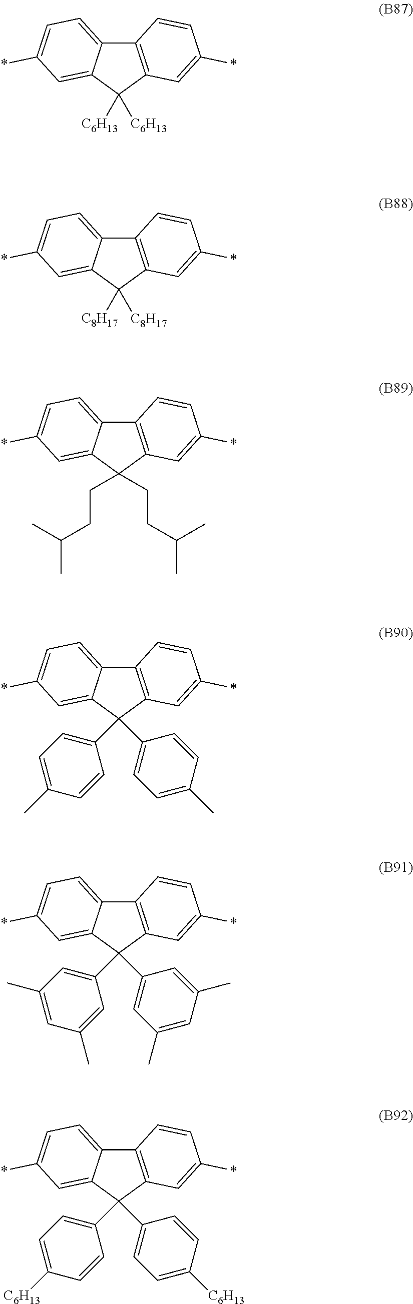

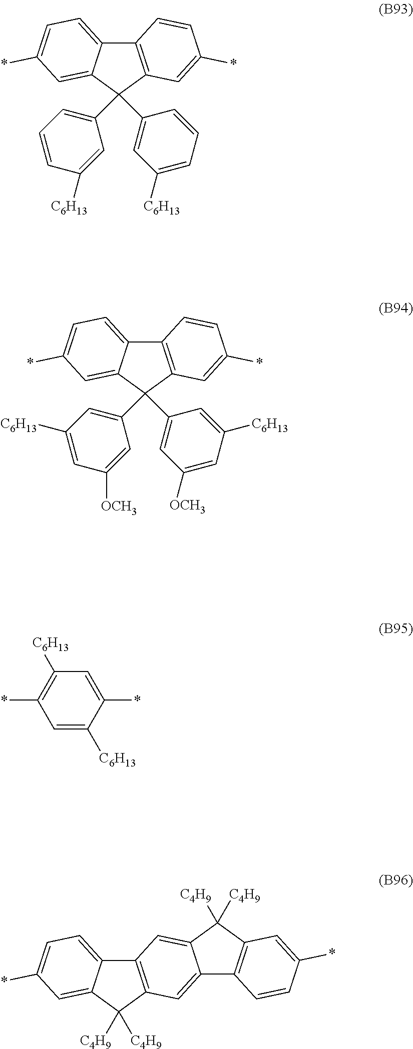

### <Regarding Structural Unit (C)>

In one aspect of the present invention, the structural unit (B) preferably contains a structural unit (C) represented by the following general formula (C-1).

Ar^{C} (C-1)

In the general formula (C-1), Ar^{C} represents an arylene group having a polymerizing functional group and having 6 to 60 (preferably 6 to 25, more preferably 6 to 18, and even more preferably 6 to 13) ring carbon atoms, or a heteroarylene group having a polymerizing functional group and having 5 to 60 (preferably 5 to 24, and more preferably 5 to 13) ring atoms.

The arylene group and the heteroarylene group may have any other substituent than a polymerizing functional group.

The arylene group and the heteroarylene group include the arylene group and the heteroarylene group that may be selected for Ar^{B} in the general formula (B-1).

The polymerizing functional group means a group that reacts with any other molecule through irradiation with heat and/or active energy ray or by receipt of energy from any other molecule such as sensitizer or the like, thereby forming a new chemical bond.

In the present invention, among the examples belonging to the structural unit (B), the structural units containing an arylene group or heteroarylene group that has a polymerizing functional group are “structural unit (C)”.

In the high-molecular compound of one aspect of the present invention that contains a structural unit (C), thermal crosslinking reaction runs on in the heating step in forming an organic thin-film layer that contains the high-molecular compound, and accordingly, an organic thin-film layer hardly dissolving in solvent can be formed. As a result, even when another layer is formed on the organic thin-film layer according to a method of coating with a solution, the resultant layer can be kept flat since the organic thin-film layer hardly dissolve in solvent, and the performance such as the lifetime of the organic EL device to be obtained can be thereby improved.

In the high-molecular compound of one aspect of the present invention, the content ratio of the structural unit (C) relative to one mol of the content of the structural unit (B) [(C)/(B)] is preferably 0.01 to 0.50 mol, more preferably 0.03 to 0.40 mol, even more preferably 0.05 to 0.30 mol, and still more preferably 0.07 to 0.20 mol.

The “content of the structural unit (B)” contains the “content of the structural unit (C)”.

The polymerizing functional group includes a group containing an unsaturated double bond, a cyclic ether, a benzocyclobutane ring, etc.

More specifically, the group includes a vinyl group, a vinylidene group, a vinylene group, an ethynylene group, a group having a substituted or unsubstituted norbornene skeleton, a substituted or unsubstituted epoxy group, an oxetane group, a group having a lactone structure, a group having a lactam structure, a cyclooctatetraene group, a 1,5-cyclooctadiene group, a 1,ω-diene group, an O-divinylbenzene group, a 1,ω-diyne group, etc.

Among these, the polymerizing functional group is preferably a group selected from the following (i) to (vii).

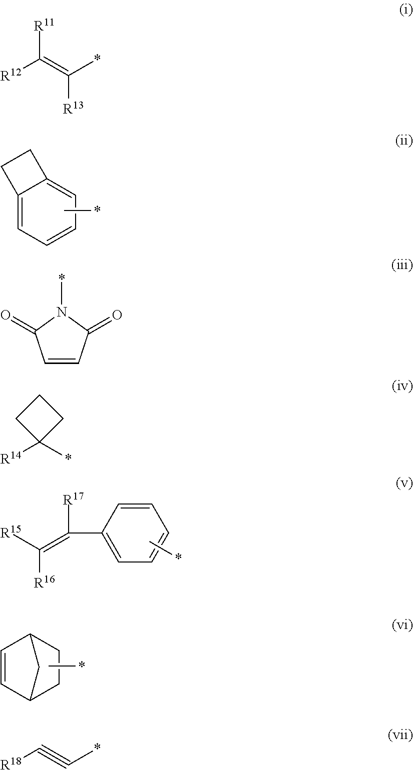

In the above formulae, * indicates a bonding position.

R¹¹ to R¹⁸ each independently represent a hydrogen atom, a substituted or unsubstituted alkyl group having 1 to 20 (preferably 1 to 8, and more preferably 1 to 4) carbon atoms, or a substituted or unsubstituted aryl group having 6 to 24 (preferably 6 to 18, and more preferably 6 to 13) ring carbon atoms.

Examples of the alkyl group that may be selected for R¹¹ to R¹⁸ include a methyl group, an ethyl group, an n-propyl group, an isopropyl group, an n-butyl group, an isobutyl group, an s-butyl group, a t-butyl group, a pentyl group (including isomer groups), a hexyl group (including isomer groups), a heptyl group (including isomer groups), an octyl group (including isomer groups), a nonyl group (including isomer groups), a decyl group (including isomer groups), an undecyl group (including isomer groups), and a dodecyl group (including isomer groups), etc.

Examples of the aryl group that may be selected for R¹¹ to R¹⁸ include a phenyl group, a naphthylphenyl group, a biphenylyl group, a terphenylyl group, a biphenylenyl group, a naphthyl group, a phenylnaphthyl group, etc.

In one aspect of the present invention, Ar^{C} is preferably a divalent group represented by the following general formula (C-2), (C-3) or (C-4).

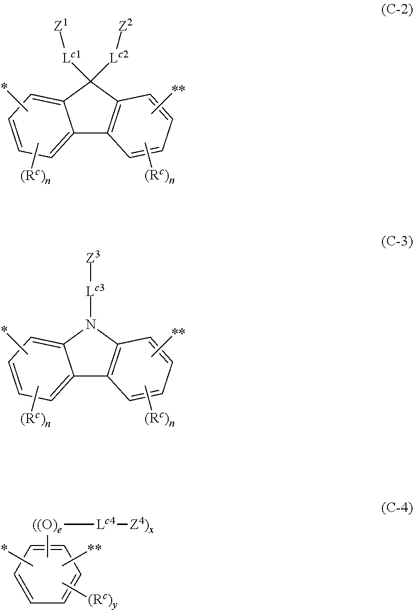

In the general formula (C-2), (C-3) and (C-4), L^{e1} to L^{e4} each independently represent a single bond, or a substituted or unsubstituted alkylene group having 1 to 50 (preferably 1 to 18, more preferably 1 to 8, even more preferably 1 to 4, and still more preferably 1 to 2) carbon atoms.

The alkylene group includes the same ones as those for the alkylene group that may be selected for L³¹ and L³² in the general formula (A-1a).

Z¹ to Z⁴ each independently represent a polymerizing functional group, and is preferably a group selected from the above formulae (i) to (vii).

R^{C} each independently represent a substituent, bonding to the carbon atom of the benzene ring in the general formulae (C-2), (C-3) and (C-4). When n and y are 0, the benzene ring is unsubstituted.

When the formula has plural R^{c}'s, the plural R^{c}'s may bond to each other to form a ring structure.

* and ** each indicate a bonding position, at which the formula bonds to the other structural unit to form a polymer chain.

In the general formulae (C-2) and (C-3), n each independently represent an integer of 0 to 3, preferably an integer of 0 to 2, more preferably an integer of 0 to 1, and even more preferably 0.

In the general formula (C-4), e is 0 or 1. When e is 0, the carbon atom of the benzene ring directly bonds to L^{C4} (or to Z⁴, when L^{C4} is a single bond).

x represents an integer of 1 to 4, y represents an integer of 0 to 3, and x+y is 4 or less.

x is preferably an integer of 1 to 2, and more preferably 1.

y is preferably an integer of 0 to 2, more preferably an integer of 0 to 1, and is even more preferably 0.

In one aspect of the present invention, preferably, Ar^{C} is a divalent group represented by the following general formula (C-5).

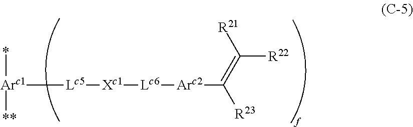

In the general formula (C-5), Ar^{c1} represent a substituted or unsubstituted aromatic hydrocarbon group having 6 to 60 (preferably 6 to 25, more preferably 6 to 18, and even more preferably 6 to 13) ring carbon atoms, or a substituted or unsubstituted aromatic heterocyclic group having 5 to 60 (preferably 5 to 24, and more preferably 5 to 13) ring atoms.

L^{c5} represents a single bond, or a substituted or unsubstituted alkylene group having 1 to 50 (preferably 1 to 18, more preferably 1 to 8, even more preferably 1 to 4, and still more preferably 1 to 2) carbon atoms.

L^{c6} represents a substituted or unsubstituted alkylene group having 1 to 50 (preferably 1 to 18, more preferably 1 to 8, even more preferably 1 to 4, and still more preferably 1 to 2) carbon atoms.

X^{c1} represents an oxygen atom or a sulfur atom.

Ar^{c2} represents a substituted or unsubstituted arylene group having 6 to 60 (preferably 6 to 25, more preferably 6 to 18, and even more preferably 6 to 13) ring carbon atoms.

R²¹ to R²³ each independently represent a hydrogen atom, an alkyl group having 1 to 20 carbon atoms, an alkoxy group having 1 to 20 carbon atoms, an alkylthio group having 1 to 20 carbon atoms, an aryl group having 6 to 20 ring carbon atoms, an aryloxy group having 6 to 20 ring carbon atoms, an arylthio group having 6 to 20 ring carbon atoms, an arylalkyl group having 7 to 48 carbon atoms, an arylalkoxy group having 7 to 48 carbon atoms, an arylalkylthio group having 7 to 48 carbon atoms, an arylalkenyl group having 8 to 60 carbon atoms, an arylalkynyl group having 8 to 60 carbon atoms, a substituted or unsubstituted amino group, a substituted or unsubstituted silyl group, a halogen atom, an acyl group having 2 to 18 carbon atoms, an acyloxy group having 2 to 18 carbon atoms, a heteroaryl group having 5 to 30 ring atoms, a substituted or unsubstituted carboxy group, a cyano group, or a nitro group.

f represents 1 or 2. When f is 2, the parenthesized structures relating to f may be the same as or different from each other.

* and ** each indicate a bonding position, bonding to the other structure to form a high-molecular chain.

Two selected from Ar_{c1}, Ar^{c2}, and R²¹ to R²³ may bond to each other to form a ring.

The divalent group represented by the general formula (C-5) is preferably a divalent group represented by the following general formula (C-5-1), more preferably a divalent group represented by the following general formula (C-5-2), and even more preferably a divalent group represented by the following general formula (C-5-3).

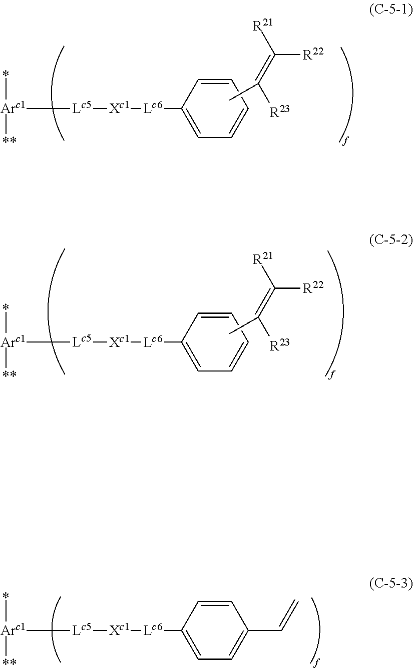

In the general formulae (C-5-1) to (C-5-3), Ar^{c1}, L^{c5}, L^{c6}, X^{c1}, R²¹ to R²³ and f have the same definitions as those relating to the general formula (C-5).

* and ** each indicate a bonding position, bonding to the other structural unit to form a high-molecular chain.

In one aspect of the present invention, Ar^{C} is preferably a divalent group represented by the following general formula (C-6).

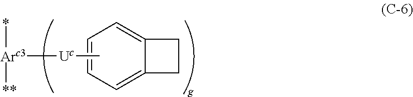

In the general formula (C-6), Ar^{c3} represents a substituted or unsubstituted aromatic hydrocarbon group having 6 to 60 (preferably 6 to 25, more preferably 6 to 18, and even more preferably 6 to 13) ring carbon atoms, or a substituted or unsubstituted aromatic heterocyclic group having 5 to 60 (preferably 5 to 24, and more preferably 5 to 13) ring atoms.

U^{c} represents a group represented by -L^{c7}-, -L^{c7}-X^{c2}—, —X^{c2}-L^{c7}-, -L^{c7}-X^{c2}-L^{c7}-, -L^{c7}-X^{c2}-L^{c8}-, or -L^{c8}-X^{c2}-L^{c7}-.

L^{c7} each independently represent a substituted or unsubstituted alkenylene group having 2 to 50 (preferably 2 to 18, and more preferably 2 to 8) carbon atoms, L^{c8} each independently represent a substituted or unsubstituted alkylene group having 1 to 50 (preferably 1 to 18, more preferably 1 to 8, even more preferably 1 to 4, and still more preferably 1 to 2) carbon atoms, and X^{c2} each independently represent an oxygen atom or a sulfur atom.

g represents 1 or 2. When g is 2, the parenthesized structures relating to g may be the same as or different from each other.

* and ** each indicate a bonding position, bonding to the other structural unit to form a high-molecular chain.

The alkenylene group that may be selected for L^{c7} includes a divalent unsaturated aliphatic hydrocarbon containing a double bond, and examples thereof include an ethene-diyl group, a propene-diyl group, a butene-diyl group, a pentene-diyl group, a hexene-diyl group, a heptene-diyl group, an octene-diyl group, a decene-diyl group, an undecene-diyl group, etc.

The double bond in the alkenylene group may be at any position. Specifically, for example, hexene of the “hexene-diyl group” includes 1-hexene, 2-hexene and 3-hexene. The group also includes isomers (cis-form, trans-form).

The divalent group represented by the general formula (C-6) is preferably a divalent group represented by the following general formula (C-6-1), and more preferably a divalent group represented by the following general formula (C-6-2) or (C-6-3).

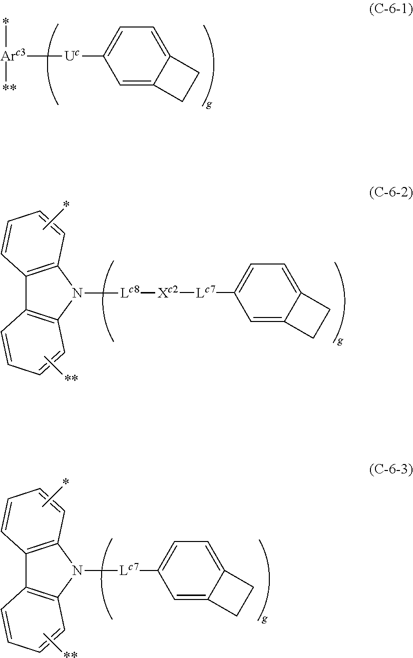

Ar^{c3}, U^{c} and g in the general formula (C-6-1), and L^{c7}, L^{c8}, X^{c2} and g in the general formulae (C-6-2) to (C-6-3) have the same definitions as those relating to the general formula (C-6).

* and ** each indicate a bonding position, bonding to the other structural formula to form a high-molecular chain.

### Examples of Structure of Structural Unit (C)

As examples of the structure of the structural unit (C) that the high-molecular compound of one aspect of the present invention has, structural units (C1) to (C80) are shown below, but the structure of the structural unit (C) is not limited thereto. In the formulae, * indicates a bonding position to the other structural unit. The hydrogen atom bonding to the carbon atom in the following structures may be substituted with the above-mentioned substituent.

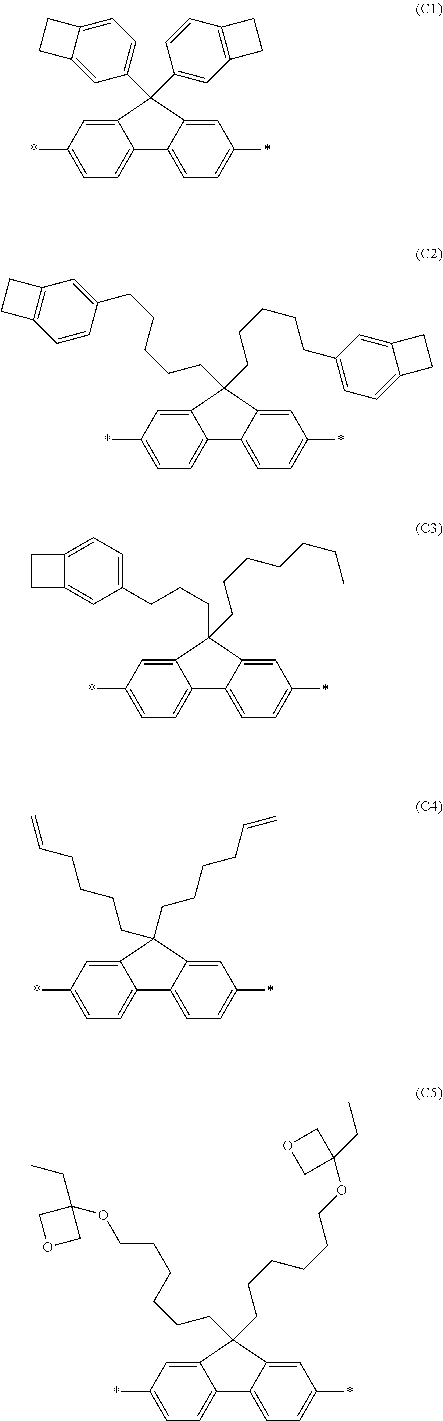

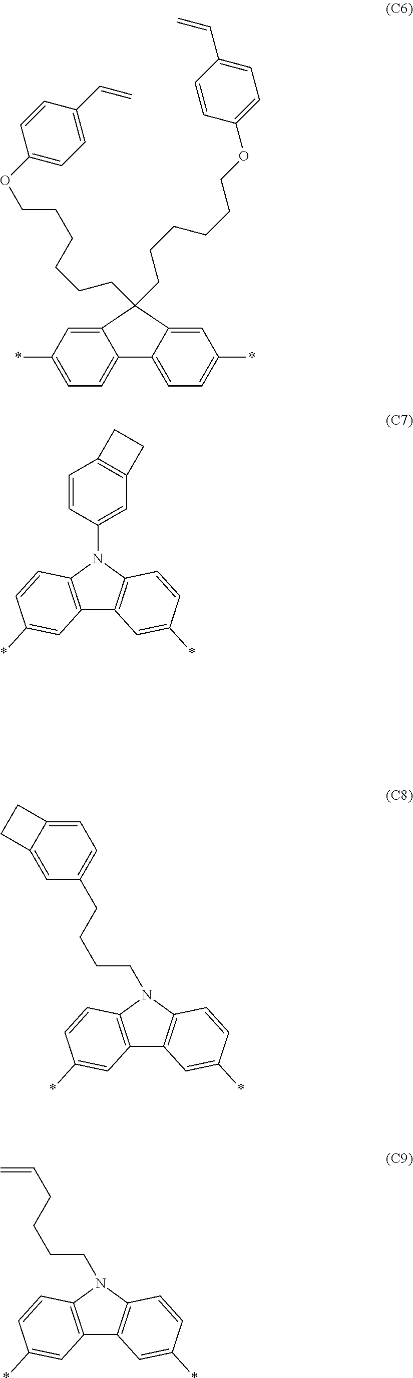

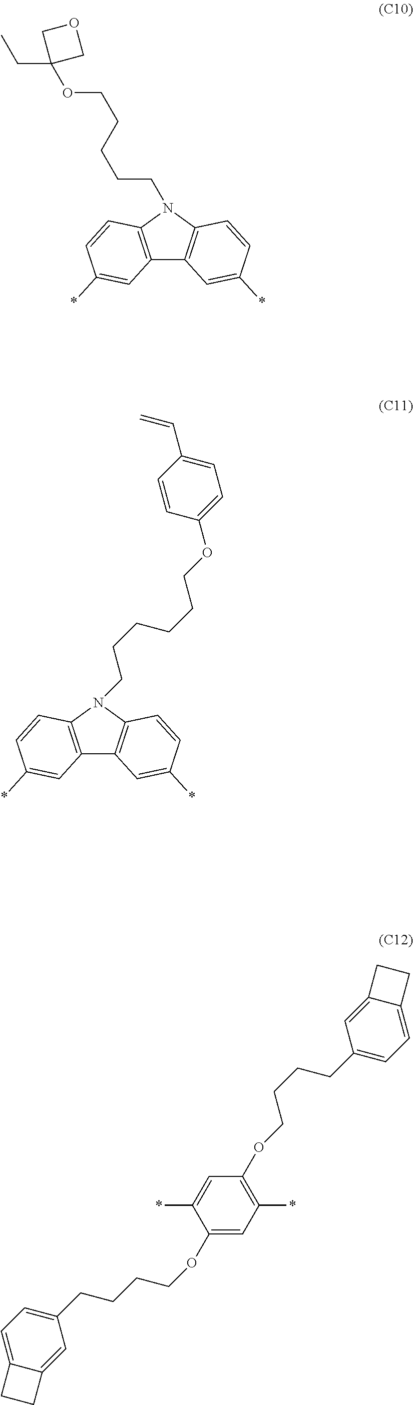

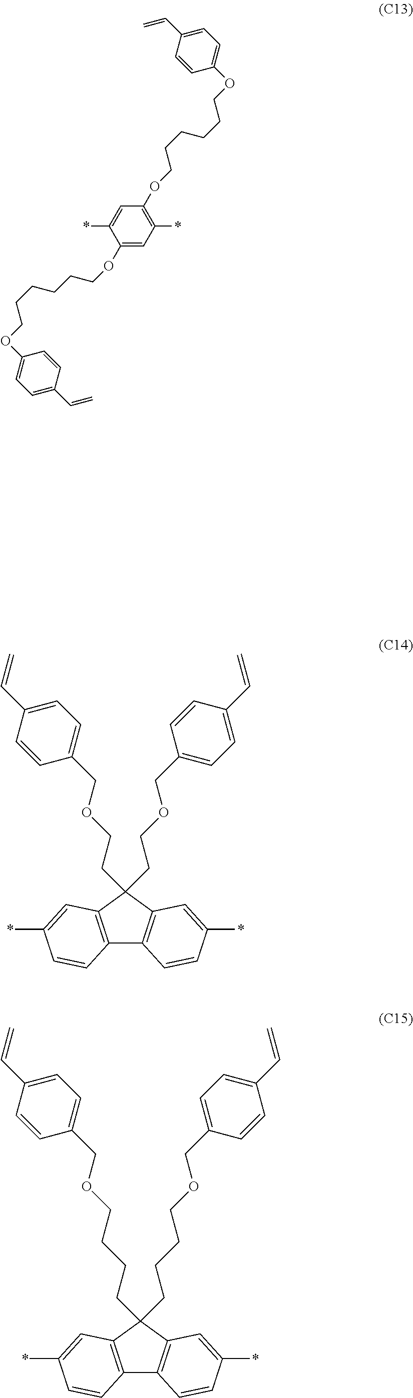

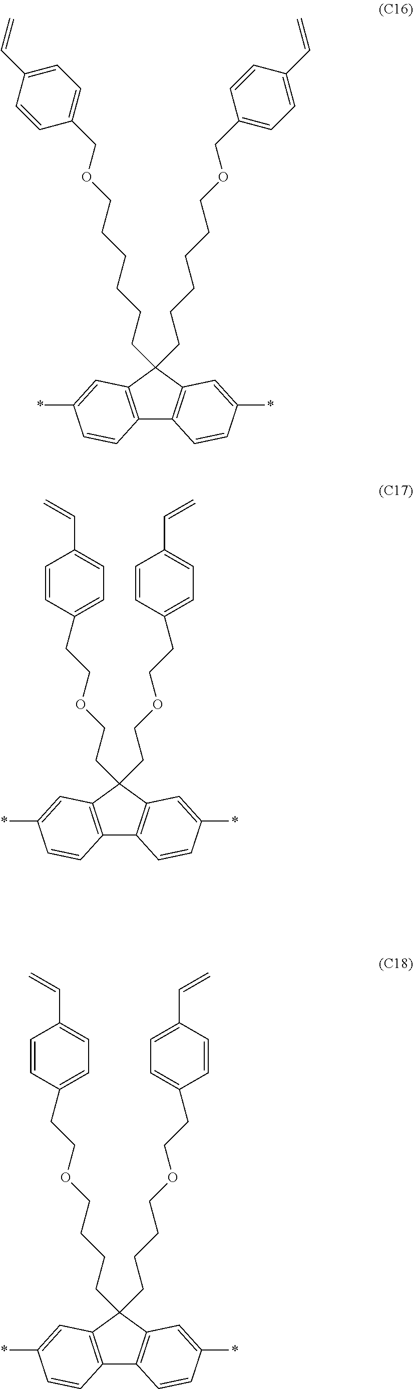

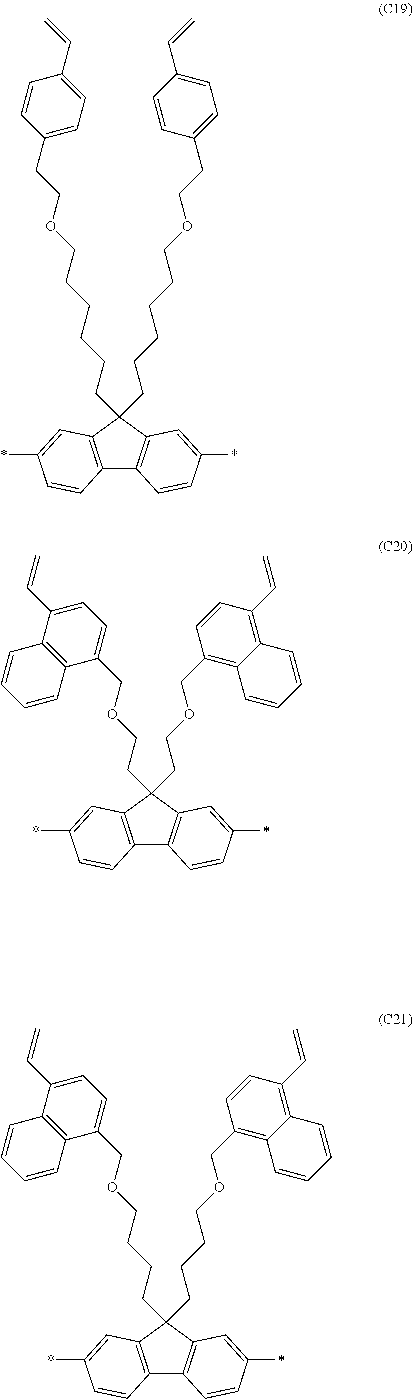

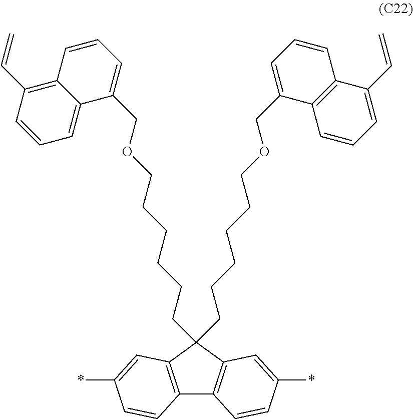

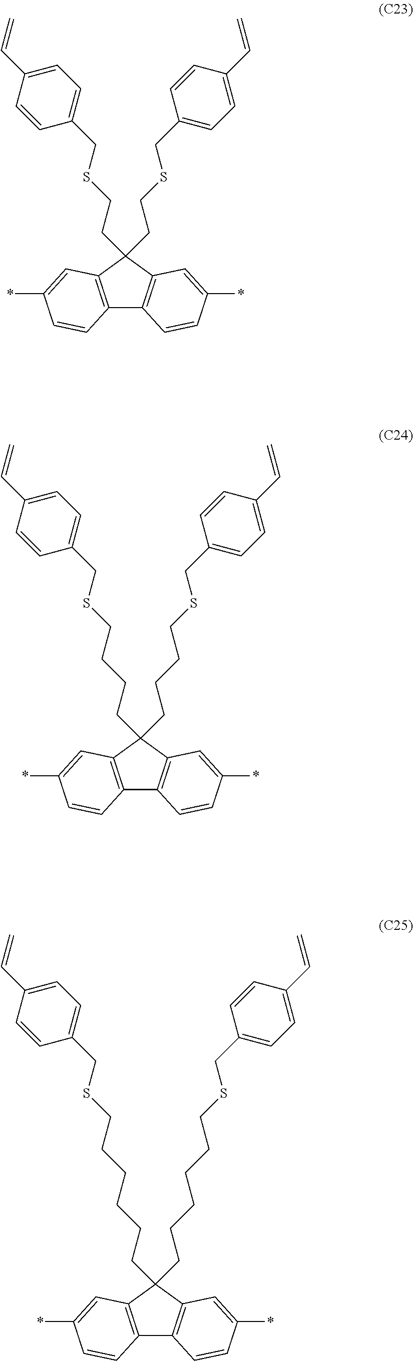

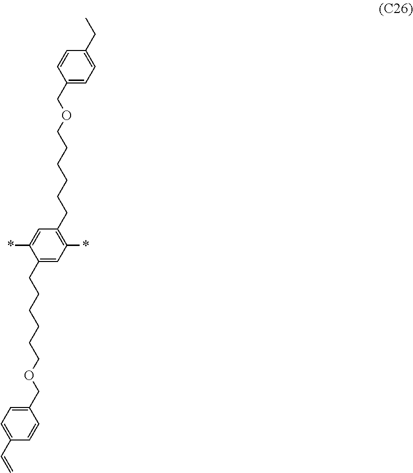

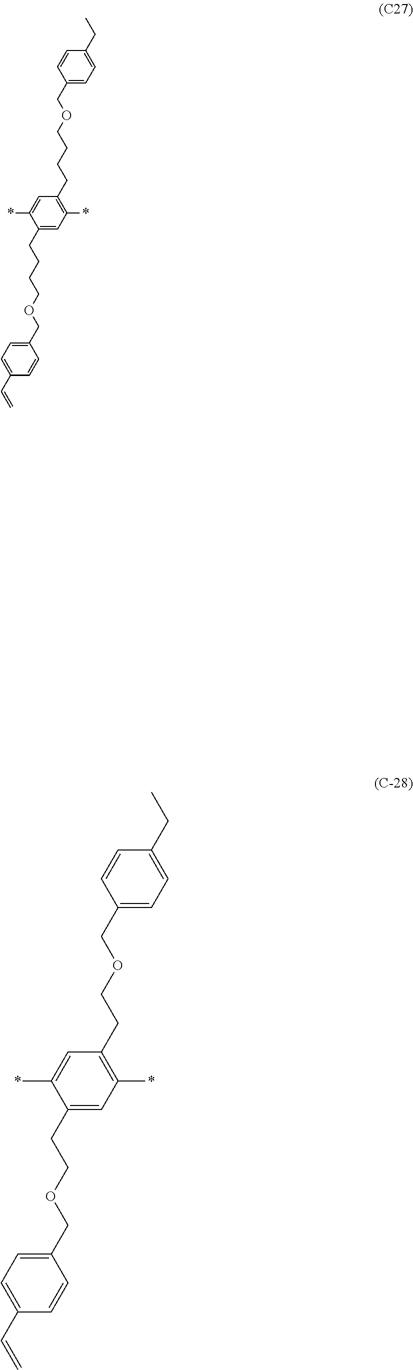

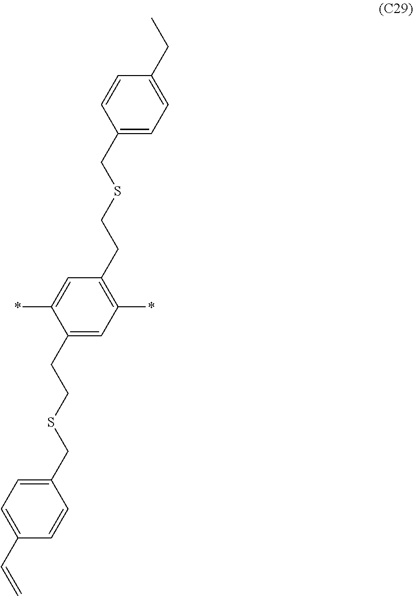

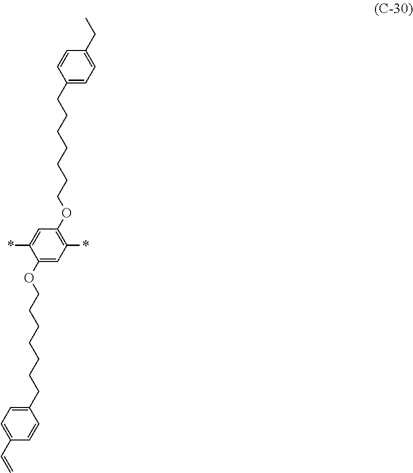

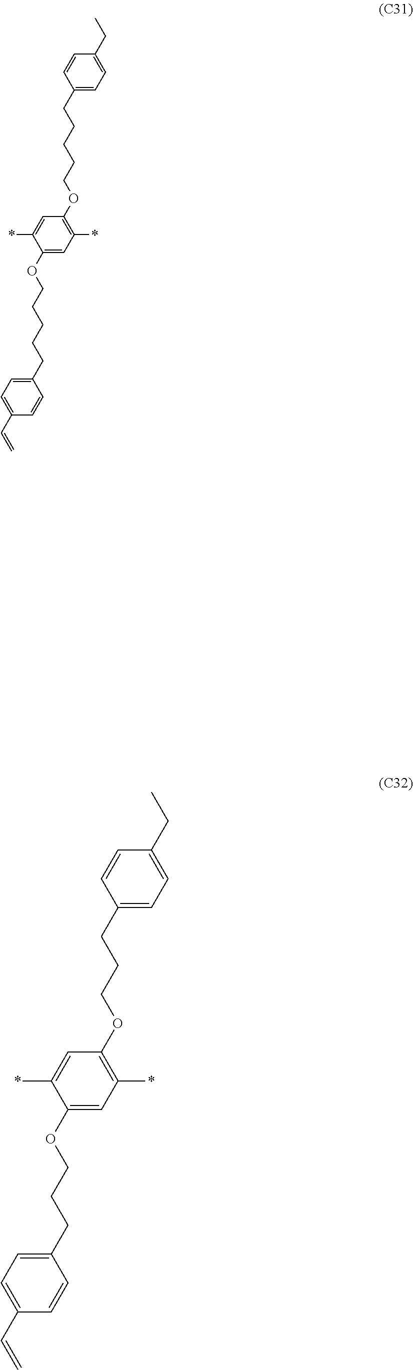

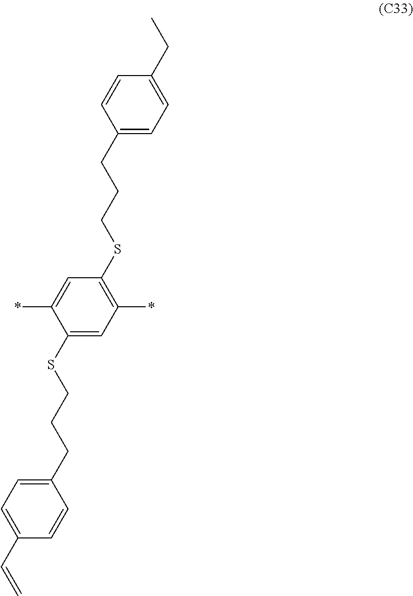

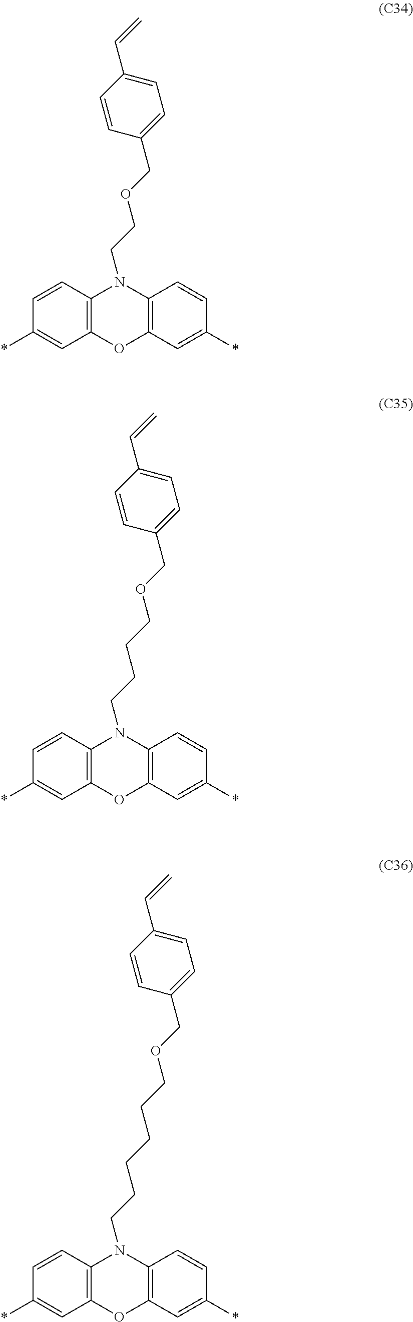

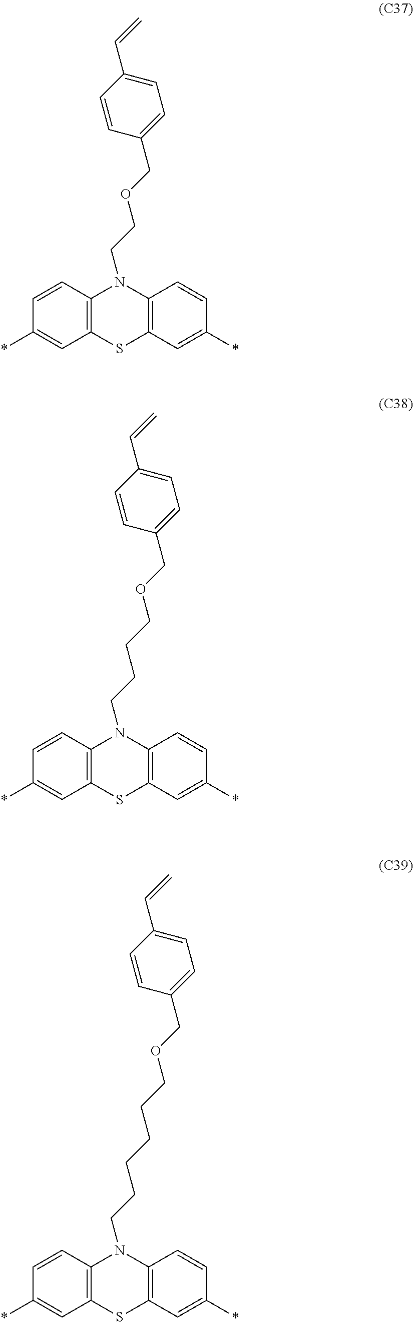

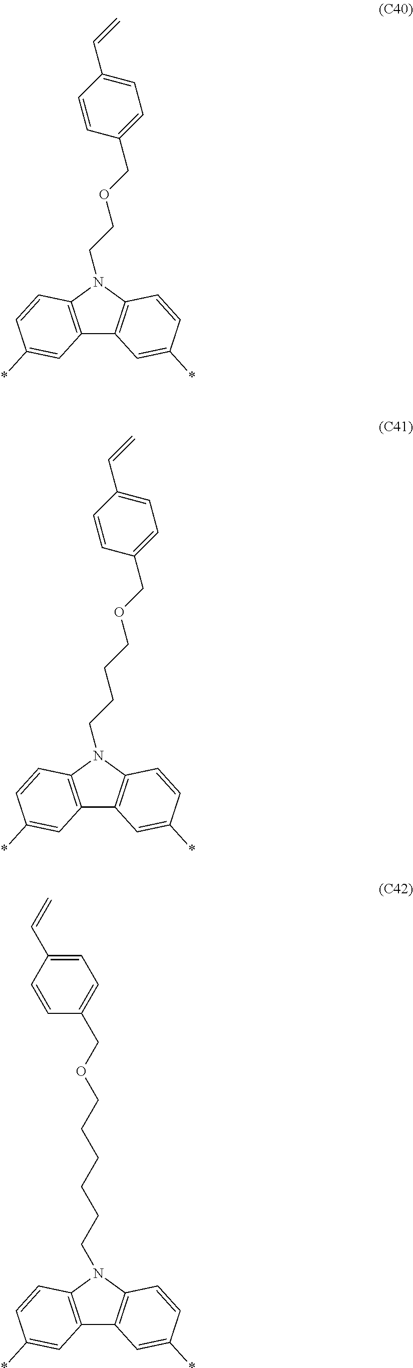

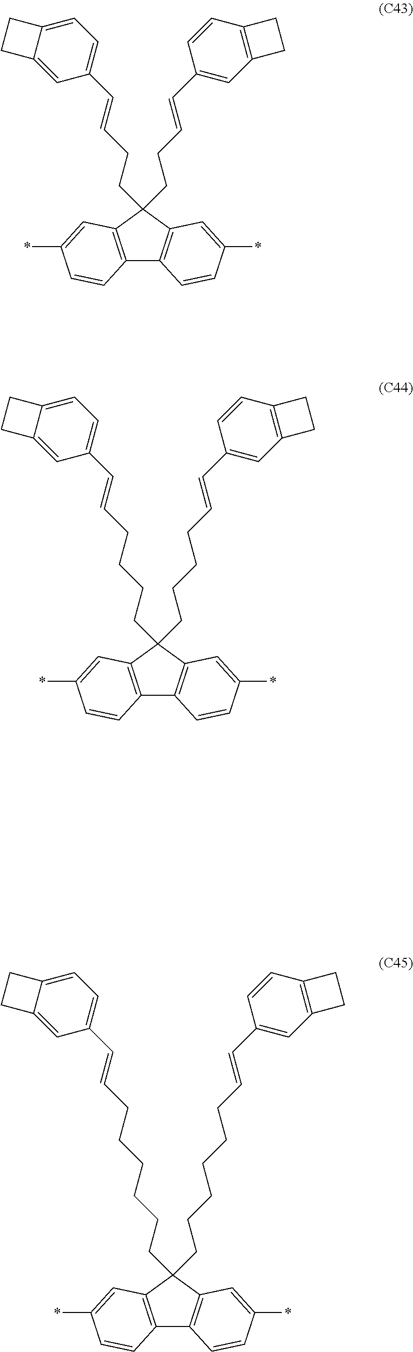

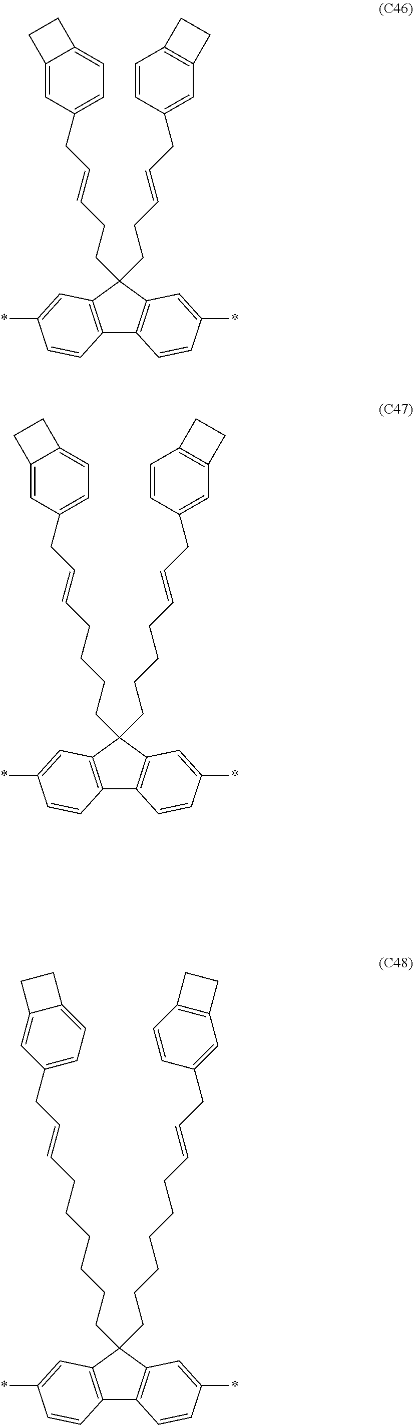

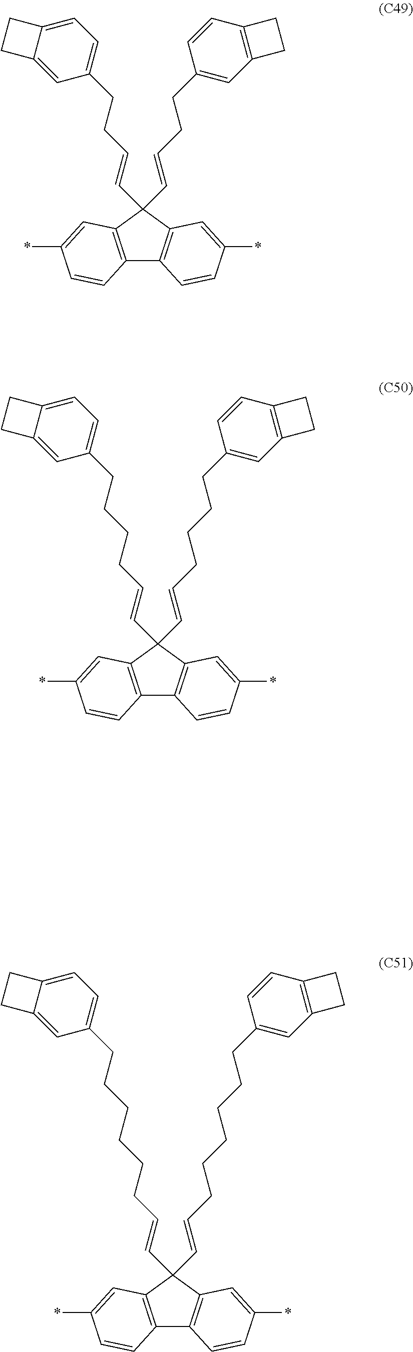

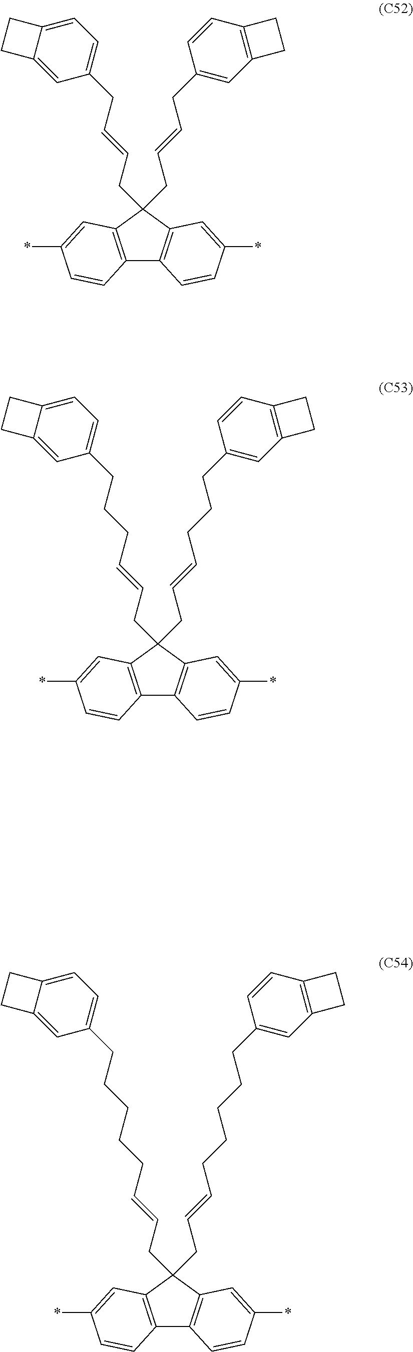

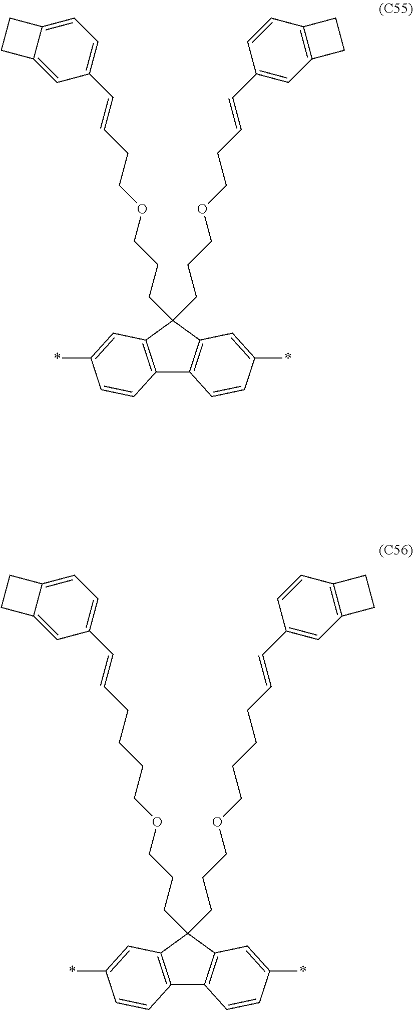

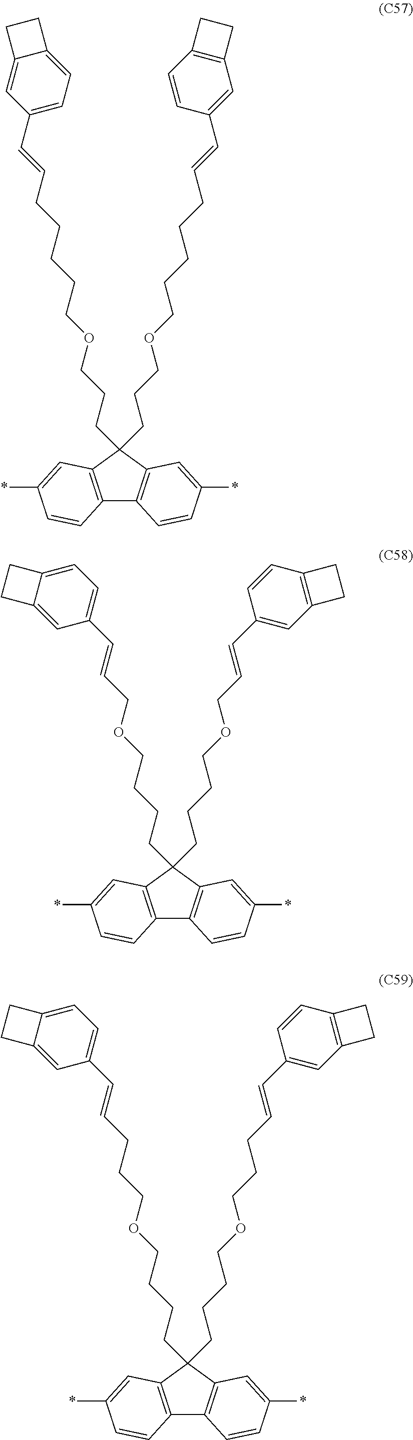

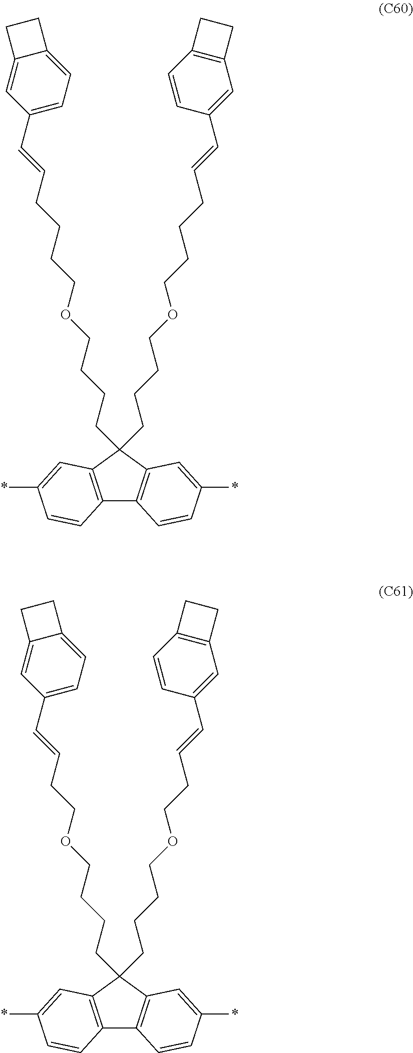

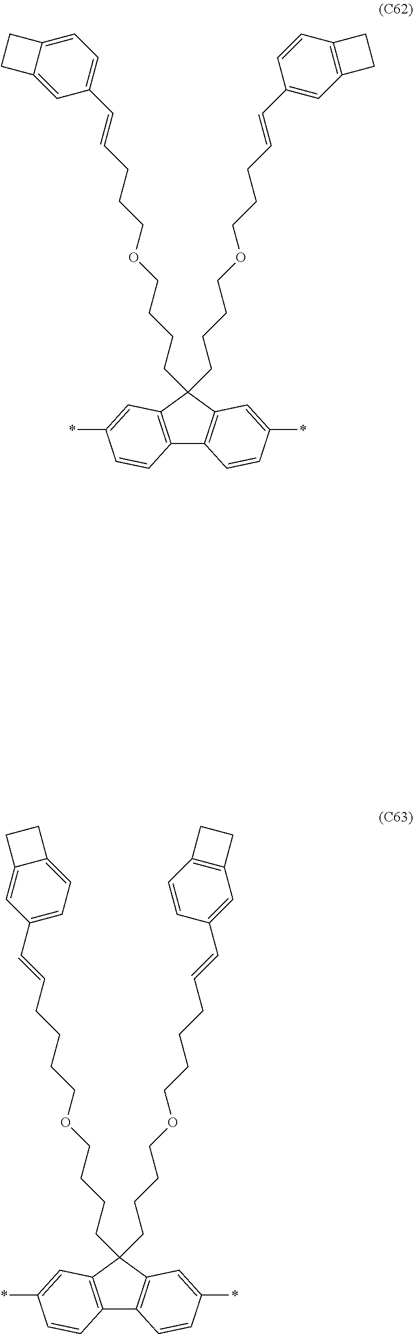

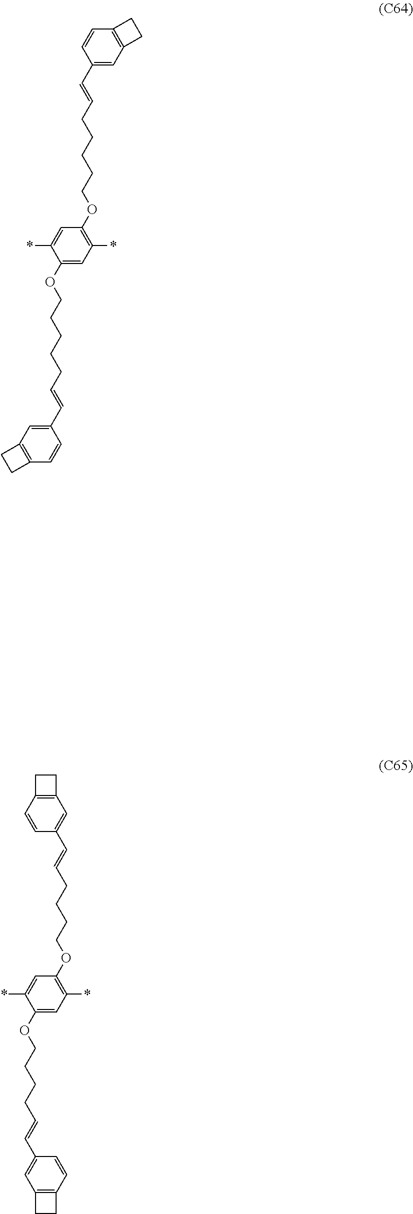

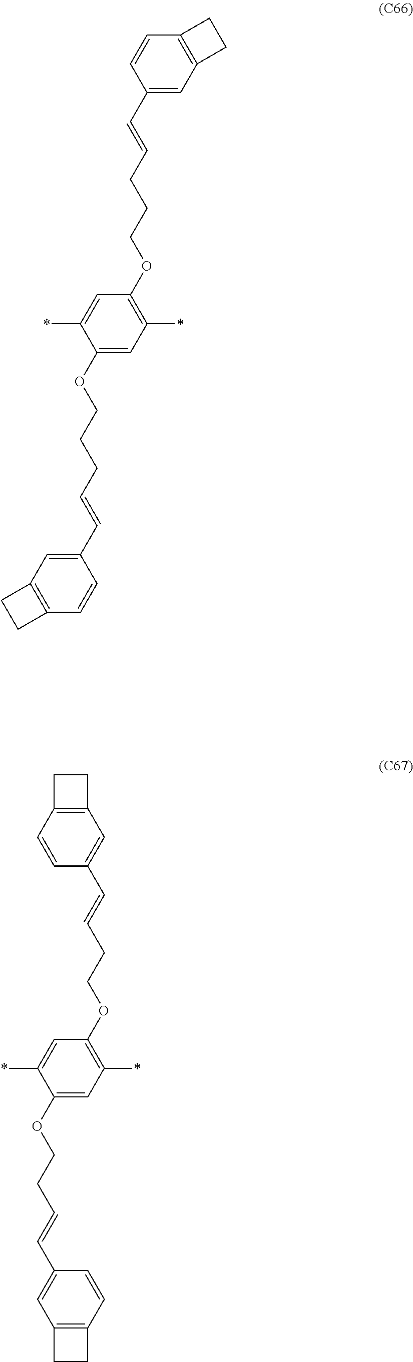

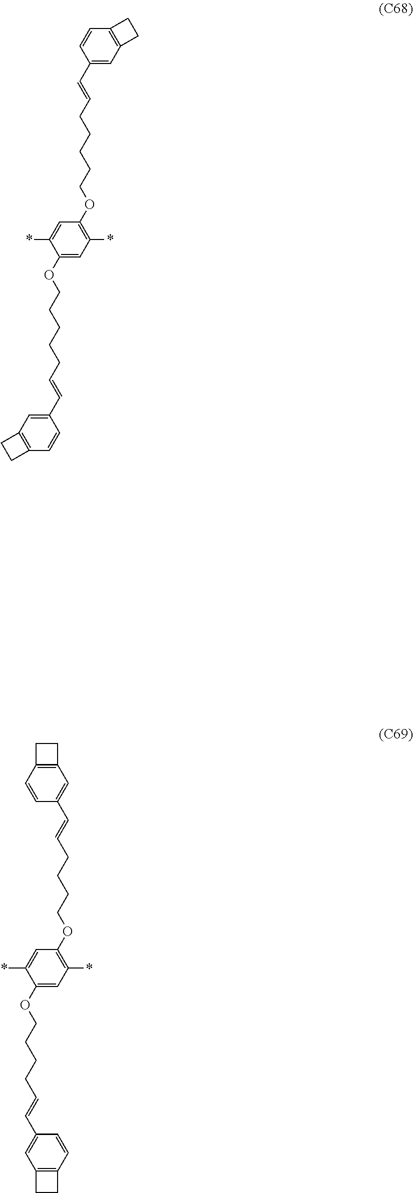

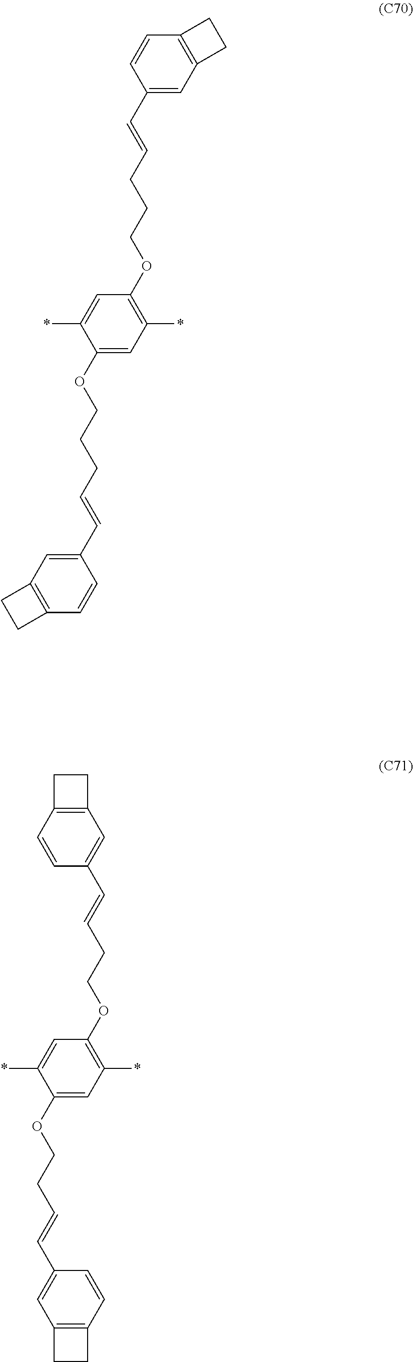

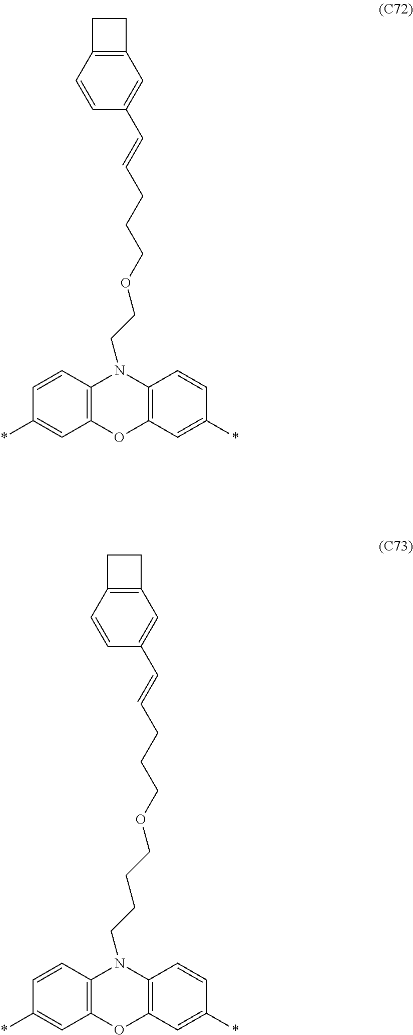

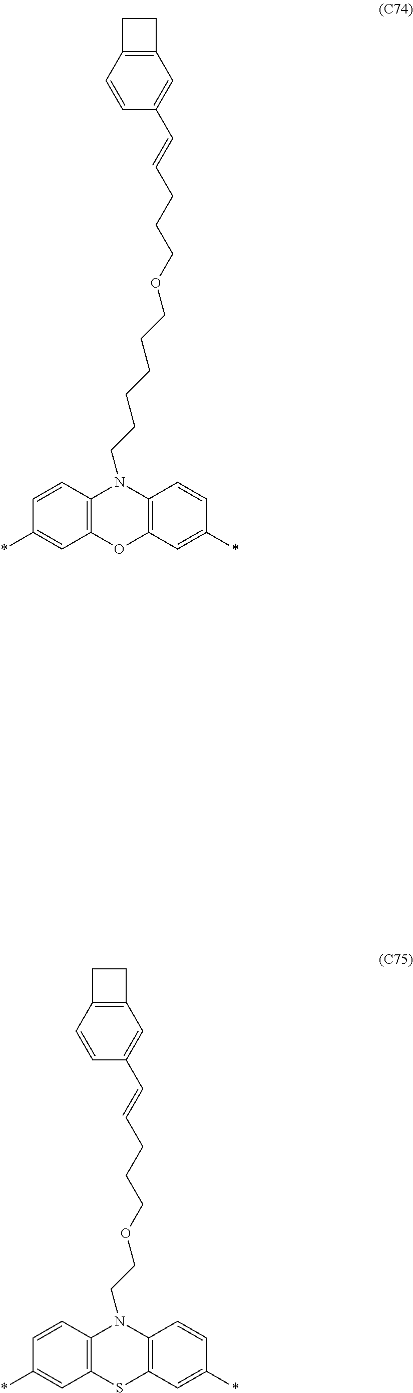

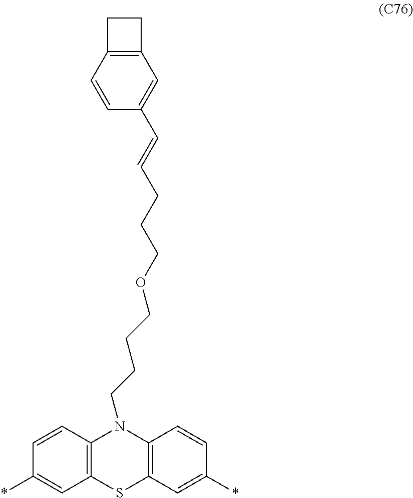

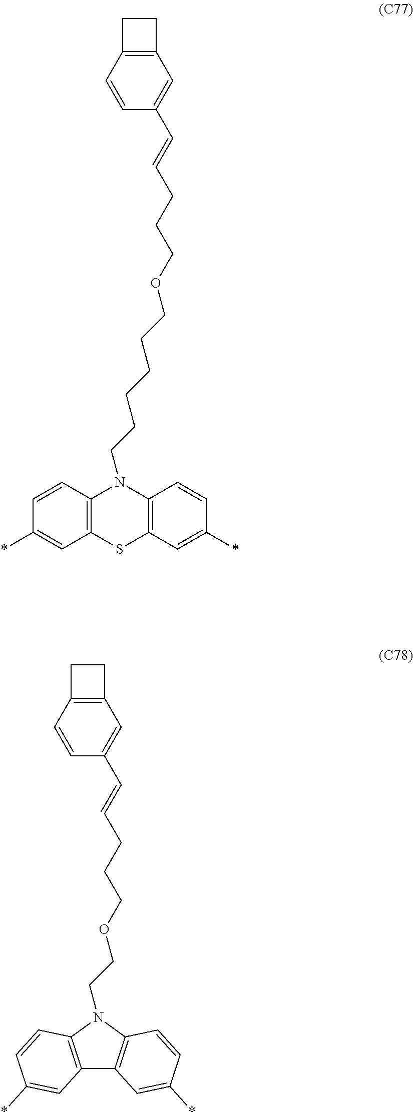

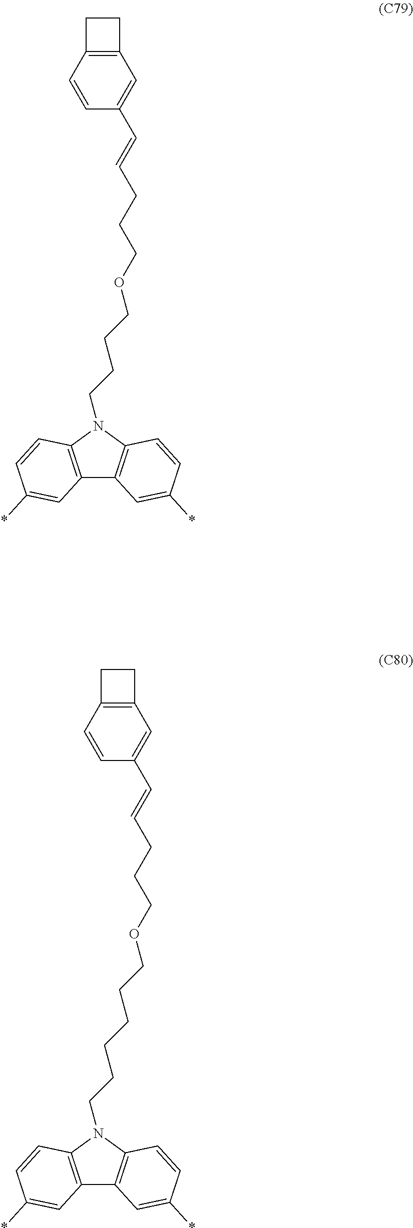

### Examples of High-Molecular Compound

Examples of specific combinations of the structural units (A) to (C) in the high-molecular compound of one aspect of the present invention are shown in Tables 1 to 9.

In Tables 1 to 9, the description of “kind of structural unit” corresponds to the above-mentioned structural units (A1) to (A96), structural units (B1) to (B94) and structural units (C1) to (C80).

TABLE 1

| | | |
|---|---|---|
| | | Content |
| | | Ratio of |
| High- | Kind of | Structural |
| Molecular | Structural | Unit |
| Compound | Unit | (mol %) |

| No. | (A) | (B) | (A) | (B) |
|---|---|---|---|---|
| 1 | A1 | B88 | 50 | 50 |
| 2 | A5 | B88 | 50 | 50 |
| 3 | A6 | B88 | 50 | 50 |
| 4 | A7 | B88 | 50 | 50 |
| 5 | A8 | B88 | 50 | 50 |
| 6 | A9 | B88 | 50 | 50 |
| 7 | A10 | B88 | 50 | 50 |
| 8 | A24 | B88 | 50 | 50 |
| 9 | A25 | B88 | 50 | 50 |
| 10 | A29 | B88 | 50 | 50 |
| 11 | A33 | B88 | 50 | 50 |
| 12 | A38 | B88 | 50 | 50 |
| 13 | A41 | B88 | 50 | 50 |
| 14 | A42 | B88 | 50 | 50 |
| 15 | A43 | B88 | 50 | 50 |
| 16 | A44 | B88 | 50 | 50 |
| 17 | A45 | B88 | 50 | 50 |
| 18 | A49 | B88 | 50 | 50 |
| 19 | A65 | B88 | 50 | 50 |
| 20 | A67 | B88 | 50 | 50 |
| 21 | A73 | B88 | 50 | 50 |
| 22 | A78 | B88 | 50 | 50 |
| 23 | A81 | B88 | 50 | 50 |
| 24 | A83 | B88 | 50 | 50 |
| 25 | A85 | B88 | 50 | 50 |
| 26 | A89 | B88 | 50 | 50 |
| 27 | A91 | B88 | 50 | 50 |
| 28 | A92 | B88 | 50 | 50 |

TABLE 2

| | | |
|---|---|---|
| | | Content |
| | | Ratio of |
| High- | Kind of | Structural |
| Molecular | Structural | Unit |
| Compound | Unit | (mol %) |

| No. | (A) | (B) | (A) | (B) |
|---|---|---|---|---|
| 29 | A1 | B95 | 50 | 50 |
| 30 | A5 | B95 | 50 | 50 |
| 31 | A6 | B95 | 50 | 50 |
| 32 | A7 | B95 | 50 | 50 |
| 33 | A8 | B95 | 50 | 50 |
| 34 | A9 | B95 | 50 | 50 |
| 35 | A10 | B95 | 50 | 50 |
| 36 | A24 | B95 | 50 | 50 |
| 37 | A25 | B95 | 50 | 50 |
| 38 | A29 | B95 | 50 | 50 |
| 39 | A33 | B95 | 50 | 50 |
| 40 | A38 | B95 | 50 | 50 |
| 41 | A41 | B95 | 50 | 50 |
| 42 | A42 | B95 | 50 | 50 |
| 43 | A43 | B95 | 50 | 50 |
| 44 | A44 | B95 | 50 | 50 |
| 45 | A45 | B95 | 50 | 50 |
| 46 | A49 | B95 | 50 | 50 |
| 47 | A65 | B95 | 50 | 50 |
| 48 | A67 | B95 | 50 | 50 |
| 49 | A73 | B95 | 50 | 50 |
| 50 | A78 | B95 | 50 | 50 |
| 51 | A81 | B95 | 50 | 50 |
| 52 | A83 | B95 | 50 | 50 |
| 53 | A85 | B95 | 50 | 50 |
| 54 | A89 | B95 | 50 | 50 |
| 55 | A91 | B95 | 50 | 50 |
| 56 | A92 | B95 | 50 | 50 |

TABLE 3

| | | |
|---|---|---|
| | | Content |
| | | Ratio of |
| High- | Kind of | Structural |
| Molecular | Structural | Unit |
| Compound | Unit | (mol %) |

| No. | (A) | (B) | (A) | (B) |
|---|---|---|---|---|
| 57 | A1 | B96 | 50 | 50 |
| 58 | A5 | B96 | 50 | 50 |
| 59 | A6 | B96 | 50 | 50 |
| 60 | A7 | B96 | 50 | 50 |
| 61 | A8 | B96 | 50 | 50 |
| 62 | A9 | B96 | 50 | 50 |
| 63 | A10 | B96 | 50 | 50 |
| 64 | A24 | B96 | 50 | 50 |
| 65 | A25 | B96 | 50 | 50 |
| 66 | A29 | B96 | 50 | 50 |
| 67 | A33 | B96 | 50 | 50 |
| 68 | A38 | B96 | 50 | 50 |
| 69 | A41 | B96 | 50 | 50 |
| 70 | A42 | B96 | 50 | 50 |
| 71 | A43 | B96 | 50 | 50 |
| 72 | A44 | B96 | 50 | 50 |
| 73 | A45 | B96 | 50 | 50 |
| 74 | A49 | B96 | 50 | 50 |
| 75 | A65 | B96 | 50 | 50 |
| 76 | A67 | B96 | 50 | 50 |
| 77 | A73 | B96 | 50 | 50 |
| 78 | A78 | B96 | 50 | 50 |
| 79 | A81 | B96 | 50 | 50 |
| 80 | A83 | B96 | 50 | 50 |
| 81 | A85 | B96 | 50 | 50 |
| 82 | A89 | B96 | 50 | 50 |
| 83 | A91 | B96 | 50 | 50 |
| 84 | A92 | B96 | 50 | 50 |

TABLE 4

| | | |
|---|---|---|
| | | Content |
| | | Ratio of |
| High- | Kind of | Structural |
| Molecular | Structural | Unit |
| Compound | Unit | (mol %) |

| No. | (A) | (B) | (A) | (B) |
|---|---|---|---|---|
| 85 | A1 | B92 | 50 | 50 |
| 86 | A5 | B92 | 50 | 50 |
| 87 | A6 | B92 | 50 | 50 |
| 88 | A7 | B92 | 50 | 50 |
| 89 | A8 | B92 | 50 | 50 |
| 90 | A9 | B92 | 50 | 50 |
| 91 | A10 | B92 | 50 | 50 |
| 92 | A24 | B92 | 50 | 50 |
| 93 | A25 | B92 | 50 | 50 |
| 94 | A29 | B92 | 50 | 50 |
| 95 | A33 | B92 | 50 | 50 |
| 96 | A38 | B92 | 50 | 50 |
| 97 | A41 | B92 | 50 | 50 |
| 98 | A42 | B92 | 50 | 50 |
| 99 | A43 | B92 | 50 | 50 |
| 100 | A44 | B92 | 50 | 50 |
| 101 | A45 | B92 | 50 | 50 |
| 102 | A49 | B92 | 50 | 50 |
| 103 | A65 | B92 | 50 | 50 |
| 104 | A67 | B92 | 50 | 50 |
| 105 | A73 | B92 | 50 | 50 |
| 106 | A78 | B92 | 50 | 50 |
| 107 | A81 | B92 | 50 | 50 |
| 108 | A83 | B92 | 50 | 50 |
| 109 | A85 | B92 | 50 | 50 |
| 110 | A89 | B92 | 50 | 50 |
| 111 | A91 | B92 | 50 | 50 |
| 112 | A92 | B92 | 50 | 50 |

TABLE 5

| | | |
|---|---|---|
| | | Content |
| | | Ratio of |
| High- | Kind of | Structural |
| Molecular | Structural | Unit |
| Compound | Unit | (mol %) |

| No. | (A) | (B) | (A) | (B) |
|---|---|---|---|---|
| 113 | A1 | B93 | 50 | 50 |
| 114 | A5 | B93 | 50 | 50 |
| 115 | A6 | B93 | 50 | 50 |
| 116 | A7 | B93 | 50 | 50 |
| 117 | A8 | B93 | 50 | 50 |
| 118 | A9 | B93 | 50 | 50 |
| 119 | A10 | B93 | 50 | 50 |
| 120 | A24 | B93 | 50 | 50 |
| 121 | A25 | B93 | 50 | 50 |
| 122 | A29 | B93 | 50 | 50 |
| 123 | A33 | B93 | 50 | 50 |
| 124 | A38 | B93 | 50 | 50 |
| 125 | A41 | B93 | 50 | 50 |
| 126 | A42 | B93 | 50 | 50 |
| 127 | A43 | B93 | 50 | 50 |
| 128 | A44 | B93 | 50 | 50 |
| 129 | A45 | B93 | 50 | 50 |
| 130 | A49 | B93 | 50 | 50 |
| 131 | A65 | B93 | 50 | 50 |
| 132 | A67 | B93 | 50 | 50 |
| 133 | A73 | B93 | 50 | 50 |
| 134 | A78 | B93 | 50 | 50 |
| 135 | A81 | B93 | 50 | 50 |
| 136 | A83 | B93 | 50 | 50 |
| 137 | A85 | B93 | 50 | 50 |
| 138 | A89 | B93 | 50 | 50 |
| 139 | A91 | B93 | 50 | 50 |
| 140 | A92 | B93 | 50 | 50 |

TABLE 6

| | | | | Content | | |
|---|---|---|---|---|---|---|
| | | | | Ratio of | | |
| High- | | | | Structural | | |
| Molecular | Kind of | | | Unit | | |
| Compound | Structural Unit | | | (mol %) | | |
| No. | (A) | (B) | (C) | (A) | (B) | (C) |
| 141 | A1 | B88 | C1 | 50 | 45 | 5 |
| 142 | A5 | B88 | C1 | 50 | 45 | 5 |
| 143 | A6 | B88 | C1 | 50 | 45 | 5 |
| 144 | A7 | B88 | C1 | 50 | 45 | 5 |
| 145 | A8 | B88 | C1 | 50 | 45 | 5 |
| 146 | A9 | B88 | C1 | 50 | 45 | 5 |
| 147 | A10 | B88 | C1 | 50 | 45 | 5 |
| 148 | A24 | B88 | C1 | 50 | 45 | 5 |
| 149 | A25 | B88 | C1 | 50 | 45 | 5 |
| 150 | A29 | B88 | C1 | 50 | 45 | 5 |
| 151 | A33 | B88 | C1 | 50 | 45 | 5 |
| 152 | A38 | B88 | C1 | 50 | 45 | 5 |
| 153 | A41 | B88 | C1 | 50 | 45 | 5 |
| 154 | A42 | B88 | C1 | 50 | 45 | 5 |
| 155 | A43 | B88 | C1 | 50 | 45 | 5 |
| 156 | A44 | B88 | C1 | 50 | 45 | 5 |
| 157 | A45 | B88 | C1 | 50 | 45 | 5 |
| 158 | A49 | B88 | C1 | 50 | 45 | 5 |
| 159 | A65 | B88 | C1 | 50 | 45 | 5 |
| 160 | A67 | B88 | C1 | 50 | 45 | 5 |
| 161 | A73 | B88 | C1 | 50 | 45 | 5 |
| 162 | A78 | B88 | C1 | 50 | 45 | 5 |
| 163 | A81 | B88 | C1 | 50 | 45 | 5 |
| 164 | A83 | B88 | C1 | 50 | 45 | 5 |
| 165 | A85 | B88 | C1 | 50 | 45 | 5 |
| 166 | A89 | B88 | C1 | 50 | 45 | 5 |
| 167 | A91 | B88 | C1 | 50 | 45 | 5 |
| 168 | A92 | B88 | C1 | 50 | 45 | 5 |

TABLE 7

| High- | | | | | | |
|---|---|---|---|---|---|---|
| Molecular | Kind of Structural | | | Content Ratio of Structural | | |
| Compound | Unit | | | Unit (mol %) | | |
| No. | (A) | (B) | (C) | (A) | (B) | (C) |
| 169 | A1 | B88 | C1 | 47 | 50 | 3 |
| 170 | A5 | B88 | C1 | 47 | 50 | 3 |
| 171 | A6 | B88 | C1 | 47 | 50 | 3 |
| 172 | A7 | B88 | C1 | 47 | 50 | 3 |
| 173 | A8 | B88 | C1 | 47 | 50 | 3 |
| 174 | A9 | B88 | C1 | 47 | 50 | 3 |
| 175 | A10 | B88 | C1 | 47 | 50 | 3 |
| 176 | A24 | B88 | C1 | 47 | 50 | 3 |
| 177 | A25 | B88 | C1 | 47 | 50 | 3 |
| 178 | A29 | B88 | C1 | 47 | 50 | 3 |
| 179 | A33 | B88 | C1 | 47 | 50 | 3 |
| 180 | A38 | B88 | C1 | 47 | 50 | 3 |
| 181 | A41 | B88 | C1 | 47 | 50 | 3 |
| 182 | A42 | B88 | C1 | 47 | 50 | 3 |
| 183 | A43 | B88 | C1 | 47 | 50 | 3 |
| 184 | A44 | B88 | C1 | 47 | 50 | 3 |
| 185 | A45 | B88 | C1 | 47 | 50 | 3 |
| 186 | A49 | B88 | C1 | 47 | 50 | 3 |
| 187 | A65 | B88 | C1 | 47 | 50 | 3 |
| 188 | A67 | B88 | C1 | 47 | 50 | 3 |
| 189 | A73 | B88 | C1 | 47 | 50 | 3 |
| 190 | A78 | B88 | C1 | 47 | 50 | 3 |
| 191 | A81 | B88 | C1 | 47 | 50 | 3 |
| 192 | A83 | B88 | C1 | 47 | 50 | 3 |
| 193 | A85 | B88 | C1 | 47 | 50 | 3 |
| 194 | A89 | B88 | C1 | 47 | 50 | 3 |
| 195 | A91 | B88 | C1 | 47 | 50 | 3 |
| 196 | A92 | B88 | C1 | 47 | 50 | 3 |

TABLE 8

| High- | | | | | | |
|---|---|---|---|---|---|---|
| Molecular | Kind of Structural | | | Content Ratio of Structural | | |
| Compound | Unit | | | Unit (mol %) | | |
| No. | (A) | (B) | (C) | (A) | (B) | (C) |
| 197 | A1 | B88 | C5 | 42 | 50 | 8 |
| 198 | A5 | B88 | C5 | 42 | 50 | 8 |
| 199 | A6 | B88 | C5 | 42 | 50 | 8 |
| 200 | A7 | B88 | C5 | 42 | 50 | 8 |
| 201 | A8 | B88 | C5 | 42 | 50 | 8 |
| 202 | A9 | B88 | C5 | 42 | 50 | 8 |
| 203 | A10 | B88 | C5 | 42 | 50 | 8 |
| 204 | A24 | B88 | C5 | 42 | 50 | 8 |
| 205 | A25 | B88 | C5 | 42 | 50 | 8 |
| 206 | A29 | B88 | C5 | 42 | 50 | 8 |
| 207 | A33 | B88 | C5 | 42 | 50 | 8 |
| 208 | A38 | B88 | C5 | 42 | 50 | 8 |
| 209 | A41 | B88 | C5 | 42 | 50 | 8 |
| 210 | A42 | B88 | C5 | 42 | 50 | 8 |
| 211 | A43 | B88 | C5 | 42 | 50 | 8 |
| 212 | A44 | B88 | C5 | 42 | 50 | 8 |
| 213 | A45 | B88 | C5 | 42 | 50 | 8 |
| 214 | A49 | B88 | C5 | 42 | 50 | 8 |
| 215 | A65 | B88 | C5 | 42 | 50 | 8 |
| 216 | A67 | B88 | C5 | 42 | 50 | 8 |
| 217 | A73 | B88 | C5 | 42 | 50 | 8 |
| 218 | A78 | B88 | C5 | 42 | 50 | 8 |
| 219 | A81 | B88 | C5 | 42 | 50 | 8 |
| 220 | A83 | B88 | C5 | 42 | 50 | 8 |
| 221 | A85 | B88 | C5 | 42 | 50 | 8 |
| 222 | A89 | B88 | C5 | 42 | 50 | 8 |
| 223 | A91 | B88 | C5 | 42 | 50 | 8 |
| 224 | A92 | B88 | C5 | 42 | 50 | 8 |

TABLE 9

| High- | | | | | | |
|---|---|---|---|---|---|---|
| Molecular | Kind of Structural | | | Content Ratio of Structural | | |
| Compound | Unit | | | Unit (mol %) | | |
| No. | (A) | (B) | (C) | (A) | (B) | (C) |
| 225 | A1 | B88 | C6 | 45 | 50 | 5 |
| 226 | A5 | B88 | C6 | 45 | 50 | 5 |
| 227 | A6 | B88 | C6 | 45 | 50 | 5 |
| 228 | A7 | B88 | C6 | 45 | 50 | 5 |
| 229 | A8 | B88 | C6 | 45 | 50 | 5 |
| 230 | A9 | B88 | C6 | 45 | 50 | 5 |
| 231 | A10 | B88 | C6 | 45 | 50 | 5 |
| 232 | A24 | B88 | C6 | 45 | 50 | 5 |
| 233 | A25 | B88 | C6 | 45 | 50 | 5 |
| 234 | A29 | B88 | C6 | 45 | 50 | 5 |
| 235 | A33 | B88 | C6 | 45 | 50 | 5 |
| 236 | A38 | B88 | C6 | 45 | 50 | 5 |
| 237 | A41 | B88 | C6 | 45 | 50 | 5 |
| 238 | A42 | B88 | C6 | 45 | 50 | 5 |
| 239 | A43 | B88 | C6 | 45 | 50 | 5 |
| 240 | A44 | B88 | C6 | 45 | 50 | 5 |
| 241 | A45 | B88 | C6 | 45 | 50 | 5 |
| 242 | A49 | B88 | C6 | 45 | 50 | 5 |
| 243 | A65 | B88 | C6 | 45 | 50 | 5 |
| 244 | A67 | B88 | C6 | 45 | 50 | 5 |
| 245 | A73 | B88 | C6 | 45 | 50 | 5 |
| 246 | A78 | B88 | C6 | 45 | 50 | 5 |
| 247 | A81 | B88 | C6 | 45 | 50 | 5 |
| 248 | A83 | B88 | C6 | 45 | 50 | 5 |
| 249 | A85 | B88 | C6 | 45 | 50 | 5 |
| 250 | A89 | B88 | C6 | 45 | 50 | 5 |
| 251 | A91 | B88 | C6 | 45 | 50 | 5 |
| 252 | A92 | B88 | C6 | 45 | 50 | 5 |

TABLE 10

| High- | | | | | | |
|---|---|---|---|---|---|---|
| Molecular | Kind of Structural | | | Content Ratio of Structural | | |
| Compound | Unit | | | Unit (mol %) | | |
| No. | (A) | (B) | (C) | (A) | (B) | (C) |
| 253 | A1 | B92 | C1 | 48 | 50 | 2 |
| 254 | A5 | B92 | C1 | 48 | 50 | 2 |
| 255 | A6 | B92 | C1 | 48 | 50 | 2 |
| 256 | A7 | B92 | C1 | 48 | 50 | 2 |
| 257 | A8 | B92 | C1 | 48 | 50 | 2 |
| 258 | A9 | B92 | C1 | 48 | 50 | 2 |
| 259 | A10 | B92 | C1 | 48 | 50 | 2 |
| 260 | A24 | B92 | C1 | 48 | 50 | 2 |
| 261 | A25 | B92 | C1 | 48 | 50 | 2 |
| 262 | A29 | B92 | C1 | 48 | 50 | 2 |
| 263 | A33 | B92 | C1 | 48 | 50 | 2 |
| 264 | A38 | B92 | C1 | 48 | 50 | 2 |
| 265 | A41 | B92 | C1 | 48 | 50 | 2 |
| 266 | A42 | B92 | C1 | 48 | 50 | 2 |
| 267 | A43 | B92 | C1 | 48 | 50 | 2 |
| 268 | A44 | B92 | C1 | 48 | 50 | 2 |
| 269 | A45 | B92 | C1 | 48 | 50 | 2 |
| 270 | A49 | B92 | C1 | 48 | 50 | 2 |
| 271 | A65 | B92 | C1 | 48 | 50 | 2 |
| 272 | A67 | B92 | C1 | 48 | 50 | 2 |
| 273 | A73 | B92 | C1 | 48 | 50 | 2 |
| 274 | A78 | B92 | C1 | 48 | 50 | 2 |
| 275 | A81 | B92 | C1 | 48 | 50 | 2 |
| 276 | A83 | B92 | C1 | 48 | 50 | 2 |
| 277 | A85 | B92 | C1 | 48 | 50 | 2 |
| 278 | A89 | B92 | C1 | 48 | 50 | 2 |
| 279 | A91 | B92 | C1 | 48 | 50 | 2 |
| 280 | A92 | B92 | C1 | 48 | 50 | 2 |

TABLE 11

| High- | | | | | | |
|---|---|---|---|---|---|---|
| Molecular | Kind of Structural | | | Content Ratio of Structural | | |
| Compound | Unit | | | Unit (mol %) | | |
| No. | (A) | (B) | (C) | (A) | (B) | (C) |
| 281 | A1 | B92 | C5 | 40 | 50 | 10 |
| 282 | A5 | B92 | C5 | 40 | 50 | 10 |
| 283 | A6 | B92 | C5 | 40 | 50 | 10 |
| 284 | A7 | B92 | C5 | 40 | 50 | 10 |
| 285 | A8 | B92 | C5 | 40 | 50 | 10 |
| 286 | A9 | B92 | C5 | 40 | 50 | 10 |
| 287 | A10 | B92 | C5 | 40 | 50 | 10 |
| 288 | A24 | B92 | C5 | 40 | 50 | 10 |
| 289 | A25 | B92 | C5 | 40 | 50 | 10 |
| 290 | A29 | B92 | C5 | 40 | 50 | 10 |
| 291 | A33 | B92 | C5 | 40 | 50 | 10 |
| 292 | A38 | B92 | C5 | 40 | 50 | 10 |
| 293 | A41 | B92 | C5 | 40 | 50 | 10 |
| 294 | A42 | B92 | C5 | 40 | 50 | 10 |
| 295 | A43 | B92 | C5 | 40 | 50 | 10 |
| 296 | A44 | B92 | C5 | 40 | 50 | 10 |
| 297 | A45 | B92 | C5 | 40 | 50 | 10 |
| 298 | A49 | B92 | C5 | 40 | 50 | 10 |
| 299 | A65 | B92 | C5 | 40 | 50 | 10 |
| 300 | A67 | B92 | C5 | 40 | 50 | 10 |
| 301 | A73 | B92 | C5 | 40 | 50 | 10 |
| 302 | A78 | B92 | C5 | 40 | 50 | 10 |
| 303 | A81 | B92 | C5 | 40 | 50 | 10 |
| 304 | A83 | B92 | C5 | 40 | 50 | 10 |
| 305 | A85 | B92 | C5 | 40 | 50 | 10 |
| 306 | A89 | B92 | C5 | 40 | 50 | 10 |
| 307 | A91 | B92 | C5 | 40 | 50 | 10 |
| 308 | A92 | B92 | C5 | 40 | 50 | 10 |

TABLE 12

| High- | | | | | | |
|---|---|---|---|---|---|---|
| Molecular | Kind of Structural | | | Content Ratio of Structural | | |
| Compound | Unit | | | Unit (mol %) | | |
| No. | (A) | (B) | (C) | (A) | (B) | (C) |
| 309 | A1 | B92 | C6 | 45 | 50 | 5 |
| 310 | A5 | B92 | C6 | 45 | 50 | 5 |
| 311 | A6 | B92 | C6 | 45 | 50 | 5 |
| 312 | A7 | B92 | C6 | 45 | 50 | 5 |
| 313 | A8 | B92 | C6 | 45 | 50 | 5 |
| 314 | A9 | B92 | C6 | 45 | 50 | 5 |
| 315 | A10 | B92 | C6 | 45 | 50 | 5 |
| 316 | A24 | B92 | C6 | 45 | 50 | 5 |
| 317 | A25 | B92 | C6 | 45 | 50 | 5 |
| 318 | A29 | B92 | C6 | 45 | 50 | 5 |
| 319 | A33 | B92 | C6 | 45 | 50 | 5 |
| 320 | A38 | B92 | C6 | 45 | 50 | 5 |
| 321 | A41 | B92 | C6 | 45 | 50 | 5 |
| 322 | A42 | B92 | C6 | 45 | 50 | 5 |
| 323 | A43 | B92 | C6 | 45 | 50 | 5 |
| 324 | A44 | B92 | C6 | 45 | 50 | 5 |
| 325 | A45 | B92 | C6 | 45 | 50 | 5 |
| 326 | A49 | B92 | C6 | 45 | 50 | 5 |
| 327 | A65 | B92 | C6 | 45 | 50 | 5 |
| 328 | A67 | B92 | C6 | 45 | 50 | 5 |
| 329 | A73 | B92 | C6 | 45 | 50 | 5 |
| 330 | A78 | B92 | C6 | 45 | 50 | 5 |
| 331 | A81 | B92 | C6 | 45 | 50 | 5 |
| 332 | A83 | B92 | C6 | 45 | 50 | 5 |
| 333 | A85 | B92 | C6 | 45 | 50 | 5 |
| 334 | A89 | B92 | C6 | 45 | 50 | 5 |
| 335 | A91 | B92 | C6 | 45 | 50 | 5 |
| 336 | A92 | B92 | C6 | 45 | 50 | 5 |

TABLE 13

| High- | | | | | | |
|---|---|---|---|---|---|---|
| Molecular | Kind of Structural | | | Content Ratio of Structural | | |
| Compound | Unit | | | Unit (mol %) | | |
| No. | (A) | (B) | (C) | (A) | (B) | (C) |
| 337 | A1 | B93 | C1 | 49 | 50 | 1 |
| 338 | A5 | B93 | C1 | 49 | 50 | 1 |
| 339 | A6 | B93 | C1 | 49 | 50 | 1 |
| 340 | A7 | B93 | C1 | 49 | 50 | 1 |
| 341 | A8 | B93 | C1 | 49 | 50 | 1 |
| 342 | A9 | B93 | C1 | 49 | 50 | 1 |
| 343 | A10 | B93 | C1 | 49 | 50 | 1 |
| 344 | A24 | B93 | C1 | 49 | 50 | 1 |
| 345 | A25 | B93 | C1 | 49 | 50 | 1 |
| 346 | A29 | B93 | C1 | 49 | 50 | 1 |
| 347 | A33 | B93 | C1 | 49 | 50 | 1 |
| 348 | A38 | B93 | C1 | 49 | 50 | 1 |
| 349 | A41 | B93 | C1 | 49 | 50 | 1 |
| 350 | A42 | B93 | C1 | 49 | 50 | 1 |
| 351 | A43 | B93 | C1 | 49 | 50 | 1 |
| 352 | A44 | B93 | C1 | 49 | 50 | 1 |
| 353 | A45 | B93 | C1 | 49 | 50 | 1 |
| 354 | A49 | B93 | C1 | 49 | 50 | 1 |
| 355 | A65 | B93 | C1 | 49 | 50 | 1 |
| 356 | A67 | B93 | C1 | 49 | 50 | 1 |
| 357 | A73 | B93 | C1 | 49 | 50 | 1 |
| 358 | A78 | B93 | C1 | 49 | 50 | 1 |
| 359 | A81 | B93 | C1 | 49 | 50 | 1 |
| 360 | A83 | B93 | C1 | 49 | 50 | 1 |
| 361 | A85 | B93 | C1 | 49 | 50 | 1 |
| 362 | A89 | B93 | C1 | 49 | 50 | 1 |
| 363 | A91 | B93 | C1 | 49 | 50 | 1 |
| 364 | A92 | B93 | C1 | 49 | 50 | 1 |

TABLE 14

| High- | | | | | | |
|---|---|---|---|---|---|---|
| Molecular | Kind of Structural | | | Content Ratio of Structural | | |
| Compound | Unit | | | Unit (mol %) | | |
| No. | (A) | (B) | (C) | (A) | (B) | (C) |
| 365 | A1 | B93 | C5 | 42 | 50 | 8 |
| 366 | A5 | B93 | C5 | 42 | 50 | 8 |
| 367 | A6 | B93 | C5 | 42 | 50 | 8 |
| 368 | A7 | B93 | C5 | 42 | 50 | 8 |
| 369 | A8 | B93 | C5 | 42 | 50 | 8 |
| 370 | A9 | B93 | C5 | 42 | 50 | 8 |
| 371 | A10 | B93 | C5 | 42 | 50 | 8 |
| 372 | A24 | B93 | C5 | 42 | 50 | 8 |
| 373 | A25 | B93 | C5 | 42 | 50 | 8 |
| 374 | A29 | B93 | C5 | 42 | 50 | 8 |
| 375 | A33 | B93 | C5 | 42 | 50 | 8 |
| 376 | A38 | B93 | C5 | 42 | 50 | 8 |
| 377 | A41 | B93 | C5 | 42 | 50 | 8 |
| 378 | A42 | B93 | C5 | 42 | 50 | 8 |
| 379 | A43 | B93 | C5 | 42 | 50 | 8 |
| 380 | A44 | B93 | C5 | 42 | 50 | 8 |
| 381 | A45 | B93 | C5 | 42 | 50 | 8 |
| 382 | A49 | B93 | C5 | 42 | 50 | 8 |
| 383 | A65 | B93 | C5 | 42 | 50 | 8 |
| 384 | A67 | B93 | C5 | 42 | 50 | 8 |
| 385 | A73 | B93 | C5 | 42 | 50 | 8 |
| 386 | A78 | B93 | C5 | 42 | 50 | 8 |
| 387 | A81 | B93 | C5 | 42 | 50 | 8 |
| 388 | A83 | B93 | C5 | 42 | 50 | 8 |
| 389 | A85 | B93 | C5 | 42 | 50 | 8 |
| 390 | A89 | B93 | C5 | 42 | 50 | 8 |
| 391 | A91 | B93 | C5 | 42 | 50 | 8 |
| 392 | A92 | B93 | C5 | 42 | 50 | 8 |

TABLE 15

| High- | | | | | | |
|---|---|---|---|---|---|---|
| Molecular | Kind of Structural | | | Content Ratio of Structural | | |
| Compound | Unit | | | Unit (mol %) | | |
| No. | (A) | (B) | (C) | (A) | (B) | (C) |
| 393 | A1 | B93 | C6 | 45 | 50 | 5 |
| 394 | A5 | B93 | C6 | 45 | 50 | 5 |
| 395 | A6 | B93 | C6 | 45 | 50 | 5 |
| 396 | A7 | B93 | C6 | 45 | 50 | 5 |
| 397 | A8 | B93 | C6 | 45 | 50 | 5 |
| 398 | A9 | B93 | C6 | 45 | 50 | 5 |
| 399 | A10 | B93 | C6 | 45 | 50 | 5 |
| 400 | A24 | B93 | C6 | 45 | 50 | 5 |
| 401 | A25 | B93 | C6 | 45 | 50 | 5 |
| 402 | A29 | B93 | C6 | 45 | 50 | 5 |
| 403 | A33 | B93 | C6 | 45 | 50 | 5 |
| 404 | A38 | B93 | C6 | 45 | 50 | 5 |
| 405 | A41 | B93 | C6 | 45 | 50 | 5 |
| 406 | A42 | B93 | C6 | 45 | 50 | 5 |
| 407 | A43 | B93 | C6 | 45 | 50 | 5 |
| 408 | A44 | B93 | C6 | 45 | 50 | 5 |
| 409 | A45 | B93 | C6 | 45 | 50 | 5 |
| 410 | A49 | B93 | C6 | 45 | 50 | 5 |
| 411 | A65 | B93 | C6 | 45 | 50 | 5 |
| 412 | A67 | B93 | C6 | 45 | 50 | 5 |
| 413 | A73 | B93 | C6 | 45 | 50 | 5 |
| 414 | A78 | B93 | C6 | 45 | 50 | 5 |
| 415 | A81 | B93 | C6 | 45 | 50 | 5 |
| 416 | A83 | B93 | C6 | 45 | 50 | 5 |
| 417 | A85 | B93 | C6 | 45 | 50 | 5 |
| 418 | A89 | B93 | C6 | 45 | 50 | 5 |
| 419 | A91 | B93 | C6 | 45 | 50 | 5 |
| 420 | A92 | B93 | C6 | 45 | 50 | 5 |

### <Method for Production of High-Molecular Compound>

A method for producing the high-molecular compound of one aspect of the present invention is not specifically limited, and for example, the compound may be produced according to a production method through oxidative polymerization using FeCl₃, a production method through Yamamoto reaction using stoichiometrically an aromatic dihalogen compound and a 0-valent nickel catalyst, a production method through Suzuki reaction for polymerization of an aromatic dihalogen compound and a diboronic acid group-having compound using a 0-valent palladium catalyst, etc.

Among these, from the viewpoints of easiness in control of the bonding position of a high-molecular main chain skeleton and of easiness in control of the molecular weight of the high-molecular compound to be obtained, a production method through Suzuki reaction is preferred.

A method for producing the high-molecular compound of one aspect of the present invention through Suzuki reaction is described below.

(Production Method for High-Molecular Compound of One Aspect of the Invention through Suzuki Reaction)

Suzuki reaction is to polymerize an aromatic dihalogen compound and a diboronic acid group-having compound in the presence of a palladium catalyst, a base and a solvent.

Examples of the palladium catalyst include palladium[tetrakis(triphenylphosphine)], palladium acetates, etc.

The amount of the palladium catalyst to be added is not specifically limited, and may be an effective amount as a catalyst, but is generally 0.0001 mol to 0.5 mol relative to 1 mol of the raw material compound, preferably 0.0003 mol to 0.1 mol.

In the case where a palladium acetate is used as the palladium catalyst, for example, a phosphorus compound such as triphenyl phosphine, tri(o-tolyl) phosphine, tri(o-methoxyphenyl) phosphine or the like may be added thereto as a ligand.

In this case, the amount of the ligand to be added is generally 0.5 mol to 100 mol relative to 1 mol of the palladium catalyst, preferably 0.9 mol to 20 mol, more preferably 1 mol to 10 mol.

Examples of the base include inorganic bases, organic bases, inorganic salts, etc.

Examples of the inorganic bases include potassium carbonate, sodium carbonate, barium hydroxide, etc.

Examples of the organic bases include triethylamine, tributylamine, etc.

Examples of the inorganic salts include cesium fluoride, etc.

The amount of the base to be added is generally 0.5 mol to 100 mol relative to 1 mol of the raw material compound, preferably 0.9 mol to 30 mol, more preferably 1 mol to 20 mol.

The base may be added as an aqueous solution thereof to cause two-phase reaction. In the case of two-phase reaction, as needed, an interphase transfer catalyst such as a quaternary ammonium salt or the like may be added.

Suzuki reaction is carried out generally in the presence of a solvent.

The solvent to be used is not specifically limited, and examples thereof include aromatic hydrocarbon solvents such as toluene, xylene, chlorobenzene, etc.; halo genohydrocarbon solvents such as methylene chloride, dichloroethane, chloroform, etc.; ether solvents such as tetrahydrofuran, dioxane, etc.; amide solvents such as N,N-dimethylformamide, etc.; alcohol solvents such as methanol, etc.; ester solvents such as ethyl acetate, etc.; ketone solvents such as acetone, etc.

Suzuki reaction is carried out in an atmosphere of an inert gas such as argon gas, nitrogen gas or the like, so as not to deactivate the catalyst.

Specifically, it is preferable that the reaction system is fully purged with an inert gas for deaeration, then raw material compounds (aromatic dihalogen compound and a diboronic acid group-having compound) and a palladium catalyst are added thereto, then further the reaction system is fully purged with an inert gas for deaeration, and thereafter a solution prepared by dissolving a base, which is previously bubbled with an inert gas, in a solvent also previously bubbled with an inert gas, is dropwise added to the system to promote the reaction.

The reaction temperature may be appropriately set depending on the kind of the solvent to be used, but is generally 0 to 200° C., and is, from the viewpoint of increasing the molecular weight of the high-molecular compound to be obtained, preferably 40 to 120° C. The system may be heated up to around the boiling point of the solvent and may be refluxed with heating.

The reaction time may be appropriately set depending on the reaction condition such as the reaction temperature and the like, but in general, the time when the product has reached the intended polymerization degree is an end point, and specifically, the reaction time is preferably 1 hour or more, and more preferably 2 to 200 hours.

### [Material for Organic EL Device]

The organic EL device material of one aspect of the present invention contains the above-mentioned high-molecular compound of one aspect of the present invention.

The organic EL device material of one aspect of the present invention is useful as a material for organic EL devices, and is, for example, useful as a material for one or more organic thin-film layers arranged between an anode and a cathode of an organic EL device, and is, in particular, more useful as a material for a hole transporting layer or a material for a hole injecting layer.

### [Organic EL Device]

The organic EL device of one aspect of the present invention is described below.

As representative device structures of the organic EL device, (1) to (13) are shown below, although not limited thereto. The device structure (8) is preferably used.

(1) anode/light emitting layer/cathode;
(2) anode/hole injecting layer/light emitting layer/cathode;
(3) anode/light emitting layer/electron injecting layer/cathode;
(4) anode/hole injecting layer/light emitting layer/electron injecting layer/cathode;
(5) anode/organic semiconductor layer/light emitting layer/cathode;
(6) anode/organic semiconductor layer/electron blocking layer/light emitting layer/cathode;
(7) anode/organic semiconductor layer/light emitting layer/adhesion improving layer/cathode;
(8) anode/hole injecting layer/hole transporting layer/light emitting layer/(electron transporting layer/)electron injecting layer/cathode;
(9) anode/insulating layer/light emitting layer/insulating layer/cathode;
(10) anode/inorganic semiconductor layer/insulating layer/light emitting layer/insulating layer/cathode;
(11) anode/organic semiconductor layer/insulating layer/light emitting layer/insulating layer/cathode;
(12) anode/insulating layer/hole injecting layer/hole transporting layer/light emitting layer/insulating layer/cathode; and
(13) anode/insulating layer/hole injecting layer/hole transporting layer/light emitting layer/(electron transporting layer/)electron injecting layer/cathode.

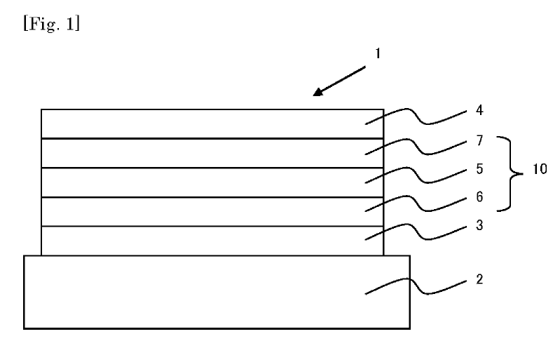

A schematic configuration of an example of the organic EL device of one aspect of the invention is shown in FIG. 1, wherein the organic EL device 1 includes a substrate 2, an anode 3, a cathode 4, and an emission unit 10 disposed between the anode 3 and the cathode 4. The emission unit 10 includes a light emitting layer 5 which contains a host material and a dopant (light emitting material). A hole injecting/transporting layer 6, etc. may be disposed between the light emitting layer 5 and the anode 3, and an electron injecting/transporting layer 7, etc. may be disposed between the light emitting layer 5 and the cathode 4. An electron blocking layer may be disposed on the anode 3 side of the light emitting layer 5, and a hole blocking layer may be disposed on the cathode 4 side of the light emitting layer 5. With these blocking layers, electrons and holes are confined in the light emitting layer 5 to increase the exciton generation in the light emitting layer 5.

The organic EL device of one aspect of the invention has an anode, a cathode, and one or more organic thin-film layers between the cathode and the anode, in which the one or more organic thin-film layers contain a light emitting layer, and in which at least one layer of the one or more organic thin-film layers is a layer containing the high-molecular compound of one aspect of the present invention.

The organic thin-film layer that contains the high-molecular compound of one aspect of the present invention includes, though not limited thereto, an anode-side organic thin-film layer (hole transporting layer, hole injecting layer, etc.) provided between an anode and a light emitting layer, a light emitting layer, a cathode-side organic thin-film layer (electron transporting layer, electron injecting layer, etc.) provided between a cathode and a light emitting layer, a space layer, a blocking layer, etc.

The high-molecular compound of one aspect of the present invention may be used in any organic thin-film layer of an organic EL device, but is, from the viewpoint of realizing an organic EL device having a prolonged lifetime, preferably used in a hole injecting layer or a hole transporting layer, and is more preferably used in a hole transporting layer.

Namely, the organic EL device of one aspect of the present invention is more preferably an organic EL device in which the above-mentioned one or more organic thin-film layers include at least one of a hole injecting layer and a hole transporting layer that contains the high-molecular compound of one aspect of the present invention.

The content of the high-molecular compound of one aspect of the present invention in the organic thin-film layer, preferably in the hole injecting layer or the hole transporting layer is preferably 30 to 100 mol % relative to the total molar amount of the components of the organic thin-film layer, more preferably 50 to 100 mol %, even more preferably 80 to 100 mol %, and still more preferably 95 to 100 mol %.

### (Substrate)

The substrate is a support for the emitting device and made of, for example, glass, quartz, and plastics. The substrate may be a flexible substrate, for example, a plastic substrate made of, for example, polycarbonate, polyarylate, polyether sulfone, polypropylene, polyester, polyvinyl fluoride, and polyvinyl chloride. An inorganic deposition film is also usable.

### (Anode)

The anode is formed on the substrate preferably from a metal, an alloy, an electrically conductive compound, and a mixture thereof, each having a large work function, for example, 4.0 eV or more. Examples of the material for the anode include indium oxide-tin oxide (ITO: indium tin oxide), indium oxide-tin oxide doped with silicon or silicon oxide, indium oxide-zinc oxide, indium oxide doped with tungsten oxide and zinc oxide, and graphene. In addition, gold (Au), platinum (Pt), nickel (Ni), tungsten (W), chromium (Cr), molybdenum (Mo), iron (Fe), cobalt (Co), copper (Cu), palladium (Pd), titanium (Ti), and a metal nitride (for example, titanium nitride) are also usable.

These materials are made into a film generally by a sputtering method. For example, a film of indium oxide-zinc oxide is formed by sputtering an indium oxide target doped with 1 to 10% by mass of zinc oxide, and a film of indium oxide doped with tungsten oxide and zinc oxide is formed by sputtering an indium oxide target doped with 0.5 to 5% by mass of tungsten oxide and 0.1 to 1% by mass of zinc oxide. In addition, a vacuum vapor deposition method, a coating method, an inkjet method, and a spin coating method are usable.

A hole injecting layer to be formed in contact with the anode is formed from a composite material which is capable of easily injecting holes independently of the work function of the anode. Therefore a material, for example, a metal, an alloy, an electroconductive compound, a mixture thereof, and a group 1 element and a group 2 element of the periodic table are usable as the electrode material.

A material having a small work function, for example, the group 1 element and the group 2 element of the periodic table, i.e., an alkali metal, such as lithium (Li) and cesium (Cs), an alkaline earth metal, such as magnesium (Mg), calcium (Ca), and strontium (Sr), and an alloy thereof, such as MgAg and AlLi, are also usable. In addition, a rare earth metal, such as europium (Eu) and ytterbium (Yb), and an alloy thereof are also usable. The alkali metal, the alkaline earth metal, and the alloy thereof can be made into the anode by a vacuum vapor deposition or a sputtering method. When a silver paste, etc. is used, a coating method and an inkjet method are usable.

### (Hole Injecting Layer)

The hole injecting layer contains a highly hole-injecting material.

The hole injecting layer of the organic EL device of one aspect of the invention preferably contains the high-molecular compound of one aspect of the present invention solely or in combination with the compound mentioned below.

Examples of the highly hole-injecting material include molybdenum oxide, titanium oxide, vanadium oxide, rhenium oxide, ruthenium oxide, chromium oxide, zirconium oxide, hafnium oxide, tantalum oxide, silver oxide, tungsten oxide, and manganese oxide.

The following low molecular aromatic amine compound is also usable: 4,4′,4″-tris(N,N-diphenylamino)triphenylamine (TDATA), 4,4′,4″-tris[N-(3-methylphenyl)-N-phenylamino]triphenylamine (MTDATA), 4,4′-bis[N-(4-diphenylaminophenyl)-N-phenylamino] biphenyl (DPAB), 4,4′-bis(N-{4-[N′-(3-methylphenyl)-N′-phenylamino]phenyl}-N-phenylamino)biphenyl (DNTPD), 1,3,5-tris[N-(4-diphenylaminophenyl)-N-phenylamino]benzene (DPA3B), 3-[N-(9-phenylcarbazol-3-yl)-N-phenylamino]-9-phenylcarbazole (PCzPCA1), 3,6-bis[N-(9-phenylcarbazole-3-yl)-N-phenylamino]-9-phenylcarbazole (PCzPCA2), and 3-[N-(1-naphthyl)-N-(9-phenylcarbazole-3-yl)amino]-9-phenylcarbazole (PCzPCN1).

A polymeric compound, such as an oligomer, a dendrimer, a polymer, is also usable. Examples thereof include poly(N-vinylcarbazole) (PVK), poly(4-vinyltriphenylamine) (PVTPA), poly[N-(4-{N′-[4-(4-diphenylamino)phenyl]phenyl-N′-phenylamino}phenyl)methacrylamide] (PTPDMA), and poly[N,N′-bis(4-butylphenyl)-N,N′-bis(phenyl)benzidine] (Poly-TPD). An acid-added polymeric compound, such as poly(3,4-ethylenedioxythiophene)/poly(styrenesulfonic acid) (PEDOT/PSS) and polyaniline/poly(styrenesulfonic acid) (PAni/PSS), is also usable.

### (Hole Transporting Layer)

The hole transporting layer contains a highly hole-transporting material.

The hole transporting layer of the organic EL device of one aspect of the invention preferably contains the high-molecular compound of one aspect of the present invention, solely or in combination with the compound mentioned below.

The hole transporting layer may contain an aromatic amine compound, a carbazole derivative, an anthracene derivative, etc. Examples the aromatic amine compound include 4,4′-bis[N-(1-naphthyl)-N-phenylamino]biphenyl (NPB), N,N′-bis(3-methylphenyl)-N,N′-diphenyl-[11′-biphenyl]-4,4′-diamine (TPD), 4-phenyl-4′-(9-phenylfluoren-9-yl)triphenylamine (BAFLP), 4,4′-bis[N-(9,9-dimethylfluoren-2-yl)-N-phenylamino]biphenyl (DFLDPBi), 4,4′,4″-tris(N,N-diphenylamino)triphenylamine (TDATA), 4,4′,4″-tris[N-(3-methylphenyl)-N-phenylamino]triphenylamine (MTDATA), and 4,4′-bis[N-(spiro-9,9′-bifluorene-2-yl)-N phenylamino]biphenyl (BSPB). The above compounds have a hole mobility of mainly 10⁻⁶ cm²/Vs or more.

In addition, the hole transporting layer may contain a carbazole derivative, such as CBP, CzPA, and PCzPA, an anthracene derivative, such as t-BuDNA, DNA, and DPAnth, and a polymeric compound, such as poly(N-vinylcarbazole) (PVK) and poly(4-vinyltriphenylamine) (PVTPA).

Other materials are also usable if their hole transporting ability is higher than their electron transporting ability.

The layer containing a highly hole-transporting material may be a single layer or a laminate of two or more layers each containing the material mentioned above. For example, the hole transporting layer may be made into a two-layered structure of a first hole transporting layer (anode side) and a second hole transporting layer (cathode side). In such a two-layered structure, the high-molecular compound of one aspect of the present invention may be used in either of the first hole transporting layer and the second hole transporting layer.

### (Guest Material for Light Emitting Layer)

The light emitting layer contains a highly light-emitting material and may be formed from various kinds of materials. For example, a fluorescent emitting compound and a phosphorescent emitting compound are usable as the highly light-emitting material. The fluorescent emitting compound is a compound capable of emitting light from a singlet excited state, and the phosphorescent emitting compound is a compound capable of emitting light from a triplet excited state.

Examples of blue fluorescent emitting material for use in the light emitting layer include a pyrene derivative, a styrylamine derivative, a chrysene derivative, a fluoranthene derivative, a fluorene derivative, a diamine derivative, and a triarylamine derivative, such as N,N′-bis[4-(9H-carbazole-9-yl)phenyl]-N,N′-diphenylstilbene-4,4′-diamine (YGA2S), 4-(9H-carbazole-9-yl)-4′-(10-phenyl-9-anthryl)triphenylamine (YGAPA), and 4-(10-phenyl-9-anthryl)-4′-(9-phenyl-9H-carbazole-3-yl)triphenylamine (PCBAPA).

Examples of green fluorescent emitting material for use in the light emitting layer include an aromatic amine derivative, such as N-(9,10-diphenyl-2-anthryl)-N,9-diphenyl-9H-carbazole-3-amine (2PCAPA), N-[9,10-bis(1,1′-biphenyl-2-yl)-2-anthryl]-N,9-diphenyl-9H-carbazole-3-amine (2PCABPhA), N-(9,10-diphenyl-2-anthryl)-N,N′,N′-triphenyl-1,4-phenylene (2DPAPA), N-[9,10-bis(1,1′-biphenyl-2-yl)-2-anthryl]-N,N′,N′-triphenyl-1,4-phenylenediamine (2DPABPhA), N-[9,10-bis(1,1′-biphenyl-2-yl)]-N-[4-(9H-carbazole-9-yl)phenyl]-N-phenylanthracene-2-amine (2YGABPhA), and N,N,9-triphenylanthracene-9-amine (DPhAPhA).

Examples of red fluorescent emitting material for use in the light emitting layer include a tetracene derivative and a diamine derivative, such as N,N,N′,N′-tetrakis(4-methylphenyl)tetracene-5,11-diamine (p-mPhTD) and 7,14-diphenyl-N,N,N′,N′-tetrakis(4-methylphenyl)acenaphtho[1,2-a]fluoranthene-3,10-diamine (p-mPhAFD).

Examples of blue phosphorescent emitting material for use in the light emitting layer include a metal complex, such as an iridium complex, an osmium complex, and a platinum complex. Examples thereof include bis[2-(4′,6′-difluorophenyl)pyridinato-N,C2′]iridium(III) tetrakis(1-pyrazolyl)borato (FIr₆), bis[2-(4′,6′-difluorophenyl)pyridinato-N,C2′]iridium(III) picolinato (FIrpic), bis[2-(3′,5′-bistrifluoromethylphenyl)pyridinato-N,C2′]iridium(III) picolinato (Ir(CF₃ppy)₂(pic)), and bis[2-(4′,6′-difluorophenyl)pyridinato-N,C2′]iridium(III) acetylacetonato (FIracac).

Examples of green phosphorescent emitting material for use in the light emitting layer include an iridium complex, such as tris(2-phenylpyridinato-N,C2′(Ir(ppy)₃), bis(2-phenylpyridinato-N,C2′)iridium(III) acetylacetonato (Ir(ppy)₂(acac)), bis(1,2-diphenyl-1H-benzimidazolato)iridium(III) acetylacetonato (Ir(pbi)₂(acac)), and bis(benzo[h]quinolinato)iridium(III) acetylacetonato (Ir(bzq)₂(acac)).

Examples of red phosphorescent emitting material for use in the light emitting layer include a metal complex, such as an iridium complex, a platinum complex, a terbium complex, and a europium complex. Examples thereof include an organometallic complex, such as bis[2-(2′-benzo[4,5-α]thienyl)pyridinato-N,C3′]iridium(III) acetylacetonato (Ir(btp)₂(acac)), bis(1-phenylisoquinolinato-N,C2′)iridium(III) acetylacetonato (Ir(piq)₂(acac)), (acetylacetonato)bis[2,3-bis(4-fluorophenyl)quinoxalinato]iridium(III) (Ir(Fdpq)₂(acac)), and 2,3,7,8,12,13,17,18-octaethyl-21H,23H-porphyrin platinum(II) (PtOEP).

The following rare earth metal complex, such as tris(acetylacetonato)(monophenanthroline)terbium (III) (Tb(acac)₃(Phen)), tris(1,3-diphenyl-1,3-propanedionato)(monophenanthroline)europium(III) (Eu(DBM)₃(Phen)), and tris[1-(2-thenoyl)-3,3,3-trifluoroacetonato](monophenanthroline)europium(III) (Eu(TTA)₃(Phen)), emits light from the rare earth metal ion (electron transition between different multiple states), and therefore, usable as a phosphorescent emitting compound.

### (Host Material for Light Emitting Layer)

The light emitting layer may be formed by dispersing the highly light-emitting material (guest material) mentioned above in another material (host material). The material in which the highly light-emitting material is to be dispersed may be selected from various kinds of materials and is preferably a material having a lowest unoccupied molecular orbital level (LUMO level) higher than that of the highly light-emitting material and a highest occupied molecular orbital level (HOMO level) lower than that of the highly light-emitting material.

The material in which the highly light-emitting material is to be dispersed (host material) may include, for example,

(1) a metal complex, such as an aluminum complex, a beryllium complex, and a zinc complex;
(2) a heterocyclic compound, such as an oxadiazole derivative, a benzimidazole derivative, and a phenanthroline derivative;
(3) a fused aromatic compound, such as a carbazole derivative, an anthracene derivative, a phenanthrene derivative, a pyrene derivative, and a chrysene derivative; and
(4) an aromatic amine compound, such as a triarylamine derivative and a fused aromatic polycyclic amine derivative.

Examples thereof include a metal complex, such as tris(8-quinolinolato)aluminum(III) (Alq), tris(4-methyl-8-quinolinolato)aluminum (III) (Almq₃), bis(10-hydroxybenzo[h]quinolinato)beryllium(II) (BeBq2), bis(2-methyl-8-quinolinolato)(4-phenylphenolato)aluminum(III) (BAlq), bis(8-quinolinolato)zinc(II) (Znq), bis[2-(2-benzoxazolyl)phenolato]zinc(II) (ZnPBO), and bis[2-(2-benzothiazolyl)phenolato]zinc(II) (ZnBTZ); a heterocyclic compound, such as 2-(4-biphenylyl)-5-(4-tert-butylphenyl)-1,3,4-oxadiazole (PBD), 1,3-bis[5-(p-tert-butylphenyl)-1,3,4-oxadiazole-2-yl]benzene (OXD-7), 3-(4-biphenylyl)-4-phenyl-5-(4-tert-butylphenyl)-1,2,4-triazole (TAZ), 2,2′,2″-(1,3,5-benzenetriyl)tris(1-phenyl-1H-benzimidazole) (TPBI), bathophenanthroline (BPhen), and bathocuproin (BCP); a fused aromatic compound, such as 9-[4-(10-phenyl-9-anthryl)phenyl]-9H-carbazole (CzPA), 3,6-diphenyl-9-[4-(10-phenyl-9-anthryl)phenyl]-9H-carbazole (DPCzPA), 9,10-bis(3,5-diphenylphenyl)anthracene (DPPA), 9,10-di(2-naphthyl)anthracene (DNA), 2-tert-butyl-9,10-di(2-naphthyl)anthracene (t-BuDNA), 9,9′-bianthryl (RANT), 9,9′-(stilbene-3,3′-diyl)diphenanthrene (DPNS), 9,9′-(stilbene-4,4′-diyl)diphenanthrene (DPNS2), 3,3′,3″-(benzene-1,3,5-triyl)tripyrene (TPB3), 9,10-diphenylanthracene (DPAnth), and 6,12-dimethoxy-5,11-diphenylchrysene; and an aromatic amine compound, such as N,N-diphenyl-9-[4-(10-phenyl-9-anthryl)phenyl]-9H-carbazole-3-amine (CzA1PA), 4-(10-phenyl-9-anthryl)triphenylamine (DPhPA), N,9-diphenyl-N-[4-(10-phenyl-9-anthryl)phenyl]-9H-carbazole-3-amine (PCAPA), N,9-diphenyl-N-{4-[4-(10-phenyl-9-anthryl)phenyl]phenyl}-9H-carbazole-3-amine (PCAPBA), N-(9,10-diphenyl-2-anthryl)-N,9-diphenyl-9H-carbazole-3-amine (2PCAPA), NPB (or α-NPD), TPD, DFLDPBi, and BSPB. The material (host material) for dispersing the highly light-emitting material (guest material) may be used alone or in combination of two or more.

### (Electron Transporting Layer)

The electron transporting layer contains a highly electron-transporting material, for example,

(1) a metal complex, such as an aluminum complex, a beryllium complex, and a zinc complex;
(2) a heteroaromatic compound, such as an imidazole derivative, a benzimidazole derivative, an azine derivative, a carbazole derivative, and a phenanthroline derivative; and
(3) a polymeric compound.

Examples of the low molecular organic compound include a metal complex, such as Alq, tris(4-methyl-8-quinolinolato)aluminum (Almq₃), bis(10-hydroxybenzo[h]quinolinato)beryllium (BeBq2), BAlq, Znq, ZnPBO, and ZnBTZ; and a heteroaromatic compound, such as 2-(4-biphenylyl)-5-(4-tert-butylphenyl)-1,3,4-oxadiazole (PBD), 1,3-bis[5-(p-tert-butylphenyl)-1,3,4-oxadiazole-2-yl]benzene (OXD-7), 3-(4-tert-butylphenyl)-4-phenyl-5-(4-biphenylyl)-1,2,4-triazole (TAZ), 3-(4-tert-butylphenyl)-4-(4-ethylphenyl)-5-(4-biphenylyl)-1,2,4-triazole (p-EtTAZ), bathophenanthroline (BPhen), b athocuproine (BCP), and 4,4′-bis(5-methylbenzoxazol-2-yl)stilbene (BzOs). The above compounds have an electron mobility of mainly 10⁻⁶ cm²/Vs or more. Other materials are also usable in the electron transporting layer if their electron transporting ability is higher than their hole transporting ability. The electron transporting layer may be a single layer or a laminate of two or more layers each containing the material mentioned above.

A polymeric compound is also usable in the electron transporting layer. Examples thereof include poly[(9,9-dihexylfluorene-2,7-diyl)-co-(pyridine-3,5-diyl)] (PF-Py), and poly[(9,9-dioctylfluorene-2,7-diyl)-co-(2,2′-bipyridine-6,6′-diyl)] (PF-BPy).

### (Electron Injecting Layer)

The electron injecting layer contains a highly electron-injecting material, for example, an alkali metal, an alkaline earth metal, and a compound of these metals, such as lithium (Li), cesium (Cs), calcium (Ca), lithium fluoride (LiF), cesium fluoride (CsF), calcium fluoride (CaF2), and lithium oxide (LiOx). In addition, an electron transporting material which is incorporated with an alkali metal, an alkaline earth metal or a compound thereof, for example, Alq doped with magnesium (Mg), is also usable. By using such a material, electrons are efficiently injected from the cathode.

A composite material obtained by mixing an organic compound and an electron donor is also usable in the electron injecting layer. Such a composite material is excellent in the electron injecting ability and the electron transporting ability, because the electron donor donates electrons to the organic compound. The organic compound is preferably a material excellent in transporting the received electrons. Examples thereof are the materials for the electron transporting layer mentioned above, such as the metal complex and the aromatic heterocyclic compound. Any material capable of giving its electron to another organic compound is usable as the electron donor. Preferred examples thereof are an alkali metal, an alkaline earth metal, and a rare earth metal, such as lithium, cesium, magnesium, calcium, erbium, and ytterbium; an alkali metal oxide and an alkaline earth metal oxide, such as, lithium oxide, calcium oxide, and barium oxide; a Lewis base, such as magnesium oxide; and an organic compound, such as tetrathiafulvalene (TTF).

### (Cathode)

The cathode is formed preferably from a metal, an alloy, an electrically conductive compound, and a mixture thereof, each having a small work function, for example, a work function of 3.8 eV or less. Examples of the material for the cathode include an element of the group 1 or 2 of the periodic table, for example, an alkali metal, such as lithium (Li) and cesium (Cs), an alkaline earth metal, such as magnesium (Mg), calcium (Ca), and strontium (Sr) an alloy containing these metals (for example, MgAg and AlLi), a rare earth metal, such as europium (Eu) and ytterbium (Yb), and an alloy containing a rare earth metal.

The alkali metal, the alkaline earth metal, and the alloy thereof can be made into the cathode by a vacuum vapor deposition or a sputtering method. When a silver paste, etc. is used, a coating method and an inkjet method are usable.

When the electron injecting layer is formed, the material for the cathode can be selected independently from the work function and various electroconductive materials, such as Al, Ag, ITO, graphene, and indium oxide-tin oxide doped with silicon or silicon oxide, are usable. These electroconductive materials are made into films by a sputtering method, an inkjet method, and a spin coating method.

Each layer of the organic EL device is formed by a dry film-forming method, such as vacuum vapor deposition, sputtering, plasma, and ion plating, and a wet film-forming method, such as spin coating, clip coating, and flow coating.

However, as the method for forming an organic thin-film layer containing the high-molecular compound of one aspect of the present invention, a method of film formation using a solution of the high-molecular compound dissolved in a solvent is preferred.

The film formation method using the solution includes a spin coating method, a casting method, a microgravure coating method, a gravure coating method, a bar coating method, a roll coating method, a wire bar coating method, a dip coating method, a spray coating method, a nozzle coating method, a capillary coating method, a screen printing method, a flexographic printing method, an offset printing method, an inkjet printing method, etc. For patterning, a screen printing method, a flexographic printing method, an offset printing method or an inkjet printing method is preferred.

The solvent for use in preparing the solution is not specifically limited so far as it dissolves the high-molecular compound of one aspect of the present invention, and examples thereof include chlorine-containing solvents such as chloroform, methylene chloride, dichloroethane, etc.; ether solvents such as tetrahydrofuran, etc.; aromatic hydrocarbon solvents such as toluene, xylene, etc.; ketone solvents such as acetone, methyl ethyl ketone, etc.; ester solvents such as ethyl acetate, butyl acetate, ethyl cellosolve acetate, etc.

The solution may contain a hole transporting material, an electron transporting material, a light emitting material and the like that contain any other component than the high-molecular compound of one aspect of the present invention, and may further contain any ordinary additive such as a stabilizer, etc.

The thickness of each layer is not particularly limited and selected so as to obtain a good device performance. If extremely thick, a large applied voltage is needed to obtain a desired emission output, thereby reducing the efficiency. If extremely thin, pinholes occur on the film to make it difficult to obtain a sufficient luminance even when applying an electric field.

The thickness of each layer is generally 1 nm to 1,000 nm, preferably 2 nm to 500 nm, and more preferably 5 nm to 200 μm.

### [Electronic Device]

The electronic device of one aspect of the present invention contains the organic EL device of one aspect of the invention mentioned above.

Examples of the electronic device include display parts, such as organic EL panel modules, etc.; display devices of television sets, mobile phones, personal computers, etc.; light emitting sources of lighting equipment and vehicle lighting equipment, etc. In particular, large-size TV panels and flexible sheet displays are preferred.

### EXAMPLES

Next, the present invention will be described in more detail with respect to the examples and comparative examples. However, it should be noted that the scope of the invention is not limited to the following examples.

The high-molecular compounds recited in the claims of this application can be synthesized by using a known alternative reaction and a starting compound depending upon the target compound while referring to the following synthesis reactions.

The weight average molecular weight (Mw) and the number average molecular weight (Mn) of high-molecular compounds were measured as standard polystyrene-equivalent values through gel permeation chromatography (GPC). Detailed conditions are as follows.

### (GPC Condition)

Apparatus: gel permeation chromatograph GPC 101 (manufactured by Shodex)
Detector: differential refractometer and UV-visible absorption detector
Column: GPC K-806LX3 (8.0 mm I.D.×30 cm) (manufactured by Shodex)
Column temperature: 40° C.
Developing solvent: chloroform
Injection amount: 100 μL
Flow rate: 1 ml/min
Standard substance: monodispersed polystyrene (manufactured by Shodex)
Implanted concentration: 0.1% by mass

### Intermediate Synthesis Example 1-1 (Synthesis of Intermediate (1-1))

In an argon atmosphere, 32.7 g (100.0 mmol) of bis(4-bromophenyl)amine, 44.5 g (210.0 mmol) of dibenzofuran-4-boronic acid and 2.31 g (2.00 mmol) of Pd(PPh₃)₄ each were weighed, and 200 ml of toluene, 200 ml of dimethoxyethane and 150 ml (300.0 ml) of an aqueous solution of 2 M Na₂CO₃ were added thereto, and heated with stirring under reflux for 10 hours.

After the reaction, the mixture was cooled down to room temperature, and the reaction product was transferred into a separatory funnel, and extracted with dichloromethane. The extracted organic layer was dried over MgSO₄, then filtered and concentrated. The resultant residue was purified through silica gel column chromatography to give 37.6 g of a white solid.

Through FD-MS analysis (field desorption mass spectrometry), the white crystal was identified as the following Intermediate (1-1).

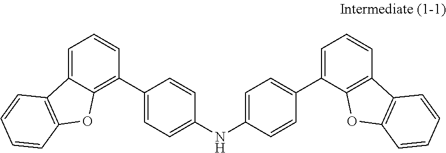 [SMILES: c1ccc2c(c1)oc1c(-c3ccc(Nc4ccc(-c5cccc6c5oc5ccccc56)cc4)cc3)cccc12]

### Intermediate Synthesis Example 1-2 (Synthesis of Intermediate (1-2))

39.1 g of a white crystal was obtained in the same manner as in Intermediate Synthesis Example 1-1, except that 44.5 g (210.0 mmol) of “dibenzofuran-2-boronic acid” was used in place of “dibenzofuran-4-boronic acid” in Intermediate Synthesis Example 1-1.

Through FD-MS analysis, the white crystal was identified as the following Intermediate (1-2).

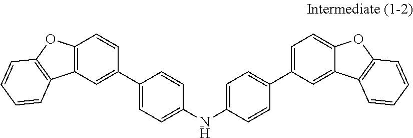 [SMILES: c1ccc2c(c1)oc1ccc(-c3ccc(Nc4ccc(-c5ccc6oc7ccccc7c6c5)cc4)cc3)cc12]

### Intermediate Synthesis Example 1-3 (Synthesis of Intermediate (1-3))

37.4 g of a white crystal was obtained in the same manner as in Intermediate Synthesis Example 1-1, except that 47.9 g (210.0 mmol) of “dibenzothiophene-4-boronic acid” was used in place of “dibenzofuran-4-boronic acid” in Intermediate Synthesis Example 1-1.

Through FD-MS analysis, the white crystal was identified as the following Intermediate (1-3).

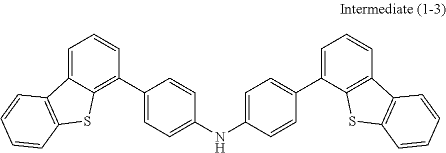 [SMILES: c1ccc2c(c1)sc1c(-c3ccc(Nc4ccc(-c5cccc6c5sc5ccccc56)cc4)cc3)cccc12]

### Intermediate Synthesis Example 1-4 (Synthesis of Intermediate (1-4))

39.5 g of a white crystal was obtained in the same manner as in Intermediate Synthesis Example 1-1, except that 47.9 g (210.0 mmol) of “dibenzothiophene-2-boronic acid” was used in place of “dibenzofuran-4-boronic acid” in Intermediate Synthesis Example 1-1.

Through FD-MS analysis, the white crystal was identified as the following Intermediate (1-4).

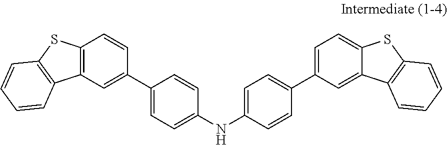 [SMILES: c1ccc2c(c1)sc1ccc(-c3ccc(Nc4ccc(-c5ccc6sc7ccccc7c6c5)cc4)cc3)cc12]

### Intermediate Synthesis Example 2-1 (Synthesis of Intermediate (2-1))

In an argon atmosphere, 95.5 g (201.6 mmol) of 2,7-dibromo-9,9′-spirobifluorene, 23.0 g (90.6 mmol) of iodine, and 9.4 g (41.2 mmol) of periodic acid dihydrate each were weighed, and 42 ml of water, 360 ml of acetic acid and 11 ml of sulfuric acid were added thereto and stirred at 65° C. for 30 minutes, and further stirred at 90° C. for 6 hours.

After the reaction, the reaction product was poured into water with ice and cooled, then filtered, and the residue was washed with water and methanol to give 64.0 g of a white powder.

Through FD-MS analysis, the white crystal was identified as the following Intermediate (2-1).

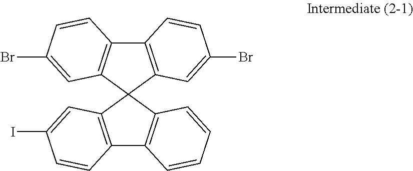 [SMILES: Brc1ccc2c(c1)C1(c3ccccc3-c3ccc(I)cc31)c1cc(Br)ccc1-2]

### Intermediate Synthesis Example 2-2 (Synthesis of Intermediate (2-2))

In an argon atmosphere, 14.3 g (28.5 mmol) of Intermediate (1-1), 8.32 g (28.5 mmol) of 2-iodofluorene, 4.0 g (39.9 mmol) of t-butoxy sodium, 135 mg (0.6 mmol) of palladium acetate, and 571 mg (1.2 mmol) of an Xphos ligand each were weighed, and 100 ml of dewatered toluene was added thereto, and reacted at 80° C. with stirring for 6 hours.

After cooled, 200 ml of toluene and 100 ml of water were added to the reaction product, the toluene liquid was washed, filtered through Celite, and the filtrate was concentrated under reduced pressure. The residue obtained through concentration was crystallized in a mixed solvent of toluene/heptane to give 13.0 g of a pale yellow solid (yield 68.6%).

Through FD-MS analysis, the pale yellow solid was identified as the following Intermediate (2-2).

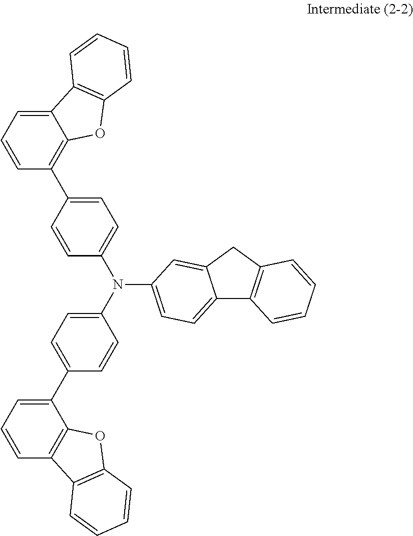 [SMILES: c1ccc2c(c1)Cc1cc(N(c3ccc(-c4cccc5c4oc4ccccc45)cc3)c3ccc(-c4cccc5c4oc4ccccc45)cc3)ccc1-2]

### Intermediate Synthesis Example 2-3 (Synthesis of Intermediate (2-3))

12.0 g of a pale yellow solid was obtained in the same manner as in Intermediate Synthesis Example 2-2, except that 14.3 g (28.5 mmol) of “Intermediate (1-2)” was used in place of “Intermediate (1-1)” in Intermediate Synthesis Example 2-2.

Through FD-MS analysis, the pale yellow solid was identified as the following Intermediate (2-3).

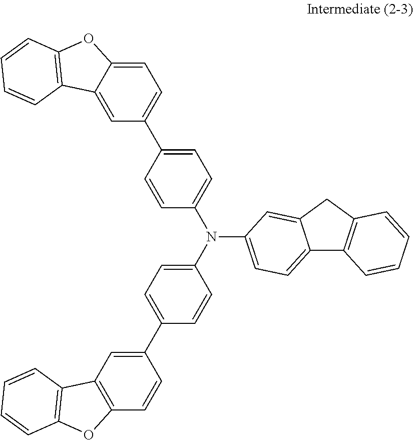 [SMILES: c1ccc2c(c1)Cc1cc(N(c3ccc(-c4ccc5oc6ccccc6c5c4)cc3)c3ccc(-c4ccc5oc6ccccc6c5c4)cc3)ccc1-2]

### Intermediate Synthesis Example 2-4 (Synthesis of Intermediate (2-4))

10.0 g of a pale yellow solid was obtained in the same manner as in Intermediate Synthesis Example 2-2, except that 15.2 g (28.5 mmol) of “Intermediate (1-3)” was used in place of “Intermediate (1-1)” in Intermediate Synthesis Example 2-2.

Through FD-MS analysis, the pale yellow solid was identified as the following Intermediate (2-4).

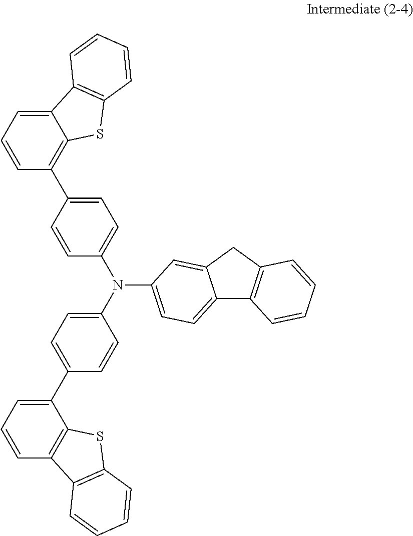 [SMILES: c1ccc2c(c1)Cc1cc(N(c3ccc(-c4cccc5c4sc4ccccc45)cc3)c3ccc(-c4cccc5c4sc4ccccc45)cc3)ccc1-2]

### Intermediate Synthesis Example 2-5 (Synthesis of Intermediate (2-5))

9.3 g of a pale yellow solid was obtained in the same manner as in Intermediate Synthesis Example 2-2, except that 15.2 g (28.5 mmol) of “Intermediate (1-4)” was used in place of “Intermediate (1-1)” in Intermediate Synthesis Example 2-2.

Through FD-MS analysis, the pale yellow solid was identified as the following Intermediate (2-5).

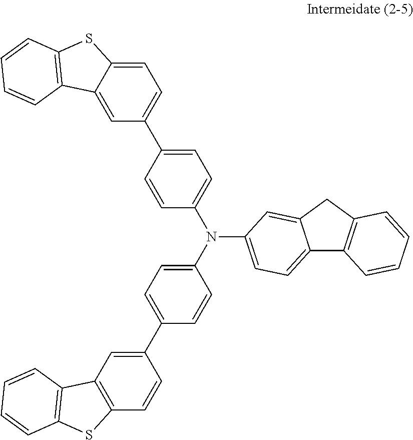 [SMILES: c1ccc2c(c1)Cc1cc(N(c3ccc(-c4ccc5sc6ccccc6c5c4)cc3)c3ccc(-c4ccc5sc6ccccc6c5c4)cc3)ccc1-2]

### Intermediate Synthesis Example 3-1 (Synthesis of Intermediate (3-1))

In an argon atmosphere, 13.0 g (19.5 mmol) of Intermediate (2-2) and 3.3 g (48.5 mmol) of sodium ethoxide each were weighed, and 100 ml of 1,3-dimethyl-2-imidazolidinone was added thereto and stirred, then 12.2 g (49 mmol) of 4-bromobenzyl bromide was dropwise added thereto at 20° C., and after the dropwise addition, this was reacted at 20° C. for 1 hour.

After the reaction, 500 ml of toluene and 200 ml of water were added to the reaction product, then this was filtered through Celite, and the filtrate was concentrated under reduced pressure. The residue obtained after concentration was purified through silica gel chromatography, and crystallized in a mixed solvent of toluene/heptane to give 7.9 g of a pale yellow solid (yield 40%).

Through FD-MS analysis, the pale yellow solid was identified as the following Intermediate (3-1).

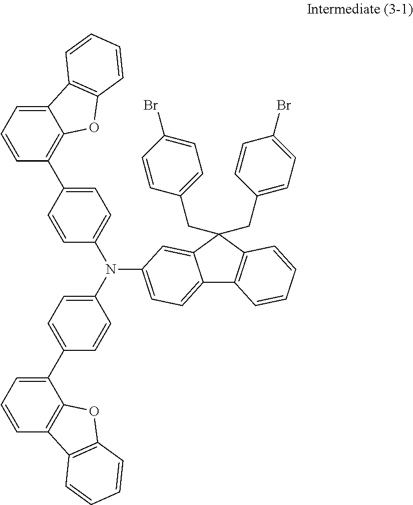 [SMILES: Brc1ccc(CC2(Cc3ccc(Br)cc3)c3ccccc3-c3ccc(N(c4ccc(-c5cccc6c5oc5ccccc56)cc4)c4ccc(-c5cccc6c5oc5ccccc56)cc4)cc32)cc1]

### Intermediate Synthesis Example 3-2 (Synthesis of Intermediate (3-2))

7.5 g of a pale yellow solid was obtained in the same manner as in Intermediate Synthesis Example 3-1, except that 13.0 g (19.5 mmol) of “Intermediate (2-3)” was used in place of “Intermediate (2-2)” in Intermediate Synthesis Example 3-1.

Through FD-MS analysis, the pale yellow solid was identified as the following Intermediate (3-2).

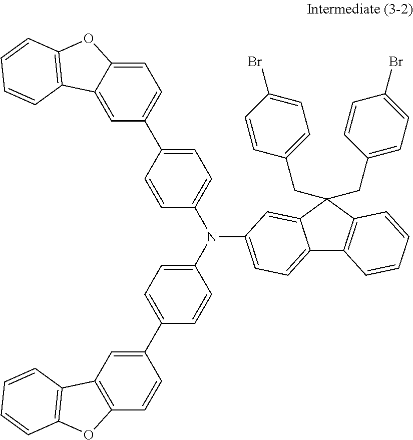 [SMILES: Brc1ccc(CC2(Cc3ccc(Br)cc3)c3ccccc3-c3ccc(N(c4ccc(-c5ccc6oc7ccccc7c6c5)cc4)c4ccc(-c5ccc6oc7ccccc7c6c5)cc4)cc32)cc1]

### Intermediate Synthesis Example 3-3 (Synthesis of Intermediate (3-3))

7.2 g of a pale yellow solid was obtained in the same manner as in Intermediate Synthesis Example 3-1, except that 13.6 g (19.5 mmol) of “Intermediate (2-4)” was used in place of “Intermediate (2-2)” in Intermediate Synthesis Example 3-1.

Through FD-MS analysis, the pale yellow solid was identified as the following Intermediate (3-3).

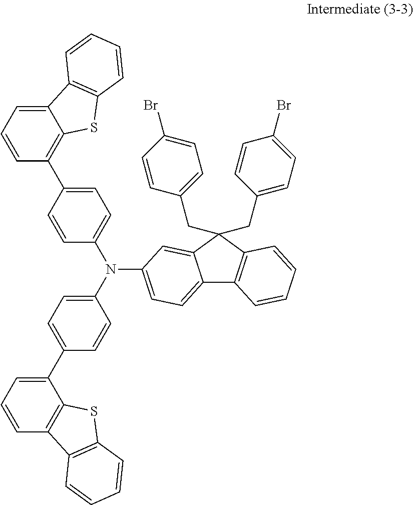 [SMILES: Brc1ccc(CC2(Cc3ccc(Br)cc3)c3ccccc3-c3ccc(N(c4ccc(-c5cccc6c5sc5ccccc56)cc4)c4ccc(-c5cccc6c5sc5ccccc56)cc4)cc32)cc1]

### Intermediate Synthesis Example 3-4 (Synthesis of Intermediate (3-4))

6.9 g of a pale yellow solid was obtained in the same manner as in Intermediate Synthesis Example 3-1, except that 13.6 g (19.5 mmol) of “Intermediate (2-5)” was used in place of “Intermediate (2-2)” in Intermediate Synthesis Example 3-1.

Through FD-MS analysis, the pale yellow solid was identified as the following Intermediate (3-4).

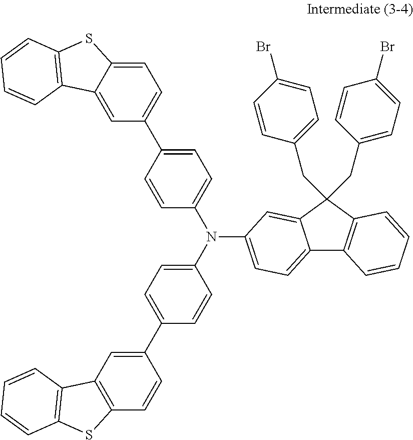 [SMILES: Brc1ccc(CC2(Cc3ccc(Br)cc3)c3ccccc3-c3ccc(N(c4ccc(-c5ccc6sc7ccccc7c6c5)cc4)c4ccc(-c5ccc6sc7ccccc7c6c5)cc4)cc32)cc1]

### Intermediate Synthesis Example 3-5 (Synthesis of Intermediate (3-5))

19.4 g of a pale yellow solid was obtained in the same manner as in Intermediate Synthesis Example 2-2, except that 14.3 g (28.5 mmol) of “Intermediate (1-2)” was used in place of “Intermediate (1-1)” and that 17.1 g (28.5 mmol) of “Intermediate (2-1)” was used in place of “2-iodofluorene” in Intermediate Synthesis Example 2-2.

Through FD-MS analysis, the pale yellow solid was identified as the following Intermediate (3-5).

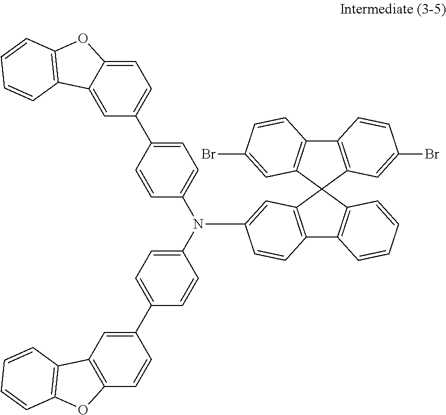 [SMILES: Brc1ccc2c(c1)C1(c3ccccc3-c3ccc(N(c4ccc(-c5ccc6oc7ccccc7c6c5)cc4)c4ccc(-c5ccc6oc7ccccc7c6c5)cc4)cc31)c1cc(Br)ccc1-2]

### Synthesis Example 1 (Synthesis of High-Molecular Compound (HD)

In a nitrogen atmosphere, 1.43 g (1.42 mmol) of Intermediate (3-1), 0.679 g (1.42 mmol) of 9,9-dioctylfluorene-2,7-diboronic acid represented by the following formula (x1), 0.37 g of tetrabutylammonium chloride, 10 ml of toluene, 10 ml of dimethoxyethane, 1.18 g of potassium carbonate and 10 ml of water each were weighed, put into a reactor, and stirred for 30 minutes. After the stirring, 6.3 mg of palladium acetate and 23.4 mg of an Sphos ligand were added, and stirred with heating under reflux for 30 hours.

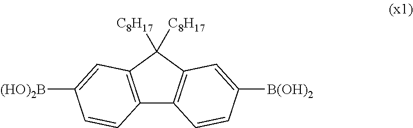

Subsequently, the reaction liquid was cooled down to room temperature, 0.166 g (1.36 mmol) of phenylboronic acid was added thereto, and reacted with heating under reflux for 2 hours.

After the reaction, the reaction liquid was cooled down to room temperature, and washed three times with 20 ml of water. After the washing, an aqueous solution of sodium diethyldithiocarbamate trihydrate was added to the organic layer, and stirred at 80° C. for 4 hours. Then, this was cooled down to room temperature, washed twice with 20 ml of an aqueous solution of 3 mass % acetic acid. After the washing, the solvent was evaporated away from the organic layer under reduced pressure to give 1.88 g of a solid.

The solid was dissolved in toluene to be a toluene solution, and then the catalyst was removed through a laminate column of silica gel 120 ml/alumina 20 ml, and the toluene solution was concentrated under reduced pressure and then washed with a mixed solution of methanol and acetone to give 1.14 g of High-molecular compound (H1).

The weight average molecular weight (Mw) of High-molecular compound (H1) was 5.18×10⁴, the number average molecular weight (Mn) thereof was 2.11×10⁴, and the molecular weight distribution (Mw/Mn) was 2.45.

The configuration and the content ratio (by mol) of the structural units contained in High-molecular compound (H1), as estimated from the quantities of the charged components, are as follows.

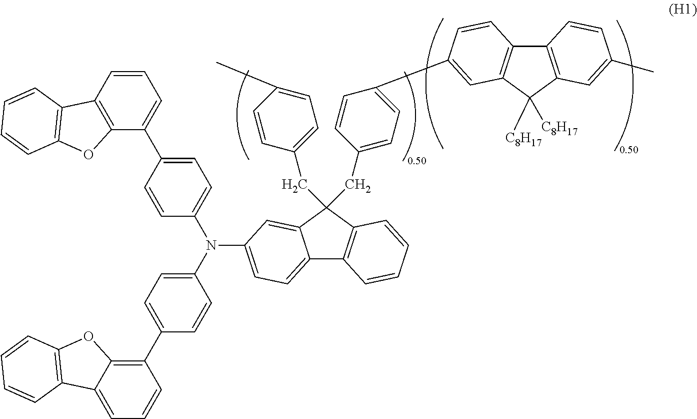

### Synthesis Example 2 (Synthesis of High-Molecular Compound (H2))

1.03 g of High-molecular compound (H2) was obtained in the same manner as in Synthesis Example 1, except that 1.43 g (1.42 mmol) of “Intermediate (3-2)” was used in place of “Intermediate (3-1)” in Synthesis Example 1.

The weight average molecular weight (Mw) of High-molecular compound (H2) was 4.65×10⁴, the number average molecular weight (Mn) thereof was 2.00×10⁴, and the molecular weight distribution (Mw/Mn) was 2.33.

The configuration and the content ratio (by mol) of the structural units contained in High-molecular compound (H2), as estimated from the quantities of the charged components, are as follows.

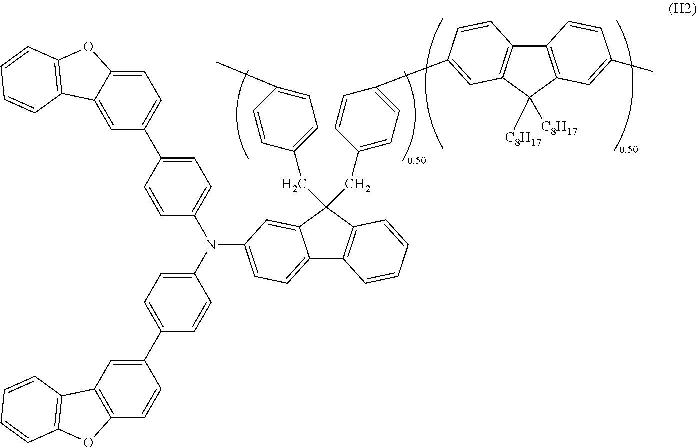

### Synthesis Example 3 (Synthesis of High-Molecular Compound (H3))

0.90 g of High-molecular compound (H3) was obtained in the same manner as in Synthesis Example 1, except that 1.47 g (1.42 mmol) of “Intermediate (3-3)” was used in place of “Intermediate (3-1)” and that 0.536 g (1.42 mmol) of “2,2′-(2,5-dihexyl-1,4-phenylene)-bis(1,3,2-dioxabororane)” represented by the following formula (x2) was used in place of “9,9-dioctylfluorene-2,7-diboronic acid” in Synthesis Example 1.

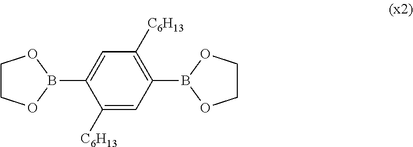

The weight average molecular weight (Mw) of High-molecular compound (H3) was 4.44×10⁴, the number average molecular weight (Mn) thereof was 1.99×10⁴, and the molecular weight distribution (Mw/Mn) was 2.23.

The configuration and the content ratio (by mol) of the structural units contained in High-molecular compound (H3), as estimated from the quantities of the charged components, are as follows.

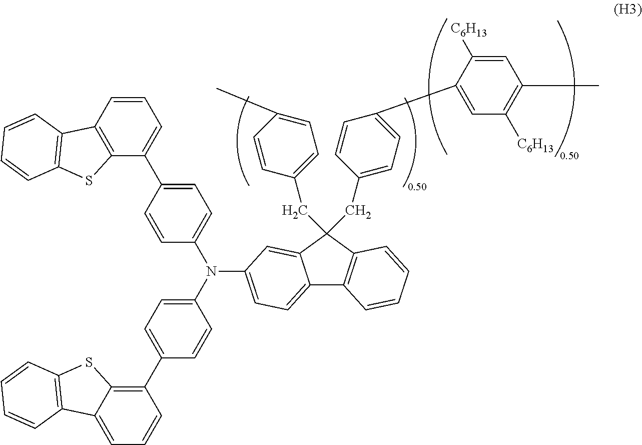

### Synthesis Example 4 (Synthesis of High-Molecular Compound (H4))

1.03 g of High-molecular compound (H4) was obtained in the same manner as in Synthesis Example 1, except that 1.47 g (1.42 mmol) of “Intermediate (3-4)” was used in place of “Intermediate (3-1)” and that 1.03 g (1.42 mmol) of a diboronate derivative represented by the following formula (x3) was used in place of “9,9-dioctylfluorene-2,7-diboronic acid” in Synthesis Example 1.

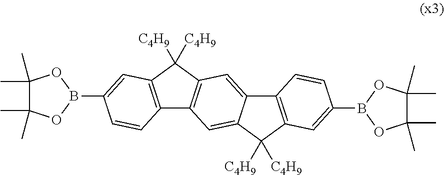

The weight average molecular weight (Mw) of High-molecular compound (H4) was 5.65×10⁴, the number average molecular weight (Mn) thereof was 2.42×10⁴, and the molecular weight distribution (Mw/Mn) was 2.33.

The configuration and the content ratio (by mol) of the structural units contained in High-molecular compound (H4), as estimated from the quantities of the charged components, are as follows.

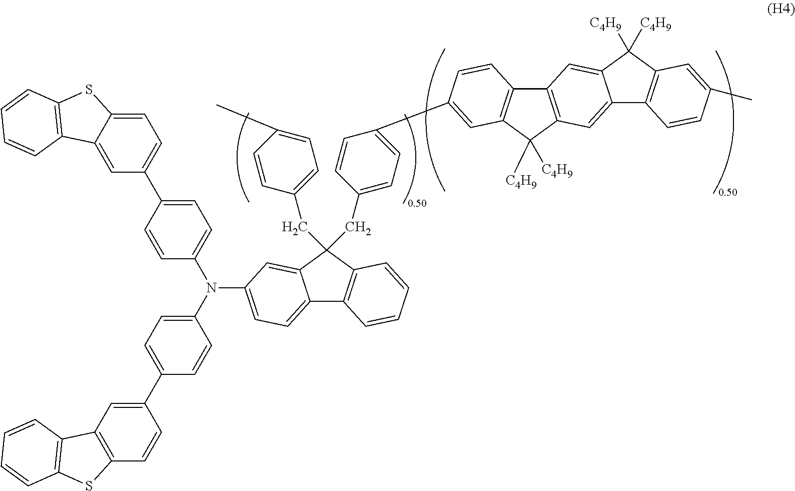

### Synthesis Example 5 (Synthesis of High-Molecular Compound (H5))

In a nitrogen atmosphere, 1.38 g (1.42 mmol) of Intermediate (3-5), 0.612 g (1.28 mmol) of 9,9-dioctylfluorenone-2,7-diboronic acid represented by the above formula (x1), 0.087 g (0.14 mmol) of a compound represented by the following formula (x4), 0.37 g of tetrabutylammonium chloride, 10 ml of toluene, 10 ml of dimethoxyethane, 1.18 g of potassium carbonate and 10 ml of water each were weighed, put into a reactor and stirred for 30 minutes. After the stirring, 6.3 mg of palladium acetate and 23.4 mg of an Sphos ligand were added thereto, and stirred with heating under reflux for 30 hours.

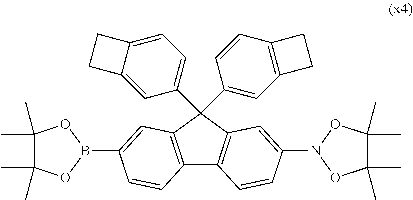

Subsequently, the reaction liquid was cooled down to room temperature, 0.166 g (1.36 mmol) of phenylboronic acid was added thereto and reacted with heating under reflux for 2 hours.

After the reaction, the reaction liquid was cooled down to room temperature, and washed three times with 20 ml of water. After the washing, an aqueous solution of sodium diethyldithiocarbamate trihydrate was added to the organic layer, and stirred at 80° C. for 4 hours. Then, this was cooled down to room temperature, and washed twice with 20 ml of an aqueous 3 mass % acetic acid solution. After the washing, the solvent was evaporated away from the organic layer under reduced pressure to give 1.78 g of a solid.

The solid was dissolved in toluene to be a toluene solution, then led to pass through a laminate column of silica gel 120 ml/alumina 20 ml to remove the catalyst, then the toluene solution was concentrated under reduced pressure, and washed with a mixed solution of methanol and acetone to give 1.04 g of High-molecular compound (H5).

The weight average molecular weight (Mw) of High-molecular compound (H5) was 5.02×10⁴, the number average molecular weight (Mn) thereof was 1.98×10⁴, and the molecular weight distribution (Mw/Mn) was 2.54.

The configuration and the content ratio (by mol) of the structural units contained in High-molecular compound (H5), as estimated from the quantities of the charged components, are as follows.

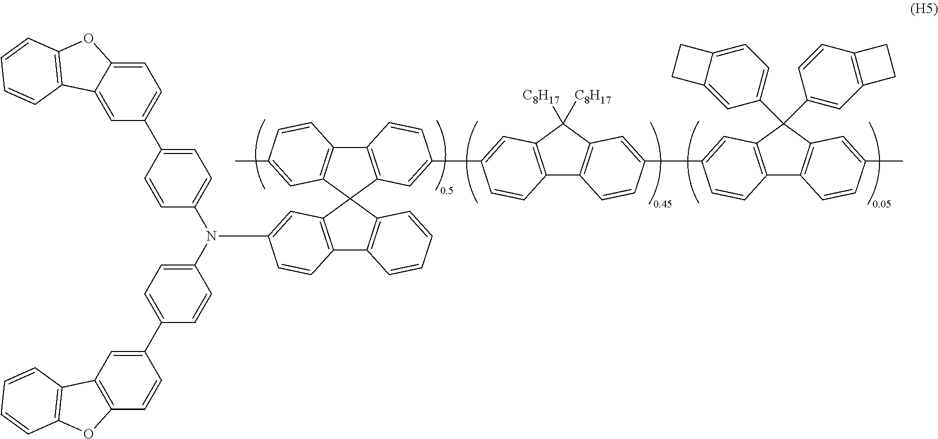

### Example 1 (Production of Organic EL Device)

According to the process mentioned below, two kinds of organic EL devices (A) and (B) were produced.

### (Cleaning of Substrate)

A glass substrate of 25 mm×25 mm×1.1 mm thick having an ITO transparent electrode (product of Geomatec Company) was cleaned by ultrasonic cleaning in isopropyl alcohol for 5 min and then UV (ultraviolet) ozone cleaning for 5 min.

### (Formation of Hole Injecting Layer)

Onto the transparent electrode line-formed surface of the ITO transparent electrode-having glass substrate, poly(3,4-ethylenedioxythiophene)/poly(styrenesulfonic acid) (PEDOT/PSS) (product name “CLEVIOS AI4083” manufactured by Heraeus K.K.) was applied according to a spin coating method for film formation thereon. After the film formation, this was washed with acetone to remove unnecessary parts, and then heated and dried on a hot plate at 200° C. for 10 minutes to form a hole injecting layer having a thickness of 30 nm. These operations were all carried out in air.

### (Formation of Hole Transporting Layer)

As a hole transporting material, High-molecular compound (H1) obtained in Synthesis Example 1 was used.

In a glass sample tube (SV-10, manufactured by Nichiden Rika Glass Co., Ltd.), High-molecular compound (H1) obtained in Synthesis Example 1 and toluene (electronic industry grade, manufactured by Kanto Chemical Co., Inc.) were so weighed that the solid concentration could be 0.8% by mass. Next, a stirring bar (Laboran Stirring Bar (diameter 4 mm×10 mm), manufactured by As One Corporation) was inserted into the sample tube, and the mixture therein was stirred at room temperature for 60 minutes, and then cooled at room temperature for 1 hour to give a coating solution.

Using the coating solution, a film was formed on the hole injecting layer according to a spin coating method. After the film formation, this was washed with toluene to remove unnecessary parts, and then heated and dried on a hot plate at 200° C. for 60 minutes to form a hole transporting layer having a thickness of 30 nm. The operation from the preparation of the coating solution to the formation of the hole transporting layer was carried out in a nitrogen atmosphere in a glove box.

### (Production of Organic EL Device (A))

The coat-laminated substrate was transferred into a vapor deposition chamber, on which the following compound (H-1) as a host material and the following compound (D-1) as a dopant material were co-deposited thereon at such a controlled deposition speed to be in a ratio of compound (H-1)/compound (D-1)=95/5 (by mass) to give a film thickness of 50 nm, thereby forming a light emitting layer.

Next, the following compound (ET-1) was vapor-deposited on the light emitting layer to have a thickness of 50 nm, thereby forming an electron transporting layer, and further, lithium fluoride was vapor-deposited to have a thickness of 1 nm thereby forming an electron injecting layer. With that, aluminum was vapor-deposited to have a thickness of 80 nm, thereby forming a cathode.

After completion of all the vapor deposition steps, this was sealed up with bored glass in a nitrogen atmosphere in a glove box, thereby producing an organic EL device (A).

### (Production of Organic EL Device (B))

Up to the step of forming a hole transporting layer, the same process as that for the organic EL device (A) was carried out, and onto the formed hole transporting layer, a toluene solution having a solid concentration of 1.6% by mass, as prepared by mixing the following compound (H-1) as a host material and the following compound (D-1) as a dopant material in a ratio of compound (H-1)/compound (D-1)=95/5 (by mass) was applied according to a spin coating method to form a film thereon. After the film formation, this was washed with toluene to remove unnecessary parts, and then heated and dried on a hot plate at 100° C., thereby forming a light emitting layer having a thickness of 50 nm. The operation up to formation of the light emitting layer was carried out in a nitrogen atmosphere in a glove box.

After the formation of the light emitting layer, the coated substrate was transferred into a vapor deposition chamber, and in the same manner as that for the organic EL device (A), an electron transporting layer, an electron injecting layer and a cathode were formed through vapor deposition, and after completion of all the deposition steps, this was sealed up with bored glass in a nitrogen atmosphere in a glove box, thereby producing an organic EL device (B).

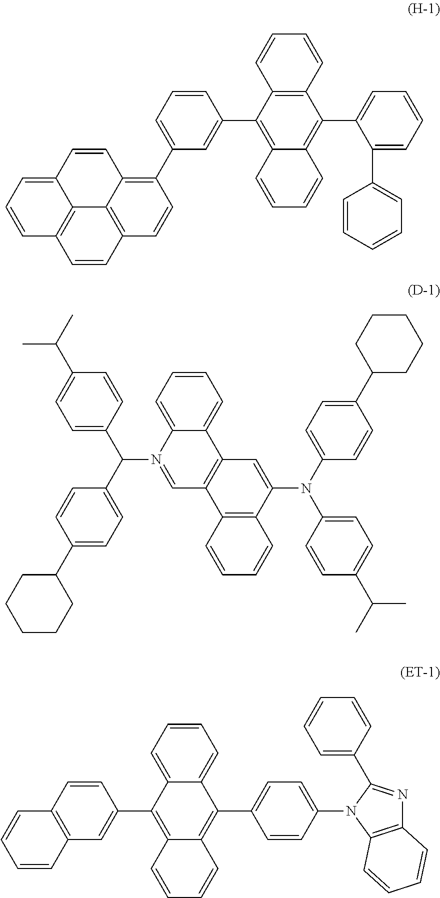

### Example 2

Two kinds of organic EL devices (A) and (B) were produced in the same manner as in Example 1, except that, as the hole transporting material, “High-molecular compound (H2)” obtained in Synthesis Example 2 was used in place of “High-molecular compound (H1)”.

### Example 3

Two kinds of organic EL devices (A) and (B) were produced in the same manner as in Example 1, except that, as the hole transporting material, “High-molecular compound (H3)” obtained in Synthesis Example 3 was used in place of “High-molecular compound (H1)”.

### Example 4

Two kinds of organic EL devices (A) and (B) were produced in the same manner as in Example 1, except that, as the hole transporting material, “High-molecular compound (H4)” obtained in Synthesis Example 4 was used in place of “High-molecular compound (H1)”.

### Example 5

Two kinds of organic EL devices (A) and (B) were produced in the same manner as in Example 1, except that, as the hole transporting material, “High-molecular compound (H5)” obtained in Synthesis Example 5 was used in place of “High-molecular compound (H1)”.

### Comparative Example 1

Two kinds of organic EL devices (A) and (B) were produced in the same manner as in Example 1, except that, as the hole transporting material, “High-molecular compound (Ha)”, in which the content of the structural unit represented by the following formula (H-a) is 100 mol %, was used in place of “High-molecular compound (H1)”.

The weight average molecular weight (Mw) of High-molecular compound (Ha) was 9.60×10³, the number average molecular weight (Mn) thereof was 6.50×10³, and the molecular weight distribution (Mw/Mn) was 1.48.

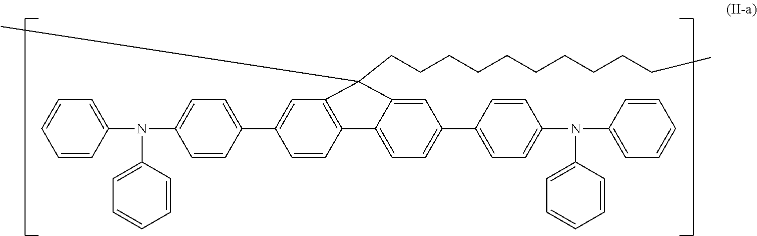

### Comparative Example 2

Two kinds of organic EL devices (A) and (B) were produced in the same manner as in Example 1, except that, as the hole transporting material, “High-molecular compound (Hb)”, in which the content of the structural unit represented by the following formula (H-b) is 100 mol %, was used in place of “High-molecular compound (H1)”.

The weight average molecular weight (Mw) of High-molecular compound (Hb) was 4.30×10⁴, the number average molecular weight (Mn) thereof was 2.20×10⁴, and the molecular weight distribution (Mw/Mn) was 1.95.

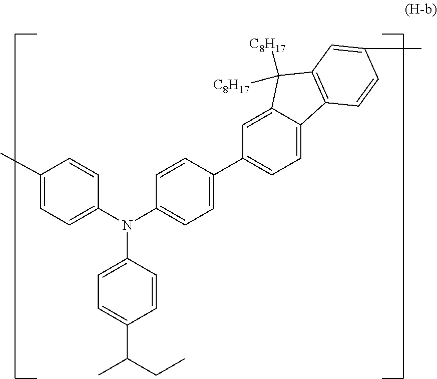

The organic EL devices (A) and (B) produced in Examples and Comparative Examples were tested according to the method mentioned below for measurement of 50% lifetime.

### (Method for Measurement of 50% Lifetime)

Using a constant-voltage power supply, a current was applied to the device so as to have a starting brightness of 1,000 cd/m², and under the same current kept maintained, the device was driven to measure the time for which the brightness decayed to 50% of the initial brightness (namely, 500 cd/m²). The measurement was carried out for both the organic EL devices (A) and (B) produced in Examples and Comparative Examples. The measurement results are shown in Table 16.

TABLE 16

| | | 50% Lifetime (hrs) | |
|---|---|---|---|
| | | Organic | Organic |
| | | EL Device | EL Device |
| | Hole Transporting Material | (A) | (B) |
| Example 1 | High-Molecular Compound (H1) | 350 | <2 |
| Example 2 | High-Molecular Compound (H2) | 322 | <2 |
| Example 3 | High-Molecular Compound (H3) | 298 | <2 |
| Example 4 | High-Molecular Compound (H4) | 184 | 160 |
| Example 5 | High-Molecular Compound (H5) | 196 | 147 |
| Comparative | High-Molecular Compound (Ha) | 12 | <2 |
| Example 1 | | | |
| Comparative | High-Molecular Compound (Hb) | 2 | <2 |
| Example 2 | | | |

From the results in Table 16, it is known that the organic EL devices using any of High-molecular compounds (H1) to (H5) included in one aspect of the present invention have a longer lifetime as compared with those using the High-molecular compound (Ha) or (Hb) of Comparative Examples 1 and 2.

In Example 5 using High-molecular compound (H5) having a polymerizing functional group, it is considered that thermal crosslinking reaction could go on in the heating step to form the hole transporting layer. Consequently, the light emitting layer was formed on the hole transporting layer according to the coating method of applying the light emitting material-containing solution onto the layer but not according to a vapor deposition method, without causing a problem of dissolving the hole transporting layer, and the organic EL device having a long lifetime was produced.

### REFERENCE SIGNS LIST

1 Organic EL Device
2 Substrate
3 Anode
4 Cathode
5 Light Emitting Layer
6 Anode-Side Organic Thin-Film Layer
7 Cathode-Side Organic Thin-Film Layer
10 Light Emitting Unit

1. A high-molecular compound having a structural unit (A) and a structural unit (B) differing from each other, wherein:
the structural unit (A) is represented by formula (A-1): 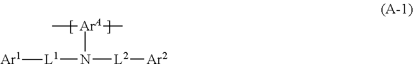
wherein Ar^{A} represents a linking group having a fluorene skeleton,
L¹ and L² each independently represent a single bond, a substituted or unsubstituted arylene group having 6 to 60 ring carbon atoms, or a substituted or unsubstituted heteroarylene group having 5 to 60 ring atoms, and
Ar¹ and Ar² each independently represent a substituted or unsubstituted aryl group having 6 to 60 ring carbon atoms, or a substituted or unsubstituted heteroaryl group having 5 to 60 ring atoms, and at least one of Ar¹ and Ar² is a monovalent organic group represented by formula (a): 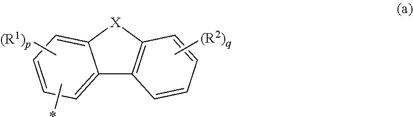
wherein X represents —O—, —S—, —N(R^{x})—, —C(R^{x})(R^{y})—, —Si(R^{x})(R^{y})—, —P(R^{x})—, —P(═O)(R^{x})—, or —P(═S)(R^{x})—, in which R^{x} and R^{y} each independently represent a hydrogen atom or a substituent, and R^{x} and R^{y} may bond to each other to form a ring structure,
R¹ and R² each independently represent a substituent, p represents an integer of 0 to 3, q represents an integer of 0 to 4, plural R¹'s, plural R²'s, and R¹ and R² may bond to each other to form a ring structure, and * indicates a bonding position to L¹ or L²; and
the structural unit (B) is represented by formula (B-1):
Ar^{B} (B-1)
wherein Ar^{B} represents a substituted or unsubstituted arylene group having 6 to 60 ring carbon atoms, or a substituted or unsubstituted heteroarylene group having 5 to 60 ring atoms.

2. The high-molecular compound according to claim 1, wherein the structural unit (A) is a structural unit (A2) represented by formula (A-2): 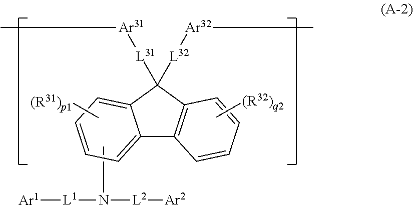
wherein L¹, L², Ar¹ and Ar² have the same definitions as in claim 1,
Ar³¹ and Ar³² each independently represent a single bond, a substituted or unsubstituted arylene group having 6 to 60 ring carbon atoms, or a substituted or unsubstituted heteroarylene group having 5 to 60 ring atoms,
L³¹ and L³² each independently represent a single bond, or a substituted or unsubstituted alkylene group having 1 to 50 carbon atoms,
R³¹ and R³² each independently represent a substituent, p1 represents an integer of 0 to 3, q2 represents an integer of 0 to 4, and plural R³¹'s, plural R³²'s, and R³¹ and R³² may bond to each other to form a ring structure.

3. The high-molecular compound according to claim 2, wherein the structural unit (A2) is a structural unit (A3) represented by formula (A-3): 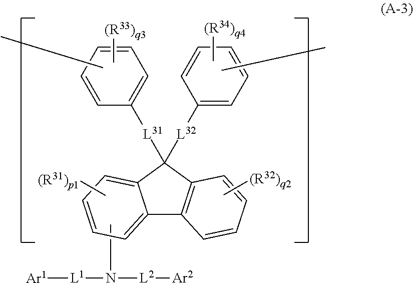
wherein L¹, L², Ar¹, Ar², L³¹, L³², R³¹, R³², p1, and q2 have the same definitions as in claim 2,
R³³ and R³⁴ each independently represent a substituent, q3 and q4 each independently represent an integer of 0 to 4, and plural R³³'s, plural R³⁴'s, and R³³ and R³⁴ may bond to each other to form a ring structure.

4. The high-molecular compound according to claim 3, wherein the structural unit (A3) is a structural unit (A4a) represented by formula (A-4a), or a structural unit (A4b) represented by formula (A-4b): 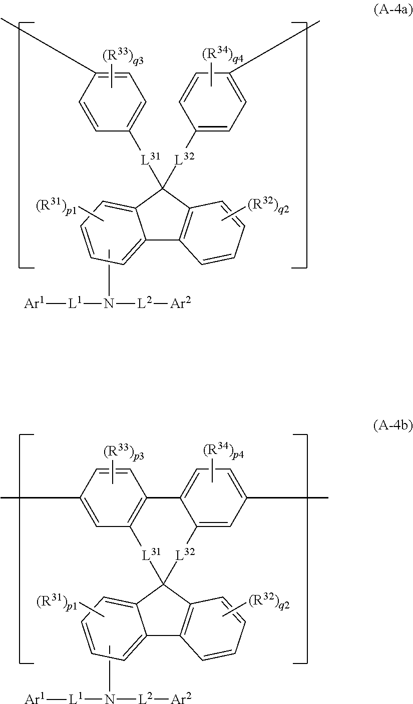
wherein L¹, L², Ar¹, Ar², L³¹, L³², R³¹, R³², p1, q2, R³³, R³⁴, q3, and q4 have the same definitions as in claim 3, and p3 and p4 each independently represent an integer of 0 to 3.

5. The high-molecular compound according to claim 3, wherein the structural unit (A3) is a structural unit (A5a) represented by formula (A-5a), or a structural unit (A5b) represented by formula (A-5b): 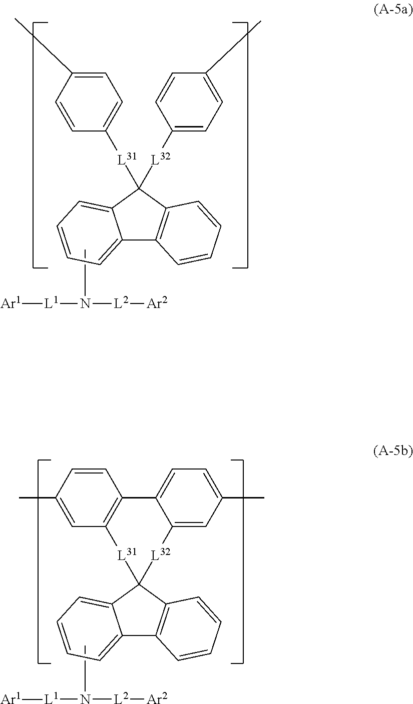
wherein L¹, L², Ar¹, Ar², L³¹ and L³² have the same definitions as in claim 3.

6. The high-molecular compound according to claim 1, wherein the structural unit (A) is a structural unit (A6) represented by formula (A-6): 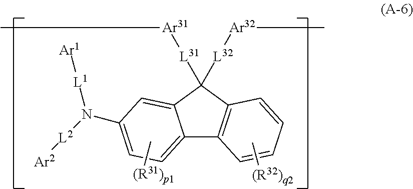
wherein L¹, L², Ar¹ and Ar² have the same definitions as in claim 1,
L³¹ and L³² each independently represent a single bond, or a substituted or unsubstituted alkylene group having 1 to 50 carbon atoms,
Ar³¹ and Ar³² each independently represent a single bond, a substituted or unsubstituted arylene group having 6 to 60 ring carbon atoms, or a substituted or unsubstituted heteroarylene group having 5 to 60 ring atoms,
R³¹ and R³² each independently represent a substituent, p1 represents an integer of 0 to 3, q2 represents an integer of 0 to 4, and plural R³¹'s, plural R³²'s, and R³¹ and R³² may bond to each other to form a ring structure.

7. The high-molecular compound according to claim 6, wherein the structural unit (A6) is a structural unit (A7) represented by formula (A-7): 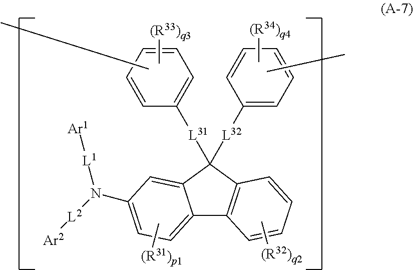
wherein L¹, L², Ar¹, Ar², L³¹, L³², R³¹, R³², p1, and q2 have the same definitions as in claim 6,
R³³ and R³⁴ each independently represent a substituent, q3 and q4 each independently represent an integer of 0 to 4, and plural R³³'s, plural R³⁴'s, and R³³ and R³⁴ may bond to each other to form a ring structure.

8. The high-molecular compound according to claim 7, wherein the structural unit (A7) is a structural unit (A8a) represented by formula (A-8a) or a structural unit (A8b) represented by formula (A-8b): 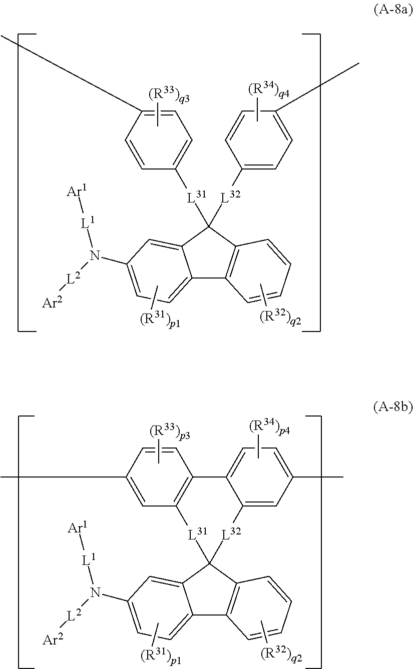
wherein L¹, L², Ar¹, Ar², L³¹, L³², R³¹, R³², p1, q2, R³³, R³⁴, q3, and q4 have the same definitions as in claim 7, and p3 and p4 each independently represent an integer of 0 to 3.

9. The high-molecular compound according to claim 7, wherein the structural unit (A7) is a structural unit (A9a) represented by formula (A-9a) or a structural unit (A9b) represented by formula (A-9b): 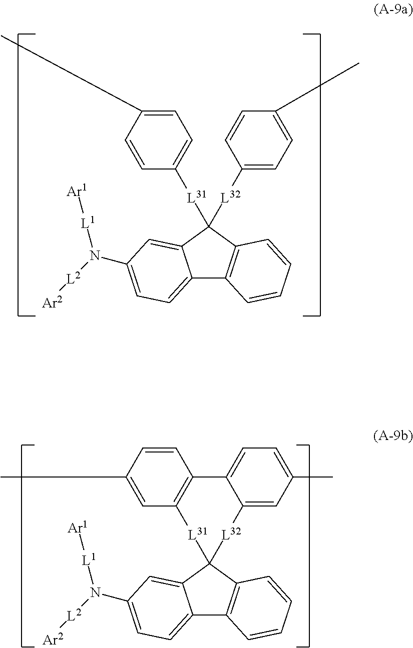
wherein L¹, L², Ar¹, Ar², L³¹ and L³² have the same definitions as in claim 7.

10. The high-molecular compound according to claim 1, wherein Ar¹ and Ar² each independently represent a monovalent organic group represented by the formula (a).

11. The high-molecular compound according to claim 1, wherein at least one of Ar¹ and Ar² is a monovalent organic group represented by formula (a-1) or (a-2): 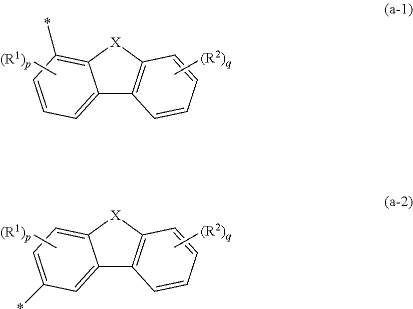
wherein X, R¹, R², p, and q have the same definitions as in the formula (a), and * indicates a bonding position to L¹ or L².

12. The high-molecular compound according to claim 11, wherein Ar¹ and Ar² each independently represent a monovalent organic group represented by the formula (a-1) or (a-2).

13. The high-molecular compound according to claim 1, wherein at least one of Ar¹ and Ar² is a monovalent organic group represented by formula (a-1-1), (a-1-2), (a-2-1), (a-2-2) or (a-2-3): 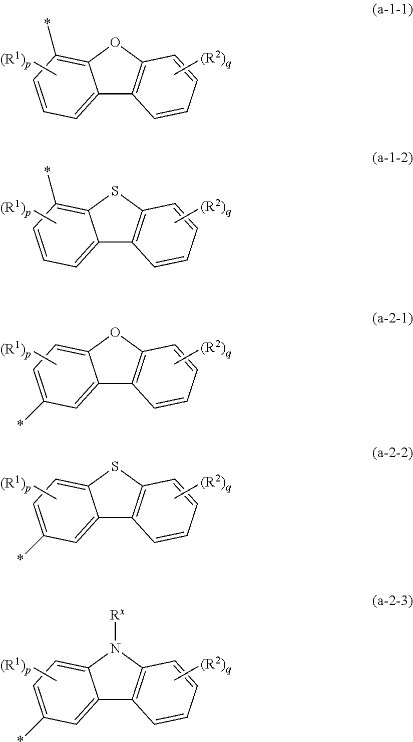
wherein R¹, R², p, and q have the same definitions as in the formula (a), R^{X} represents a hydrogen atom or a substituent, and * indicates a bonding position to L¹ or L².

14. The high-molecular compound according to claim 13, wherein Ar¹ and Ar² each independently represent a monovalent organic group represented by the formula (a-1-1), (a-1-2), (a-2-1), (a-2-2) or (a-2-3).

15. The high-molecular compound according to claim 1, wherein L¹ and L² each independently represent a single bond or a group represented by any of the formulae (L-i) and (L-ii): 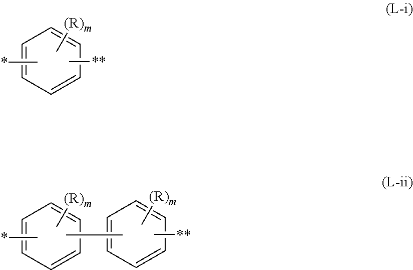
wherein R each independently represent a substituent, m each independently are an integer of 0 to 4, plural R's, if any, may be the same as or different from each other, and two selected from plural R's may bond to each other to form a ring structure, and
and ** each indicate a bonding position.

16. The high-molecular compound according to claim 1, wherein Ar^{B} in the formula (B) represents a divalent residue of a compound represented by formula (B-2): 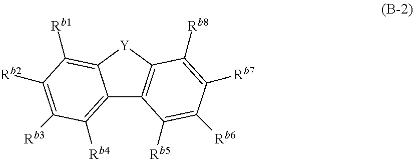
wherein R^{b1} to R^{b8} each independently represent a hydrogen atom or a substituent, and two selected from R^{b1} to R^{b8} may bond to each other to form a ring structure,
Y represents —O—, —S—, —N(R^{a})—, —C(R^{a})(R^{b})—, or —Si(R^{a})(R^{b})—, R^{a} and R^{b} each independently represent a hydrogen atom or a substituent, and R^{a} and R^{b} may bond to each other to form a ring structure.

17. The high-molecular compound according to claim 1, wherein Ar^{B} in the formula (B-1) is an arylene group selected from the group consisting of a substituted or unsubstituted phenylene group, a substituted or unsubstituted biphenylene group, a substituted or unsubstituted terphenylene group, a substituted or unsubstituted naphthalenyl group, and a substituted or unsubstituted anthracenyl group.

18. The high-molecular compound according to claim 1, wherein the structural unit (B) comprises a structural unit (C) represented by formula (C-1):
Ar^{C} (C-1)
wherein Ar^{C} represents an arylene group having a polymerizing functional group and having 6 to 60 ring carbon atoms, or a heteroarylene group having a polymerizing functional group and having 5 to 60 ring atoms, and the arylene group and the heteroarylene group may have any other substituent than a polymerizing functional group.

19. The high-molecular compound according to claim 18, wherein Ar^{C} represents a divalent group represented by formula (C-2), (C-3) or (C-4): 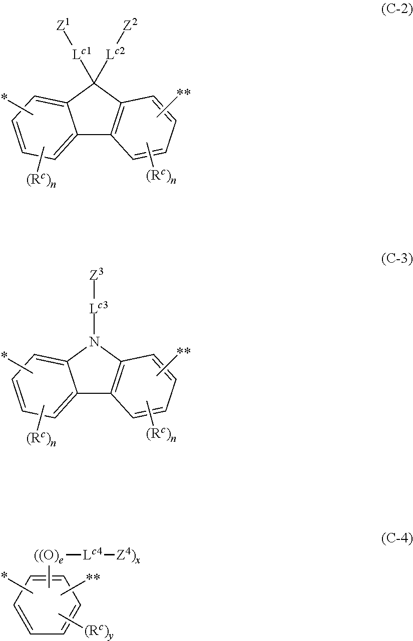
wherein L^{c1} to L^{c4} each independently represent a single bond, or a substituted or unsubstituted alkylene group having 1 to 50 carbon atoms,
Z¹ to Z⁴ each independently represent a polymerizing functional group,
R^{C} each independently represent a substituent, plural R^{c}'s, if any, may bond to each other to form a ring structure,
and ** each indicate a bonding position,
n each independently represent an integer of 0 to 3,
e represents 0 or 1, x represents an integer of 1 to 4, y represents an integer of 0 to 3, and x+y is 4 or less.

20. The high-molecular compound according to claim 18, wherein the polymerizing functional group is selected from the group consisting of formulae (i) to (vii): 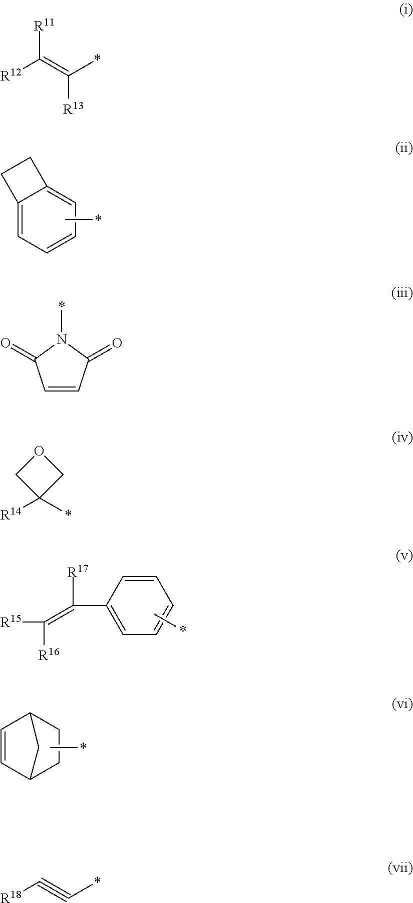
wherein * indicates a bonding position, and R¹¹ to R¹⁸ each independently represent a hydrogen atom, a substituted or unsubstituted alkyl group having 1 to 20 carbon atoms, or a substituted or unsubstituted aryl group having 6 to 24 ring carbon atoms.

21. The high-molecular compound according to claim 1, wherein the substituent, or the substituent relating to the expression of “substituted or unsubstituted” is a group selected from the group consisting of an alkyl group having 1 to 50 carbon atoms, a cycloalkyl group having 5 to 60 ring carbon atoms, an aryl group having 6 to 60 ring carbon atoms, an alkoxy group having an alkyl group having 1 to 50 carbon atoms, an aryloxy group having an aryl group having 6 to 60 ring carbon atoms, an arylthio group having an aryl group having 6 to 60 ring carbon atoms, a heteroaryl group having 5 to 60 ring atoms, an alkylcarbonyloxy group having an alkyl group having 1 to 50 carbon atoms, a halogen atom, a cyano group, a nitro group, a hydroxy group and a carboxy group.

22. The high-molecular compound according to claim 1, wherein a ratio of a molar fraction of the structural unit (A) to a molar fraction of the structural unit (B) [(A)/(B)] is in a range from 30/70 to 90/10.

23. A material for organic electroluminescence devices, comprising the high-molecular compound of claim 1.

24. An organic electroluminescence device comprising a cathode, an anode, and an organic thin-film layer formed of one layer or plural layers sandwiched between the cathode and the anode, wherein:
the organic thin-film layer comprises a light emitting layer, and
at least one layer of the organic thin-film layer comprises the high-molecular compound of claim 1.

25. The organic electroluminescence device according to claim 24, wherein the organic thin-film layer comprising the high-molecular compound is any of a hole injecting layer or a hole transporting layer.

26. An electronic device equipped with the organic electroluminescence device of claim 24.
